(19) United States
(12) Patent Application Publication
(10) Pub. No.: US 2026/0003283 A1
(43) Pub. Date: Jan. 1, 2026

(54) PHOTOSENSITIVE COMPOSITION, METHOD FOR FORMING PATTERNED SILICON-CONTAINING RESIN FILM, AND SILICON-CONTAINING RESIN

(71) Applicant: TOKYO OHKA KOGYO CO., LTD., Kawasaki-shi (JP)

(72) Inventors: Saburo Kobayashi, Kawasaki-shi (JP); Hayato Ouchi, Kawasaki-shi (JP); Keiichi Ibata, Kawasaki-shi (JP)

(21) Appl. No.: 19/246,392

(22) Filed: Jun. 23, 2025

(30) Foreign Application Priority Data
Jun. 28, 2024 (JP) 2024-104805

(51) Int. Cl. G03F 7/075; C08G 77/00; C08G 77/24; G03F 7/00; G03F 7/004

(52) U.S. Cl. CPC G03F 7/0757; C08G 77/24; G03F 7/0045; G03F 7/0046; G03F 7/70033; C08G 77/80

(57) ABSTRACT

A photosensitive composition capable of forming a fine pattern with high sensitivity and low roughness; a method for producing a patterned silicon-containing resin film using the photosensitive composition; and a silicon-containing resin that can be preferably incorporated into the photosensitive composition. The photosensitive composition includes a silicon-containing resin, a photoacid generating agent, and a cross-linking agent, and the silicon-containing resin has an aromatic group substituted with one or more iodine atoms.

This application claims priority to Japanese Patent Application No. 2024-104805, filed Jun. 28, 2024, the entire content of which is incorporated herein by reference.

### BACKGROUND OF THE INVENTION

### Field of the Invention

The present invention relates to a photosensitive composition, a method for producing a patterned silicon-containing resin film, and a silicon-containing resin.

### Related Art

In manufacture of electronic components, a laminate in which a resist film is formed on a substrate such as a silicon wafer using a resist material is subjected to processing including etching. For example, a resist pattern is formed on the resist film by selective exposure, and dry etching is performed using the resist pattern as a mask to form a pattern on the substrate.

In recent years, advances in lithography technology have led to rapid pattern miniaturization in manufacture of semiconductor elements or liquid crystal elements. A method of pattern miniaturization generally involves shortening a wavelength (increasing energy) of an exposure light source.

A resist material is required to have lithographic properties such as sensitivity to the exposure light source and resolution that can reproduce a fine pattern. As a resist material that satisfies such a requirement, a chemically amplified resist composition which contains a base material component having a solubility in a developing solution that changes under action of an acid and an acid generating agent component that generates an acid upon exposure has been conventionally used. In the chemically amplified resist composition, a resin having a plurality of constituent units is generally used to improve the lithographic properties, etc. A chemically amplified resist composition that combines an acid generating agent component with an acid diffusion controlling agent that controls diffusion of an acid generated from the acid generating agent component upon exposure has also been proposed.

Furthermore, a resist material needs to have etching resistance in order to function as a mask for processing a substrate. For this reason, a silicon-containing compound may be used as a base material component from the viewpoint of the etching resistance. For example, Patent Document 1 discloses a resist composition containing a silicon-containing resin, an acid generating agent component, and a photodegradable base that controls acid diffusion in order to accommodate pattern miniaturization and etching processing.
Patent Document 1: Japanese Unexamined Patent Application, Publication No. 2022-59575

### SUMMARY OF THE INVENTION

Further advances in lithography technology and expansion of application fields have led to rapid pattern miniaturization. Accordingly, a technology that can form a fine pattern with a good shape is required when semiconductor elements, etc., are manufactured. For example, extreme ultraviolet (EUV) lithography aims to form a pattern as fine as a dozen nanometers. Such a smaller pattern dimension makes it more difficult to achieve both etching resistance and lithographic properties. A resist composition containing a silicon-containing resin as a base material component, as disclosed in Patent Document 1, has the advantage of higher etching resistance compared to a resist composition with a common organic material as a base material. However, formation of a fine pattern needs further improvement in terms of sensitivity and reduction of pattern roughness.

The present invention was made in view of the above circumstances, and an object thereof is to provide a photosensitive composition capable of forming a fine pattern with high sensitivity and low roughness, a method for producing a patterned silicon-containing resin film using the photosensitive composition, and a silicon-containing resin that can be suitably incorporated into the photosensitive composition.

As a result of extensive studies to solve the above problem, the present invention has been completed based on findings that a photosensitive composition including a silicon-containing resin (A), a photoacid generating agent (B), and a cross-linking agent (C), the silicon-containing resin (A) having an aromatic group substituted with one or more iodine atoms can be used to solve the above problem. Specifically, the present invention provides the following aspects.

A first aspect relates to a photosensitive composition including a silicon-containing resin (A), a photoacid generating agent (B), and a cross-linking agent (C), the silicon-containing resin (A) having an aromatic group substituted with one or more iodine atoms.

A second aspect relates to a method for producing a patterned silicon-containing resin film, the method including: coating a support with the photosensitive composition according to the first aspect to form a coated film; exposing the coated film in a position-selective manner; and developing the thus-exposed coated film.

A third aspect relates to a silicon-containing resin having an aromatic group substituted with one or more iodine atoms.

The present invention can provide a photosensitive composition capable of forming a fine pattern with high sensitivity and low roughness, a method for producing a patterned silicon-containing resin film using the photosensitive composition, and a silicon-containing resin that can be suitably incorporated into the photosensitive composition.

### DETAILED DESCRIPTION OF THE INVENTION

Although embodiments of the present invention will be described hereafter in detail, the present invention is not limited to the embodiments below in any way and can be implemented with modifications as appropriate within the scope of the object of the present invention.

### <<Photosensitive Composition>>

A photosensitive composition contains a silicon-containing resin (A), a photoacid generating agent (B), and a cross-linking agent (C).

The silicon-containing resin (A) has an aromatic group substituted with one or more iodine atoms.

The photosensitive composition containing a silicon-containing resin (A), a photoacid generating agent (B), and a cross-linking agent (C), the silicon-containing resin (A) having an aromatic group substituted with one or more iodine atoms enables formation of a fine pattern with high sensitivity and low roughness (patterned silicon-containing resin film), as described in Examples below. On the other hand, for example, even though a photoacid generating agent (B) having an iodine atom or a base component (D) having an iodine atom is contained, a photosensitive composition that does not contain a silicon-containing resin (A) having an aromatic group substituted with one or more iodine atoms is inferior in at least one of sensitivity and roughness to a photosensitive composition containing the silicon-containing resin (A) having an aromatic group substituted with one or more iodine atoms.

### <Silicon-Containing Resin (A)>

A photosensitive composition contains a silicon-containing resin (A). The silicon-containing resin (A) has an aromatic group substituted with one or more iodine atoms.

An aromatic group for the aromatic group substituted with one or more iodine atoms may be an aromatic hydrocarbon group, or an aromatic heterocyclic group in which at least one of carbon atoms in an aromatic hydrocarbon ring constituting an aromatic hydrocarbon group is substituted with a heteroatom. Specific examples of the aromatic hydrocarbon ring constituting an aromatic hydrocarbon group include a benzene ring, a fluorene ring, a naphthalene ring, an anthracene ring, a phenanthrene ring, a biphenyl ring, etc. Examples of the aromatic hydrocarbon group include a group in which one or more hydrogen atoms are removed from the above-described aromatic hydrocarbon ring (aryl group), etc. Specific examples of the aromatic hydrocarbon group include a phenyl group, a naphthalene-1-yl group, a naphthalene-2-yl group, etc. Examples of the heteroatom in the aromatic heterocyclic ring include an oxygen atom, a sulfur atom, a nitrogen atom, etc. Specific examples of the aromatic heterocyclic ring constituting an aromatic heterocyclic group include a pyridine ring, a thiophene ring, etc.

A number of the iodine atoms substituted for the aromatic group is preferably 1 or more and 5 or less and more preferably 1 or more and 3 or less.

A content of the iodine atoms in the silicon-containing resin (A) is preferably 0.1% by mass or more and 50% by mass or less, more preferably 1% by mass or more and 40% by mass or less, and particularly preferably 10% by mass or more and 30% by mass or less relative to a total mass of all atoms constituting the silicon-containing resin.

A silicon-containing resin (A) and a cross-linking agent (C) form a cross-linked structure under action of an acid generated from a photoacid generating agent (B) upon exposure. As a result, the silicon-containing resin (A) has a higher molecular weight and is insoluble in an alkaline developing solution. Furthermore, a silicon-containing resin (A) having a phenolic hydroxy group, etc., is soluble in an alkaline developing solution. Therefore, when a photosensitive composition is exposed in a position-selective manner, an unexposed area thereof is soluble in the alkaline developing solution. Thus, the photosensitive composition has a photolithographic property, that is, can be patterned by position-selective exposure and development with an alkaline developing solution. Note that, the photosensitive composition herein is a negative photosensitive composition.

Suitable examples of a silicon-containing resin (A) include a polysilane and a polysiloxane. The silicon-containing resin (A) is preferably a polysiloxane and more preferably a polysiloxane including a silsesquioxane unit. The silicon-containing resin (A) will be described below using a polysiloxane as an example. The polysiloxane is not particularly limited as long as it is a resin having a main chain composed of a siloxane bond (Si—O—Si). The polysiloxane can be a linear polysiloxane, a branched polysiloxane, or a silsesquioxane. The silsesquioxane may be any of a cage silsesquioxane, an incomplete cage silsesquioxane, a laddered silsesquioxane, or a random silsesquioxane. The polysiloxane may have a linear polysiloxane backbone and/or a branched polysiloxane backbone in combination with a silsesquioxane skeleton.

[Constituent Unit (a1)]

A polysiloxane preferably has a constituent unit (a1) represented by Formula (a1) below as a constituent unit having an aromatic group substituted with one or more iodine atoms:

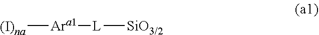

in which
L is a divalent linking group having 1 or more and 40 or less carbon atoms;
provided that when the divalent linking group for L is bonded to an aromatic hydrocarbon ring in Ar^{a1}, there is no aromatic hydrocarbon group at an end of the divalent linking group for L that is bonded to the aromatic hydrocarbon ring in Ar^{a1};
Ar^{a1} is a group having an aromatic hydrocarbon ring that is optionally substituted with one or more groups selected from a hydroxy group, an alkoxy group, or a hydrocarbon group that may have a substituent;
I is bonded to the aromatic hydrocarbon ring that Ar^{a1} has; and na is an integer of 1 or more and 3 or less.

Examples of the divalent linking group having 1 or more and 40 or less carbon atoms for L in Formula (a1) include —O—, —C(═O)—O—, —O—C(═O)—, —C(═O)—NH—, —C(═O)—, —O—C(═O)—O—, a divalent hydrocarbon group, or a divalent group composed of a combination thereof. The divalent linking group having 1 or more and 40 or less carbon atoms for L is preferably —O—, —C(═O)—O—, —O—C(═O)—, a divalent hydrocarbon group, or a divalent group composed of a combination thereof. Examples of the divalent hydrocarbon group include an alkylene group, a divalent aromatic hydrocarbon group, etc. The alkylene group may be linear or branched. Specific examples of the alkylene group include a methylene group, an ethylene group, a propan-1,3-diyl group, a propan-1,2-diyl group, an n-butylene group, an n-pentylene group, etc. Specific examples of an aromatic hydrocarbon ring constituting the divalent aromatic hydrocarbon group include a benzene ring, a fluorene ring, a naphthalene ring, an anthracene ring, a phenanthrene ring, a biphenyl ring, etc. Examples of the divalent aromatic hydrocarbon group include a group in which two hydrogen atoms are removed from the above-described aromatic hydrocarbon ring. Specific suitable examples of the divalent aromatic hydrocarbon group include a phenylene group such as an o-phenylene group, a m-phenylene group, or a p-phenylene group; a naphthalene-diyl group such as a naphthalene-1,4-diyl group, a naphthalene-1,3-diyl group, a naphthalene-2,6-diyl group, or a naphthalene-2,7-diyl group; a biphenyl-diyl group such as a biphenyl-4,4′-diyl group, a biphenyl-3,4′-diyl group, or a biphenyl-3,3′-diyl group, etc.

Specific examples of L include linking groups having structures below. In the linking groups having structures below, * denotes an atomic bond.

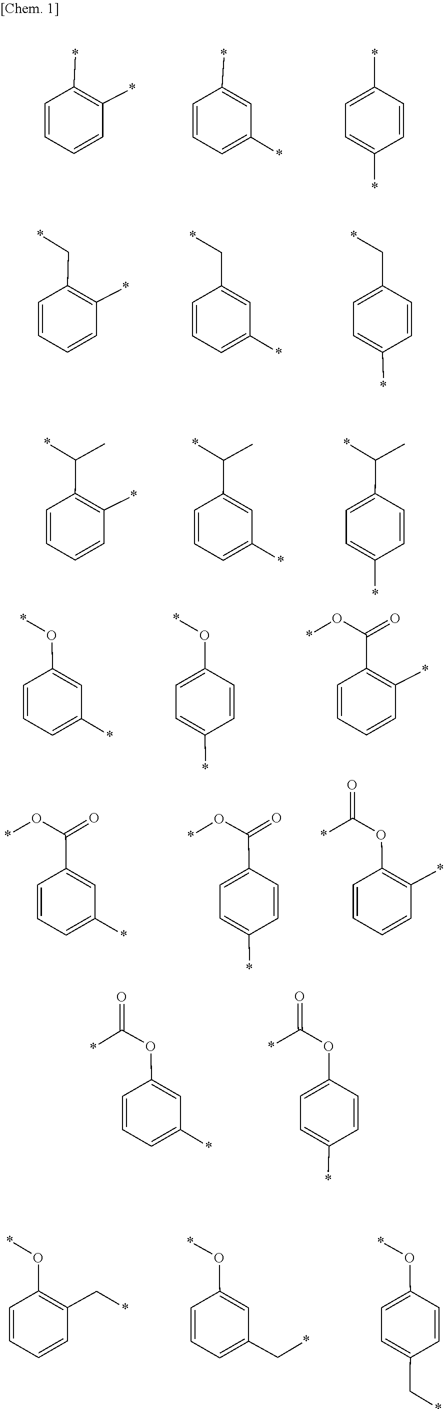

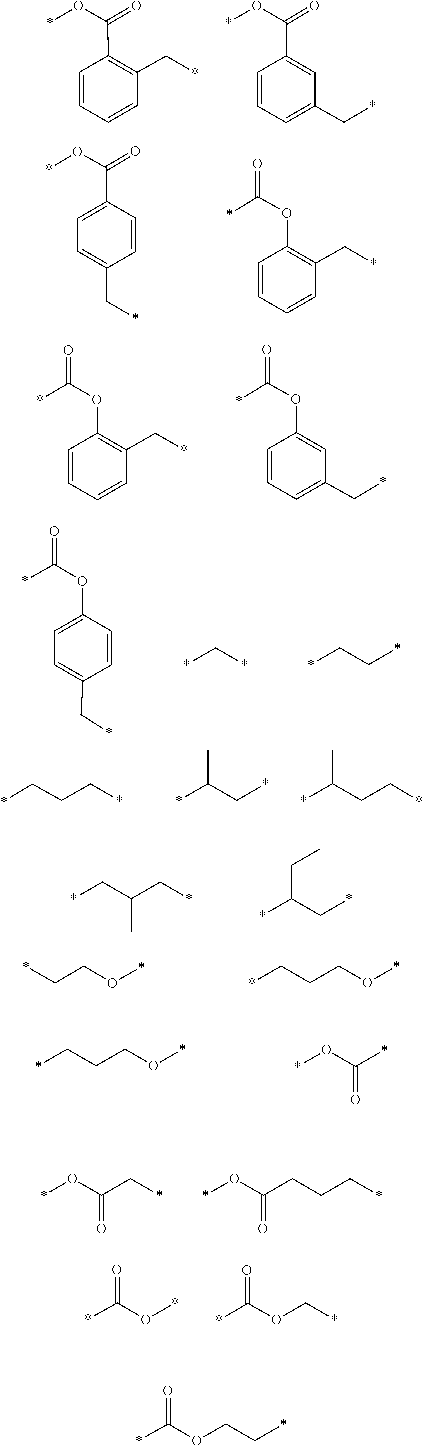

L is preferably a linking group having any of structures below.

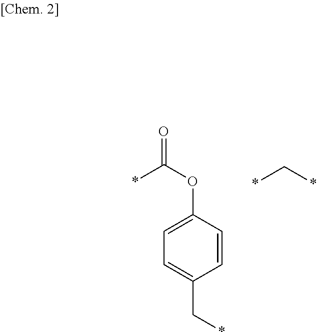

In Formula (a1), Arai is a cyclic group having an aromatic hydrocarbon ring that is optionally substituted with one or more groups selected from a hydroxy group, an alkoxy group, or a hydrocarbon group that may have a substituent. Arai may consist of an aromatic hydrocarbon ring that is optionally substituted with one or more groups selected from a hydroxy group, an alkoxy group, or a hydrocarbon group that may have a substituent or may be composed of a fused ring formed by an aromatic hydrocarbon ring that is optionally substituted with one or more groups selected from a hydroxy group, an alkoxy group, or a hydrocarbon group that may have a substituent and an aliphatic hydrocarbon ring. Note that, na I (s) is/are bonded to the aromatic hydrocarbon ring that Arai has.

The aromatic hydrocarbon ring that Arai has may be a monocyclic aromatic hydrocarbon ring or a polycyclic aromatic hydrocarbon ring. The polycyclic aromatic hydrocarbon ring may be a fused ring of two or more monocyclic aromatic hydrocarbon rings, a monocyclic aromatic hydrocarbon ring or a fused ring attached to each other via a single bond. The aromatic hydrocarbon ring preferably has 6 or more and 30 or less carbon atoms, more preferably 6 or more and 20 or less carbon atoms, further preferably 6 or more and 15 or less carbon atoms, and particularly preferably 6 or more and 12 or less carbon atoms. Examples of the aromatic hydrocarbon ring that Ar^{a1} has include a benzene ring, a fluorene ring, a naphthalene ring, an anthracene ring, a phenanthrene ring, a biphenyl ring, etc. Examples of the aliphatic hydrocarbon ring that forms a fused ring with the aromatic hydrocarbon ring that Ar^{a1} has include an aliphatic hydrocarbon ring having 5 or more and 7 or less carbon atoms (a cyclopentene ring, a cyclohexene ring, a cycloheptene ring).

When the aromatic hydrocarbon ring that Ar^{a1} has is substituted with an alkoxy group, specific examples of the alkoxy group include a methoxy group, an ethoxy group, an n-propyloxy group, an isopropyloxy group, an n-butyloxy group, an isobutyloxy group, a sec-butyloxy group, a tert-butyloxy group, etc.

When the aromatic hydrocarbon ring that Ar^{a1} has is substituted with a hydrocarbon group that may have a substituent, the hydrocarbon group that may have a substituent may be a saturated hydrocarbon group or an unsaturated hydrocarbon group, and may be linear or branched. Examples of the saturated hydrocarbon group include an alkyl group. Specific examples of the alkyl group include a methyl group, an ethyl group, a propyl group, an n-butyl group, a tert-butyl group, etc. Examples of a substituent that the hydrocarbon group serving as a substituent may have include a hydroxy group, an alkoxy group, etc.

When Ar^{a1} has an aromatic hydrocarbon ring that is substituted with two or more hydrocarbon groups that each may have a substituent, the two hydrocarbon groups that each may have a substituent may be linked to each other to form an aliphatic hydrocarbon ring together with carbon atoms in the aromatic hydrocarbon ring to which the two hydrocarbon groups that each may have a substituent are attached. Examples of the aliphatic hydrocarbon ring include a cyclopentene ring, a cyclohexene ring, a norbornene ring, etc.

na is an integer of 1 or more and 3 or less and preferably 1 or 2.

Specific examples of Ar^{a1} include groups having structures below. In the groups having structures below, * denotes an atomic bond.

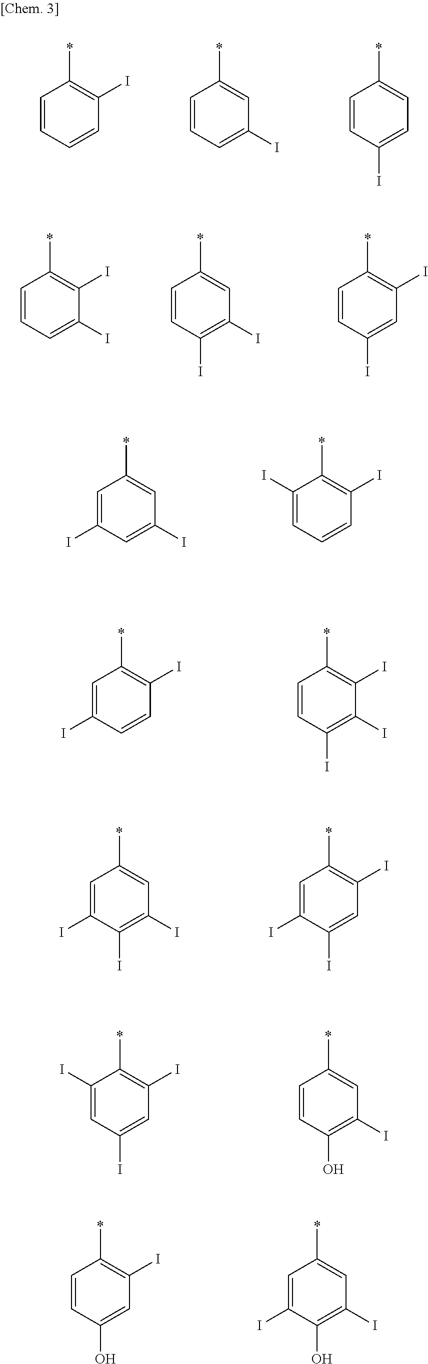

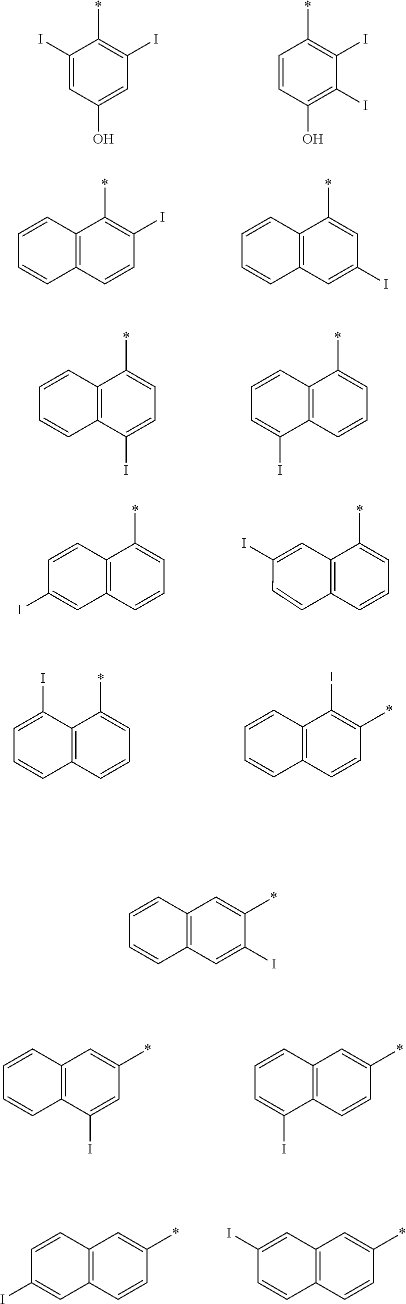

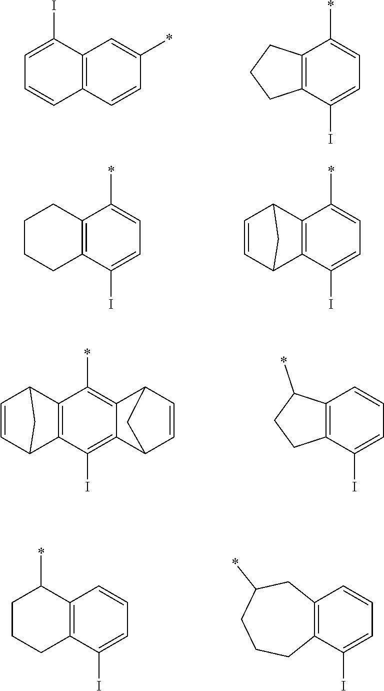

Ar^{a1} is preferably a group having any of structures below.

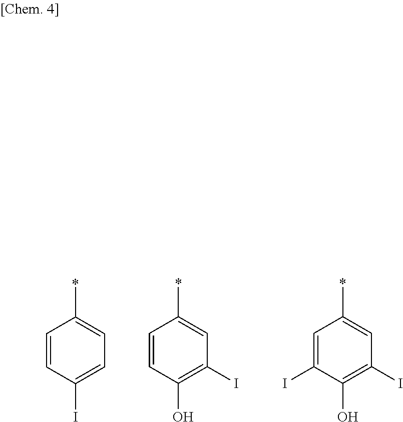

Specific preferred examples of a constituent unit (a1) are shown below.

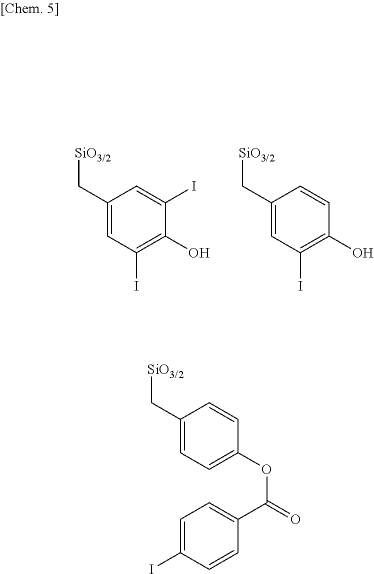

A constituent unit (a1) that a polysiloxane has may be one or two or more. A proportion of the constituent unit (a1) in the polysiloxane is preferably 1% by mole or more, more preferably 4% by mole or more, and further preferably 15% by mole or more relative to a total (100% by mole) of all constituent units constituting the polysiloxane. The proportion is preferably 50% by mole or less, more preferably 40% by mole or less, and further preferably 30% by mole or less.

[Constituent Unit (a2)]

A polysiloxane preferably has a phenolic hydroxy group. Specifically, for example, the polysiloxane preferably includes a constituent unit (a2) represented by Formula (a2) below. Herein, the constituent unit (a2) represented by Formula (a2) does not fall under the constituent unit (a1) represented by Formula (a1).

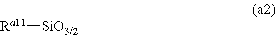

In Formula (a2), R^{a11} is an organic group having a phenolic hydroxy group.

The organic group for R^{a11} preferably has 6 or more and 40 or less carbon atoms, more preferably 6 or more and 20 or less carbon atoms, and further preferably 6 or more and 10 or less carbon atoms.

The organic group for R^{a11} is preferably a hydrocarbon group having a phenolic hydroxy group. Note that, the hydrocarbon group having a phenolic hydroxy group is a hydrocarbon group including an aromatic hydrocarbon group substituted with one or more hydroxy groups.

As used herein, an aromatic hydrocarbon group refers to a group consisting of an aromatic hydrocarbon ring or a group in which two or more aromatic hydrocarbon rings are linked via a single bond. The aromatic hydrocarbon ring may be monocyclic or a fused ring of two or more rings. Specific examples of the aromatic hydrocarbon ring constituting the aromatic hydrocarbon group include a benzene ring, a fluorene ring, a naphthalene ring, an anthracene ring, a phenanthrene ring, a biphenyl ring, etc. The hydrocarbon group including an aromatic hydrocarbon ring may consist of an aromatic hydrocarbon group, or may be a combination of an aromatic hydrocarbon group and an aliphatic hydrocarbon group. The aliphatic hydrocarbon group may be a saturated aliphatic hydrocarbon group or an unsaturated aliphatic hydrocarbon group, and is preferably a saturated aliphatic hydrocarbon group. Examples of a hydrocarbon group constituting the hydrocarbon group having a phenolic hydroxy group include a group in which one hydrogen atom is removed from the above-described aromatic hydrocarbon ring or a group in which one hydrogen atom on the above-described aromatic hydrocarbon ring is substituted with an alkylene group. The alkylene group to be substituted for the hydrogen atom on the aromatic hydrocarbon ring preferably has 1 or more and 4 or less carbon atoms, more preferably 1 or more and 2 or less carbon atoms, and particularly preferably 1 carbon atom. The group in which one hydrogen atom is removed from the aromatic hydrocarbon ring is an aromatic hydrocarbon group (aryl group). Specific examples of the aromatic hydrocarbon group include a phenyl group, a naphthalene-1-yl group, a naphthalene-2-yl group, etc. The group in which one hydrogen atom on the aromatic hydrocarbon ring is substituted with an alkylene group is an aralkyl group. Specific suitable examples of the aralkyl group include a benzyl group, a phenethyl group, a naphthalene-1-ylmethyl group, a naphthalene-2-ylmethyl group, a 2-(naphthalene-1-yl)ethyl group, a 2-(naphthalene-2-yl)ethyl group, etc.

When R^{a11} is an organic group having a phenolic hydroxy group, the organic group may consist of an aromatic group or may be a combination of an aromatic group and an aliphatic group. The aromatic group may be an aromatic hydrocarbon group or an aromatic heterocyclic group. The aliphatic group may be a chain aliphatic group, a cyclic aliphatic group, or a combination of a chain aliphatic group and a cyclic aliphatic group. When the aliphatic group is a cyclic aliphatic group, the cyclic aliphatic group may form a fused ring with an aromatic group. When R^{all} is an organic group having a phenolic hydroxy group, the organic group may have a substituent on an aromatic group or an aliphatic group. Examples of the substituent include a carboxy group, a hydroxy group, an amino group, a sulfo group, a halogen atom, a halogenated alkyl group, an alkoxy group, an alkyloxycarbonyl group, a nitro group, etc. When the organic group having a phenolic hydroxy group for R^{a11} has an aliphatic group, the aliphatic group may include a bond containing a heteroatom such as —O—, —C(═O)—O—, —C(═O)—, —O—C(═O)—O—, —C(═O)—NH—, —NH—, ═N—, —NH—C(═NH)—, —S—, —S(═O)₂—, —S(═O)₂—O—, or a combination of two or more selected from the above-described groups. H in the above-described bond containing a heteroatom may be substituted with an alkyl group such as a methyl group or an ethyl group, or an acyl group such as an acetyl group, a propionyl group, or a benzoyl group.

A constituent unit (a2) is preferably a constituent unit (a2-1) represented by Formula (a2-1) below:

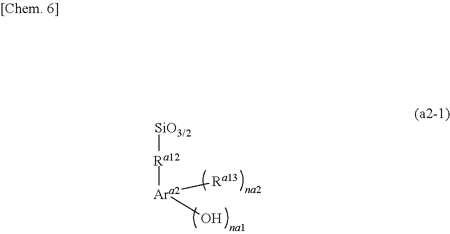

in which Ar^{a2} is a cyclic group having an aromatic hydrocarbon ring;
   R^{a12} is a single bond or a divalent linking group;
   R^{a13} is a hydrocarbon group having 1 or more and 6 or less carbon atoms, a fluorine atom, a chlorine atom, or a bromine atom;
   na1 OH and na2 R^{a13} are bonded to an aromatic hydrocarbon ring that Ar^{a2} has;
   na1 is an integer of 1 or more and 3 or less; and
   na2 is an integer of 0 or more and 4 or less.

Ar^{a2} is a (na1+na2+1)-valent cyclic group having an aromatic hydrocarbon ring. Ar^{a2} may consist of an aromatic hydrocarbon ring, or may be composed of a fused ring formed by an aromatic hydrocarbon ring and an aliphatic hydrocarbon ring. Note that, na1 OH and na2 R^{a13} are bonded to the aromatic hydrocarbon ring that Ar^{a2} has.

The aromatic hydrocarbon ring that Ar^{a2} has may be a monocyclic aromatic hydrocarbon ring or a polycyclic aromatic hydrocarbon ring. The polycyclic aromatic hydrocarbon ring may be a fused ring of two or more monocyclic aromatic hydrocarbon rings, or a monocyclic aromatic hydrocarbon ring or a fused ring attached to each other via a single bond. The aromatic hydrocarbon ring is preferably 6 or more and 30 or less carbon atoms, more preferably 6 or more and 20 or less carbon atoms, further preferably 6 or more and 15 or less carbon atoms, and particularly preferably 6 or more and 12 or less carbon atoms. Examples of the aromatic hydrocarbon ring that Ar^{a2} has include a benzene ring, a naphthalene ring, a biphenyl ring, an anthracene ring, a phenanthrene ring, etc. Among these, a benzene ring or a naphthalene ring is preferred and a benzene ring is more preferred. Examples of an aliphatic hydrocarbon ring that forms a fused ring together with the aromatic hydrocarbon ring that Ar^{a2} has include a cyclopentene ring, a norbornane ring, or a norbornene ring.

A divalent linking group for R^{a12} may be a divalent hydrocarbon group that may have a substituent. The hydrocarbon group for R^{a12} may be an aliphatic hydrocarbon group or a combination of an aliphatic hydrocarbon group and an aromatic hydrocarbon group.

The aliphatic hydrocarbon group for R^{a12} may be a saturated aliphatic hydrocarbon group or an unsaturated aliphatic hydrocarbon group, and is preferably a saturated aliphatic hydrocarbon group. The aliphatic hydrocarbon group for R^{a12} may be a chain aliphatic hydrocarbon group, an alicyclic hydrocarbon group, or a combination of a chain aliphatic hydrocarbon group and an alicyclic hydrocarbon group. The chain aliphatic hydrocarbon group included in the aliphatic hydrocarbon group for R^{a12} may be linear or branched.

The linear aliphatic hydrocarbon group preferably has 1 or more and 10 or less carbon atoms, more preferably 1 or more and 6 or less carbon atoms, further preferably 1 or more and 4 or less carbon atoms, and most preferably 1 or more and 3 or less carbon atoms. The linear aliphatic hydrocarbon group is preferably a linear alkylene group. Specific examples thereof include a methylene group [—CH₂—], an ethylene group [—(CH₂)₂—], a trimethylene group [—(CH₂)₃—], a tetramethylene group [—(CH₂)₄—], a pentamethylene group [—(CH₂)₅—], etc. The branched aliphatic hydrocarbon group preferably has 2 or more and 10 or less carbon atoms, more preferably 2 or more and 6 or less carbon atoms, and further preferably 2 or 3 carbon atoms. The branched aliphatic hydrocarbon group is preferably a branched alkylene group. Specific examples thereof include an alkylalkylene group, for example, an alkylmethylene group such as —CH(CH₃)—, —CH(CH₂CH₃)—, —C(CH₃)₂—, —C(CH₃) (CH₂CH₃)—, —C(CH₃) (CH₂CH₂CH₃)—, or —C(CH₂CH₃)₂—; an alkylethylene group such as —CH(CH₃)CH₂—, —CH(CH₃)CH(CH₃)—, —C(CH₃)₂CH₂—, —CH(CH₂CH₃)CH₂—, or —C(CH₂CH₃)₂—CH₂—; an alkyltrimethylene group such as —CH(CH₃)CH₂CH₂— or —CH₂CH(CH₃)CH₂—; or an alkyltetramethylene group such as —CH(CH₃)CH₂CH₂CH₂— or —CH₂CH(CH₃)CH₂CH₂—, etc. An alkyl group in the alkylalkylene group is preferably a linear alkyl group having 1 or more and 5 or less carbon atoms.

The linear or branched aliphatic hydrocarbon group may have a substituent. Examples of the substituent include a fluorine atom, a fluorinated alkyl group having 1 or more and 5 or less carbon atoms substituted with a fluorine atom, etc. At least one of methylene groups in the linear or branched aliphatic hydrocarbon group may be substituted with a divalent group other than a methylene group. Examples of the divalent group include —O—, —S—, —C(═O)—, etc.

The alicyclic hydrocarbon group preferably has 3 or more and 20 or less carbon atoms and more preferably 3 or more and 12 or less carbon atoms. The alicyclic hydrocarbon group may be a polycyclic group or a monocyclic group. A monocyclic aliphatic hydrocarbon group is preferably a group in which two hydrogen atoms are removed from a monocycloalkane. The monocycloalkane preferably has 3 or more and 6 or less carbon atoms. Specific examples of the monocycloalkane include cyclopentane, cyclohexane, etc. A polycyclic aliphatic hydrocarbon group is preferably a group in which two hydrogen atoms are removed from a polycycloalkane. The polycycloalkane preferably has 7 or more and 12 or less carbon atoms. Specific examples of the polycycloalkane include adamantane, norbornane, isobornane, tricyclodecane, tetracyclododecane, etc.

The alicyclic hydrocarbon group may or may not have a substituent. Examples of the substituent include an alkyl group, an alkoxy group, a halogen atom, a halogenated alkyl group, a hydroxy group, etc. The alkyl group serving as the substituent is preferably an alkyl group having 1 or more and 5 or less carbon atoms and more preferably a methyl group, an ethyl group, an n-propyl group, an n-butyl group, or a tert-butyl group. The alkoxy group serving as the substituent is preferably an alkoxy group having 1 or more and 5 or less carbon atoms, more preferably a methoxy group, an ethoxy group, an n-propyloxy group, an isopropyloxy group, an n-butyloxy group, or a tert-butyloxy group, and further preferably a methoxy group or an ethoxy group. The halogen atom serving as the substituent is preferably a fluorine atom. Examples of the halogenated alkyl group serving as the substituent include a group in which a part or all of hydrogen atoms in the alkyl group are substituted with the halogen atom. At least one of carbon atoms constituting a cyclic structure in the alicyclic hydrocarbon group may be substituted with a group including a heteroatom. The group including a heteroatom is preferably —O—, —C(═O)—O—, —S—, —S(═O)₂—, or —S(═O)₂—O—.

R^{a12} is preferably a single bond or a linear or branched aliphatic hydrocarbon group that may have a substituent, more preferably a single bond or a linear or branched aliphatic hydrocarbon group, and further preferably a linear or branched aliphatic hydrocarbon group. The linear or branched aliphatic hydrocarbon group is preferably an alkylene group having 1 or more and 6 or less carbon atoms, more preferably an alkylene group having 1 or more and 5 or less carbon atoms, further preferably a methylene group, an ethylene group, a propan-1,3-diyl group, a propan-2,2-diyl group, or a propan-1,2-diyl group, particularly preferably a methylene group or an ethylene group, and most preferably a methylene group.

The hydrocarbon group for R^{a13} may be a linear hydrocarbon group, a branched hydrocarbon group, a cyclic hydrocarbon group, or a combination of two or more thereof, and is preferably a linear hydrocarbon group and a branched hydrocarbon group. The hydrocarbon group for R^{a13} may be a saturated hydrocarbon group or an unsaturated hydrocarbon group, and is preferably a saturated hydrocarbon group. The hydrocarbon group for R^{a13} preferably has 1 or more and 5 or less carbon atoms. The hydrocarbon group for R^{a13} is more preferably a methyl group, an ethyl group, an n-propyl group, or an isopropyl group, further preferably a methyl group or an ethyl group, and particularly preferably a methyl group.

na1 is preferably 1.

na2 is preferably an integer of 0 or more and 2 or less, more preferably 0 or 1, and further preferably 0.

Specific examples of a constituent unit (a2-1) are shown below:

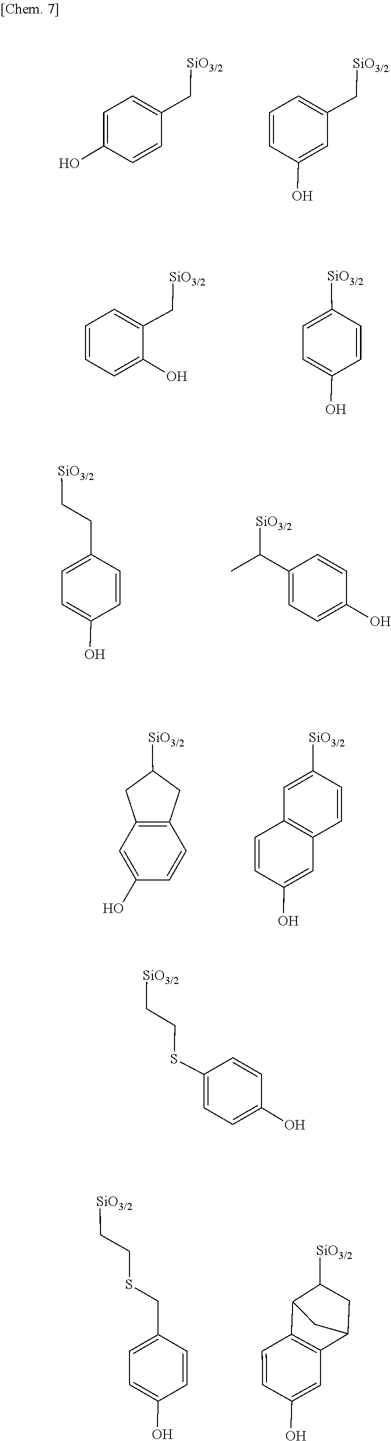

The constituent unit (a2-1) is preferably a constituent unit having any of structures below:

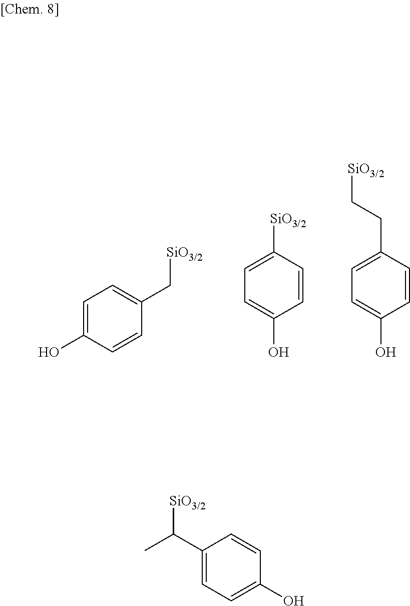

A constituent unit (a2) that a polysiloxane has may be one or two or more. When the polysiloxane has the constituent unit (a2), a proportion of the constituent unit (a2) in the polysiloxane is preferably 10% by mole or more, more preferably 20% by mole or more, and further preferably 30% by mole or more relative to a total (100% by mole) of all constituent units constituting the polysiloxane. The proportion is preferably 90% by mole or less, more preferably 80% by mole or less, and further preferably 70% by mole or less.

### [Other Constituent Units]

A polysiloxane may have a constituent unit other than the constituent unit (a1) or the constituent unit (a2) (hereinafter may be referred to as “other constituent units”). Examples of the other constituent units include a constituent unit (a3) including a hydrocarbon group or a constituent unit (a4) represented by Formula (a4).

(Constituent Unit (a3))

A constituent unit (a3) is a constituent unit including a hydrocarbon group. Examples of the constituent unit (a3) include a constituent unit including a Si—O bond as a main chain portion and a hydrocarbon group as a side chain portion attached to the Si atom. A presence of the constituent unit (a3) makes it easy to control a property of a cured film (silicon-containing resin film) formed using a photosensitive composition.

The constituent unit (a3) is preferably a constituent unit (a3-1) represented by Formula (a3-1) below or a constituent unit (a3-2) represented by Formula (a3-2) below:

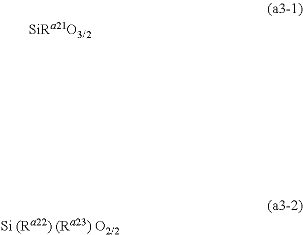

in which R^{a21} to R^{a23} are each independently a hydrogen atom or a hydrocarbon group that may have a substituent.

In Formulae (a3-1) and (a3-2), the hydrocarbon group for R^{a21} to R^{a23} may be an aliphatic hydrocarbon group or an aromatic hydrocarbon group. The aliphatic hydrocarbon group may be a saturated aliphatic hydrocarbon group or an unsaturated aliphatic hydrocarbon group. A structure of the aliphatic hydrocarbon group may be linear, branched, cyclic, or a combination of these structures. The aliphatic hydrocarbon group for R^{a21} to R^{a23} may have a substituent. Examples of the substituent include a hydroxy group, an alkoxy group having 1 or more and 5 or less carbon atoms, a mercapto group, an amino group, etc. R^{a21} to R^{a23} is preferably a hydrogen atom, an alkyl group, or an alkenyl group. The alkyl group for R^{a21} to R^{a23} preferably has 1 or more and 10 or less carbon atoms, more preferably 1 or more and 5 or less carbon atoms, and further preferably 1 or more and 3 or less carbon atoms. Examples of the alkyl group for R^{a21} to R^{a23} include a methyl group, an ethyl group, an n-propyl group, an n-butyl group, an n-pentyl group, an n-hexyl group, an n-octyl group, an n-decyl group, an isopropyl group, an isobutyl group, a sec-butyl group, a tert-butyl group, a 2-ethylhexyl group, etc. Among these, a methyl group, an ethyl group, an n-propyl group, an n-butyl group, an n-pentyl group, an isopropyl group, an isobutyl group, a sec-butyl group, or a tert-butyl group is preferred, a methyl group, an ethyl group, an n-propyl group, or an isopropyl group is more preferred, a methyl group or an ethyl group is further preferred, and a methyl group is particularly preferred. The alkenyl group for R^{a21} to R^{a23} preferably has 2 or more and 10 or less carbon atoms, more preferably 2 or more and 5 or less carbon atoms, and further preferably 2 or 3 carbon atoms. The alkenyl group for R^{a21} to R^{a23} is preferably a vinyl group or an allyl group. Examples of the aromatic hydrocarbon ring constituting an aromatic hydrocarbon group include a benzene ring, a fluorene ring, a naphthalene ring, an anthracene ring, a phenanthrene ring, a biphenyl ring, etc. Examples of the aromatic hydrocarbon group include a group in which one hydrogen atom is removed from the above-described aromatic hydrocarbon ring (aryl group), etc. Specific suitable examples of the aromatic hydrocarbon group include a phenyl group, a naphthalene-1-yl group, a naphthalene-2-yl group, etc.

A constituent unit (a3) that a polysiloxane has may be one or two or more. When the polysiloxane has the constituent unit (a3), a proportion of the constituent unit (a3) in the polysiloxane is preferably 10 mol % or more and 60 mol % or less, more preferably 20 mol % or more and 55 mol % or less, and further preferably 30 mol % or more and 50 mol % or less relative to a total (100% by mole) of all constituent units constituting the polysiloxane.

(Constituent Unit (a4))

A constituent unit (a4) is a constituent unit represented by Formula (a4) below. The constituent unit (a4) is useful for enhancing a lithographic property. Introduction of the constituent unit (a4) makes it easier to control a dissolution rate.

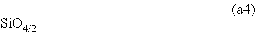

When the polysiloxane has the constituent unit (a4), a proportion of the constituent unit (a4) in the polysiloxane is preferably 10 mol % or more and 60 mol % or less, more preferably 20 mol % or more and 55 mol % or less, and further preferably 30 mol % or more and 50 mol % or less relative to a total (100% by mole) of all constituent units constituting the polysiloxane.

Specific examples of other constituent units (constituent unit (a3) and constituent unit (a4)) will be shown below:

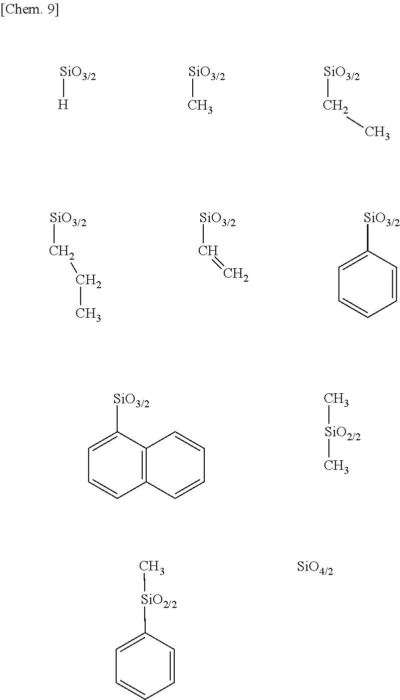

The other constituent units (constituent unit (a3) and constituent unit (a4)) preferably have structures below:

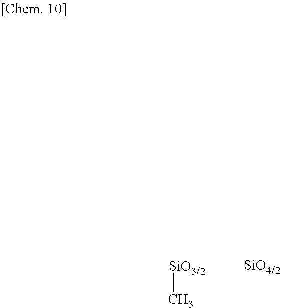

A polysiloxane may, for example, have a terminal structure represented by any of formulae below. In the structures below, * represents an atomic bond.

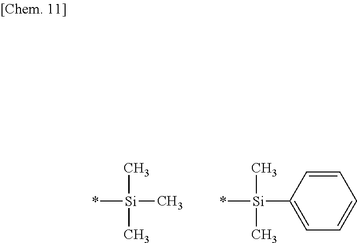

Among polysiloxanes, a silsesquioxane resin having a constituent unit represented by Formula (a1), a constituent unit represented by Formula (a2), and a constituent unit represented by Formula (a4), or a silsesquioxane resin having a constituent unit represented by Formula (a1), a constituent unit represented by Formula (a2), and a constituent unit represented by Formula (a3) is preferred.

A mass average molecular weight (Mw) (in terms of polystyrene by gel permeation chromatography (GPC)) of a silicon-containing resin (A) such as a polysiloxane is not particularly limited and is, for example, 1000 or more, preferably 1000 or more and 10000 or less, more preferably 1300 or more and 9000 or less, and further preferably 1500 or more and 8000 or less.

A proportion of a mass of a silicon-containing resin (A) to a mass of a solid content of a photosensitive composition is preferably 10% by mass or more, more preferably 20% by mass or more, further preferably 30% by mass or more and 75% by mass or less, particularly preferably 40% by mass or more and 70% by mass or less, and most preferably 50% by mass or more and 70% by mass or less. When the proportion of a mass of a silicon-containing resin (A) falls within the above-described preferred range, a film with good etching resistance is formed using a photosensitive composition. Note that, the “solid component of a photosensitive composition” is defined as a component of the photosensitive composition except for an organic solvent (S).

A silicon-containing resin (A) having an aromatic group substituted with one or more iodine atoms can be synthesized by a well-known reaction. For example, it can be produced by reacting a silicon-containing resin having a phenolic hydroxy group such as a silicon-containing resin having a constituent unit (a2) with an iodine element in an organic solvent such as tetrahydrofuran in the presence of sodium hydroxide to thereby substitute a hydrogen atom attached to a carbon atom adjacent to a carbon atom to which the phenolic hydroxy group is bonded with an iodine atom. It can also be produced by esterifying at least one of phenolic hydroxy groups in a silicon-containing resin having a phenolic hydroxy group such as a silicon-containing resin having a constituent unit (a2) with iodobenzoic acid in an organic solvent such as N,N-dimethylformamide in the presence of a catalyst such as dimethylaminopyridine or a condensing agent such as 1-(3-dimethylaminopropyl)-3-ethylcarbodiimide hydrochloride.

Note that, the silicon-containing resin (A) having an aromatic group substituted with one or more iodine atoms is a new resin. A silicon-containing resin (A), for example, a silicon-containing resin having a constituent unit (a1) represented by Formula (a1) can be contained in a photosensitive composition other than the above-described photosensitive composition, and can also be used for an application other than a photosensitive composition.

### <Photoacid Generating Agent(B)>

A photosensitive composition includes a photoacid generating agent (B) in addition to the silicon-containing resin (A). When the photosensitive composition is exposed, cross-linking of the silicon-containing resin (A) proceeds under action of an acid generated by the photoacid generating agent (B). The photoacid generating agent (B) is a compound that generates an acid upon irradiation with (exposure to) active light or radiation. The photoacid generating agent (B) may be a known photoacid generating agent that has conventionally been used in a photosensitive resin composition. An anion constituting the photoacid generating agent (B) may or may not have an iodine atom. A cation constituting the photoacid generating agent (B) may or may not have an iodine atom. The photoacid generating agent (B) preferably includes an onium salt composed of an organosulfonic acid anion having 1 or more and 40 or less carbon atoms and an organosulfonium ion or an organoiodonium ion. In other words, the photoacid generating agent (B) preferably includes an onium salt composed of an organosulfonic acid anion having 1 or more and 40 or less carbon atoms and an organosulfonium ion, or an onium salt composed of an organosulfonic acid anion having 1 or more and 40 or less carbon atoms and an organoiodonium ion. The onium salt composed of an organosulfonic acid anion having 1 or more and 40 or less carbon atoms and an organosulfonium ion serving as the photoacid generating agent (B) may be a photoacid generating agent including a sulfonium cation without a fluorine atom, but is preferably a photoacid generating agent (B1) including a sulfonium cation having a fluorine atom as described below. The onium salt composed of an organosulfonic acid anion having 1 or more and 40 or less carbon atoms and an organoiodonium ion serving as the acid generating agent (B) is preferably a photoacid generating agent (B2) including an iodonium cation as described below.

### [Photo Acid Generating Agent (B1) Including Sulfonium Cation Having Fluorine Atom]

A photoacid generating agent (B1) is a sulfonium salt that has a sulfonium cation having a fluorine atom as a cationic moiety. An anionic moiety and a cationic moiety in the photoacid generating agent (B1) are not particularly limited as long as the sulfonium cation serving as the cationic moiety has a fluorine atom.

Specific preferred examples of the photoacid generating agent (B1) include a sulfonium salt represented by Formula (b0-1) below:

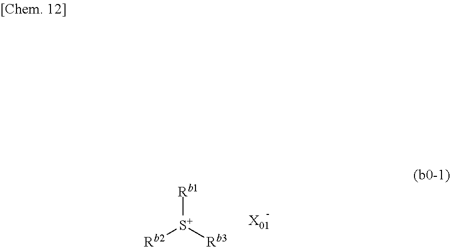

in which R^{b1} is an aryl group having a fluorine atom or an aryl group having a fluorinated alkyl group;
   R^{b2} and R^{b3} are each independently an aryl group that may have a substituent, an alkyl group that may have a substituent, or an alkenyl group that may have a substituent;
   two of R^{b1} to R^{b3} may be linked to each other to form a ring together with a sulfur atom in the formula; and X₀₁⁻ is a counter anion.
   (Cationic Moiety in Formula (b0-1))

In Formula (b0-1), R^{b1} is an aryl group having a fluorine atom or an aryl group having a fluorinated alkyl group. An aromatic hydrocarbon ring constituting the aryl group having a fluorine atom or the aryl group having a fluorinated alkyl group serving as R^{b1} preferably has 6 or more and 30 or less carbon atoms, more preferably 6 or more and 20 or less carbon atoms, further preferably 6 or more and 15 or less carbon atoms, and particularly preferably 6 or more and 10 or less carbon atoms. The aromatic hydrocarbon ring constituting the aryl group having a fluorine atom or the aryl group having a fluorinated alkyl group serving as R^{b1} is preferably a benzene ring, a naphthalene ring, an anthracene ring, a phenanthrene ring, or a biphenyl ring, more preferably a benzene ring or a naphthalene ring, and further preferably a benzene ring.

Examples of a fluorinated alkyl group constituting the aryl group having a fluorinated alkyl group include a group in which a part or all of hydrogen atoms in an alkyl group are substituted with a fluorine atom. The fluorinated alkyl group preferably has 1 or more and 12 or less carbon atoms, more preferably 1 or more and 8 or less carbon atoms, further preferably 1 or more and 5 or less carbon atoms, and particularly preferably 1 or more and 3 or less carbon atoms. The fluorinated alkyl group may be linear or branched.

Examples of a linear fluorinated alkyl group having 1 or more and 12 or less carbon atoms include a group in which a part or all of hydrogen atoms in a methyl group, an ethyl group, an n-propyl group, an n-butyl group, an n-pentyl group, an n-hexyl group, an n-heptyl group, an n-octyl group, an n-nonyl group, an n-decyl group, an n-undecyl group, or an n-dodecyl group is substituted with a fluorine atom.

Examples of a branched fluorinated alkyl group having 1 or more and 12 or less carbon atoms include a group in which a part or all of hydrogen atoms in a 1-methylethyl group (isopropyl group), a 1-methylpropyl group (sec-butyl group), a 2-methylpropyl group (isobutyl group), a 1-methylbutyl group (sec-pentyl group), a 2-methylbutyl group, a 3-methylbutyl group (isopentyl group), a 1-ethylbutyl group, a 2-ethylbutyl group, a 1-methylpentyl group, a 2-methylpentyl group, a 3-methylpentyl group, or a 4-methylpentyl group (isohexyl group) is substituted with a fluorine atom.

Among the above-described fluorinated alkyl groups, a trifluoromethyl group is particularly preferred.

The aryl group having a fluorine atom or the aryl group having a fluorinated alkyl group for R^{b1} may have another substituent other than a fluorine atom or a fluorinated alkyl group on an aromatic hydrocarbon ring. Examples of the other substituent include an alkyl group, a halogen atom other than a fluorine atom, a halogenated alkyl group other than a fluorinated alkyl group, an oxo group (=O), a cyano group, an amino group, an aryl group, a group represented by each of Formulae (ca-r-1) to (ca-r-7), or a group represented by —SO₂—R^{b0}. R^{b0} is an alkyl group that may have a substituent, an alicyclic hydrocarbon group that may have a substituent, or an aromatic hydrocarbon group that may have a substituent. The alkyl group for R^{b0} may be linear or branched.

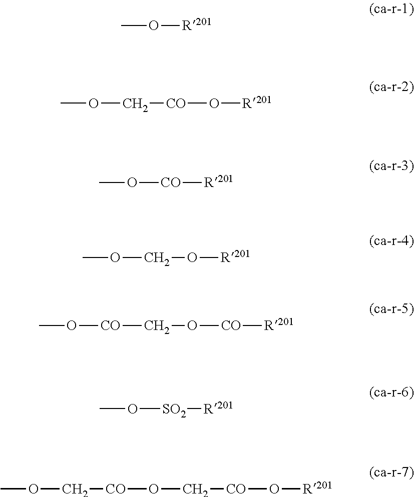

In Formulae (ca-r-1) to (ca-r-7), R′²⁰¹ are each independently a hydrogen atom, a cyclic group that may have a substituent, an alkyl group that may have a substituent, an aralkyl group that may have a substituent, or an alkenyl group that may have a substituent.

A cyclic group constituting the cyclic group that may have a substituent for R′²⁰¹ is not particularly limited. The cyclic group may be a cyclic hydrocarbon group or a heterocyclic group. The heterocyclic group may include a heteroatom such as a nitrogen atom, an oxygen atom, or a sulfur atom as a ring member atom. The heterocyclic group may be an aromatic heterocyclic group or an aliphatic heterocyclic group.

The cyclic group is preferably a cyclic hydrocarbon group. The cyclic hydrocarbon group may be an aromatic hydrocarbon group or a cyclic aliphatic hydrocarbon group. The cyclic aliphatic hydrocarbon group means a hydrocarbon group that is not aromatic. The cyclic aliphatic hydrocarbon group may have one or more unsaturated bonds. The cyclic hydrocarbon group is preferably a saturated cyclic aliphatic hydrocarbon group.

An aromatic hydrocarbon ring constituting the aromatic hydrocarbon group that may have a substituent for R′²⁰¹ preferably has 6 or more and 30 or less carbon atoms, more preferably 6 or more and 20 or less carbon atoms, further preferably 6 or more and 15 or less carbon atoms, and particularly preferably 6 or more and 12 or less carbon atoms. The aromatic hydrocarbon ring constituting the aromatic hydrocarbon group that may have a substituent for R′²⁰¹ is preferably a benzene ring, a fluorene ring, a naphthalene ring, an anthracene ring, a phenanthrene ring, or a biphenyl ring.

Examples of an aromatic hydrocarbon ring constituting the aralkyl group that may have a substituent for R′²⁰¹ include a benzene ring, a fluorene ring, a naphthalene ring, an anthracene ring, a phenanthrene ring, a biphenyl ring, etc. An alkylene group constituting the aralkyl group that may have a substituent for R′²⁰¹ is preferably an alkylene group having from 1 or more and 4 or less carbon atoms, more preferably a methylene group or an ethan-1,2-diyl group (ethylene group), and further preferably a methylene group.

An aliphatic hydrocarbon ring constituting the cyclic aliphatic hydrocarbon group that may have a substituent for R′²⁰¹ preferably has 3 or more and 30 or less carbon atoms, more preferably 3 or more and 20 or less carbon atoms, and further preferably 3 or more and 12 or less carbon atoms. The cyclic aliphatic hydrocarbon group that may have a substituent may be a group in which one hydrogen atom is removed from a monocycloalkane that may have a substituent or a group in which one hydrogen atom is removed from a polycycloalkane that may have a substituent.

A number of carbon atoms in the monocycloalkane that may have a substituent is preferably 3 or more and 6 or less. Note that, a number of carbon atoms in the substituent is not included in the number of carbon atoms in the monocycloalkane. The monocycloalkane that may have a substituent is preferably cyclopentane that may have a substituent or cyclohexane that may have a substituent.

The polycycloalkane that may have a substituent preferably has 7 or more and 30 or less carbon atoms. The polycycloalkane that may have a substituent is preferably a polycycloalkane having a polycyclic backbone of a bridged ring system that may have a substituent or a fused ring aliphatic hydrocarbon ring having a steroid backbone that may have a substituent. Examples of the polycycloalkane include adamantane, norbornane, isobornane, tricyclodecane, tetracyclododecane, etc.

The heterocyclic group for R′²⁰¹ may be lactone-containing cyclic groups represented by Formulae (a2-r-1) to (a2-r-7) below:

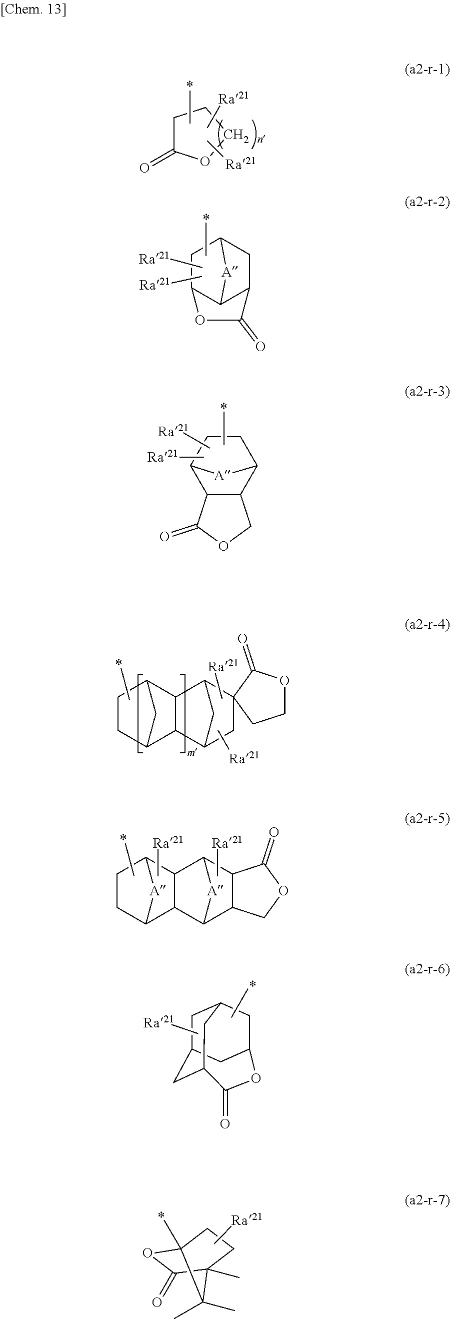

in which Ra′²¹ are each independently a hydrogen atom, an alkyl group, an alkoxy group, a halogen atom, a halogenated alkyl group, a hydroxy group, —CO—O—R″, —O—CO—R″, a hydroxyalkyl group, or a cyano group;
   R″ is a hydrogen atom, an alkyl group that may have a substituent, a cyclic aliphatic hydrocarbon group that may have a substituent, a lactone-containing cyclic group, a carbonate-containing cyclic group, or a —SO₂-containing cyclic group;
   A″ is an alkylene group having 1 or more and 5 or less carbon atoms and optionally interrupted by an oxygen atom or a sulfur atom, an oxygen atom, or a sulfur atom;
   n′ is an integer of 0 or more and 2 or less; and
   m′ is 0 or 1.

In Formulae (a2-r-1) to (a2-r-7), an alkyl group for Ra′²¹ preferably has 1 or more and 6 or less carbon atoms. The alkyl group for Ra′²¹ may be linear or branched.

Specific examples of the alkyl group for Ra′²¹ include a methyl group, an ethyl group, an n-propyl group, an isopropyl group, an n-butyl group, an isobutyl group, a sec-butyl group, a tert-butyl group, an n-pentyl group, an isopentyl group, a neopentyl group, an n-hexyl group, etc. Among these, a methyl group or an ethyl group is preferred, and a methyl group is more preferred.

The alkoxy group for Ra′²¹ preferably has 1 or more and 6 or less carbon atoms. The alkoxy group for Ra′²¹ may be linear or branched.

Specific examples of the alkoxy group for Ra′²¹ include a methoxy group, an ethoxy group, an n-propyloxy group, an isopropyloxy group, an n-butyloxy group, an isobutyloxy group, a sec-butyloxy group, a tert-butyloxy group, an n-pentyloxy group, an isopentyloxy group, a neopentyloxy group, an n-hexyloxy group, etc. Among these, a methoxy group or an ethoxy group is preferred, and a methoxy group is more preferred.

Examples of the halogen atom for Ra′²¹ include a fluorine atom, a chlorine atom, a bromine atom, or an iodine atom, with a fluorine atom being preferred.

Examples of the halogenated alkyl group for Ra′²¹ include a group in which a part or all of hydrogen atoms in the alkyl group for Ra′²¹ are substituted with a halogen atom. The halogenated alkyl group is preferably a fluorinated alkyl group and more preferably a perfluoroalkyl group.

R″ in —CO—O—R″ and —O—CO—R″ for Ra′²¹ is a hydrogen atom, an alkyl group that may have a substituent, a cyclic aliphatic hydrocarbon group that may have a substituent, a lactone-containing cyclic group, a carbonate-containing cyclic group, or a —SO₂-containing cyclic group.

The alkyl group that may have a substituent for R″ may be linear or branched. A number of carbon atoms in the alkyl group is preferably 1 or more and 15 or less, more preferably 1 or more and 10 or less, further preferably 1 or more and 5 or less, and particularly preferably 1 or 2. Note that, a number of carbon atoms in the substituent is not included in the number of carbon atoms in the alkyl group. The alkyl group for R″ is particularly preferably a methyl group or an ethyl group.

A number of carbon atoms in a cyclic aliphatic hydrocarbon group that may have a substituent for R″ is preferably 3 or more and 30 or less, more preferably 3 or more and 15 or less, further preferably 4 or more and 12 or less, and particularly preferably 5 or more and 10 or less. A number of carbon atoms in the substituent is not included in the number of carbon atoms in the cyclic aliphatic hydrocarbon group.

Examples of the cyclic aliphatic hydrocarbon group that may have a substituent include a group in which one hydrogen atom is removed from a monocycloalkane which is optionally substituted with a fluorine atom or a fluorinated alkyl group; a group in which one hydrogen atom is removed from a polycycloalkane such as a bicycloalkane, a tricycloalkane, or a tetracycloalkane, etc. More specific examples of the cyclic aliphatic hydrocarbon group include a group in which one hydrogen atom is removed from a monocycloalkane such as a cyclopentane or a cyclohexane; a group in which one or more hydrogen atoms are removed from a polycycloalkane such as adamantane, norbornane, isobornane, tricyclodecane, or tetracyclododecane, etc.

The lactone-containing cyclic group for R″ is a group represented by any of Formulae (a2-r-1) to (a2-r-7) above, and when Ra′²¹ is —CO—O—R″ or —O—CO—R″, R″ is not the lactone-containing cyclic group.

Suitable examples of the lactone-containing cyclic group represented by any of Formulae (a2-r-1) to (a2-r-7) include groups shown below:

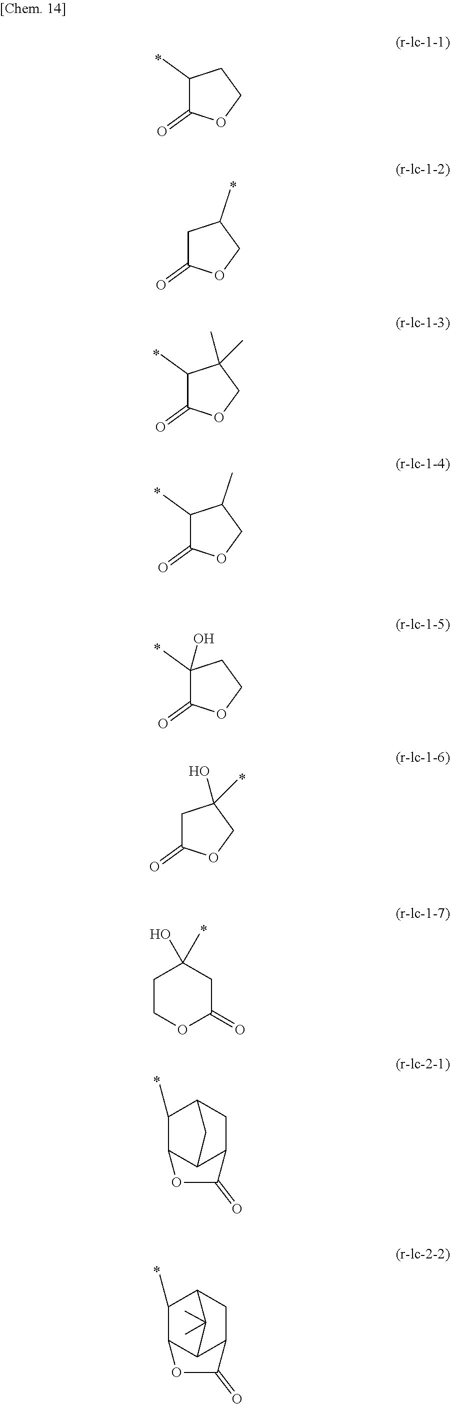

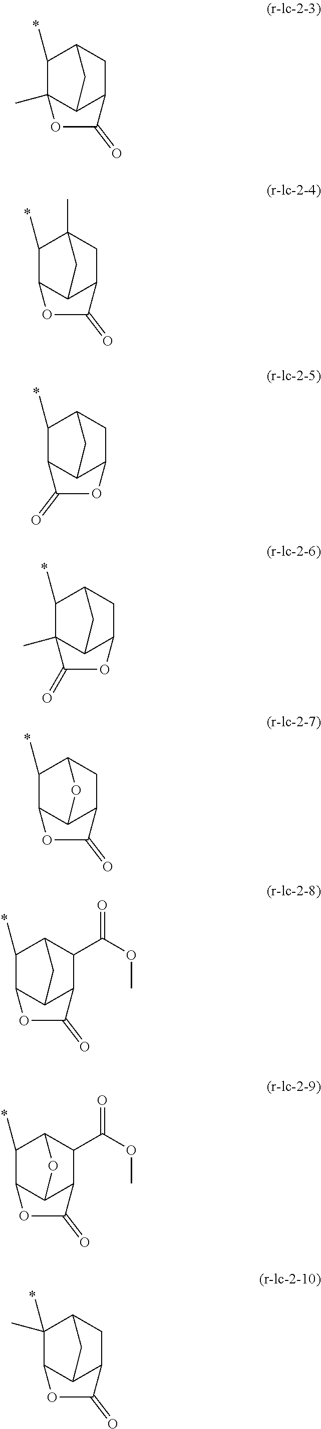

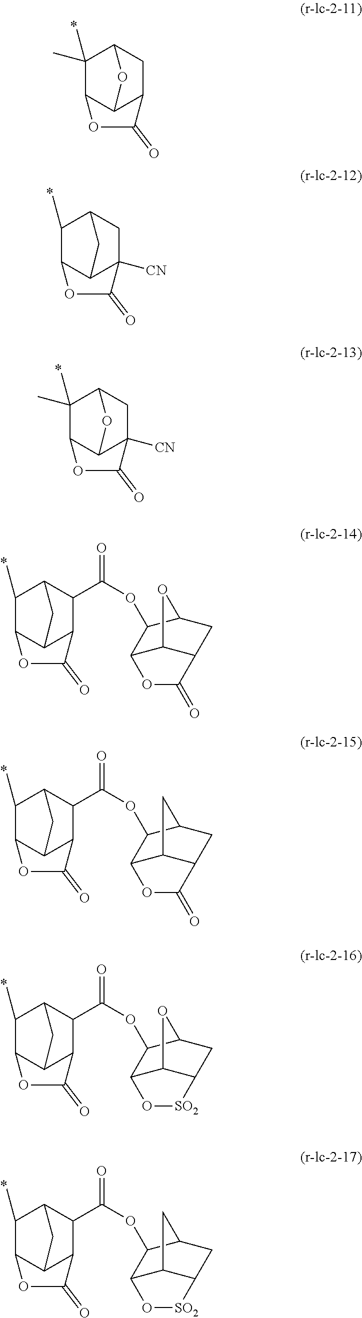

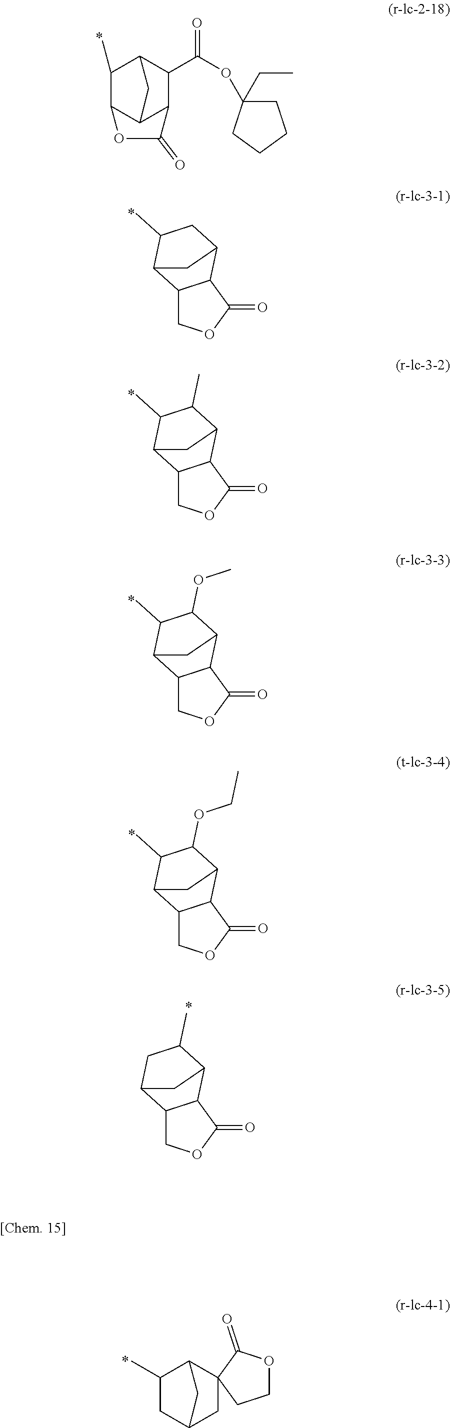

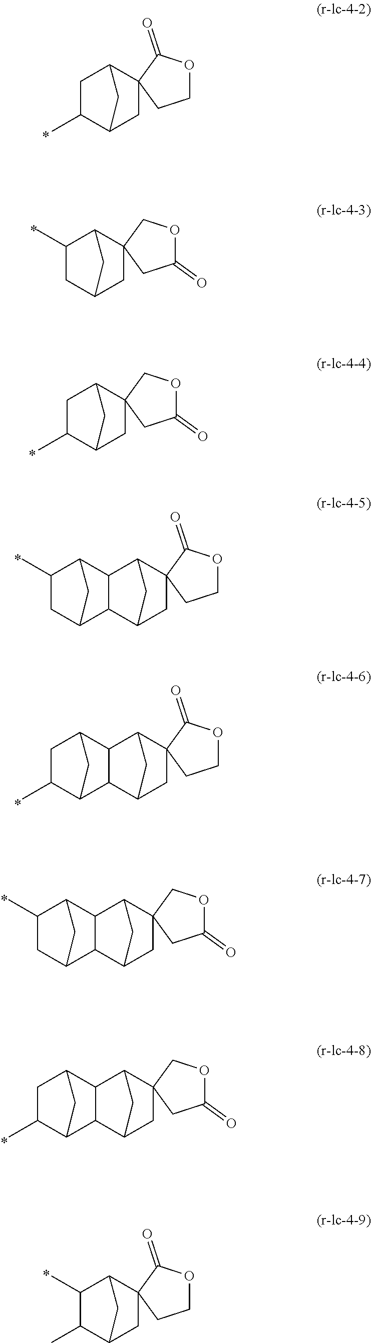

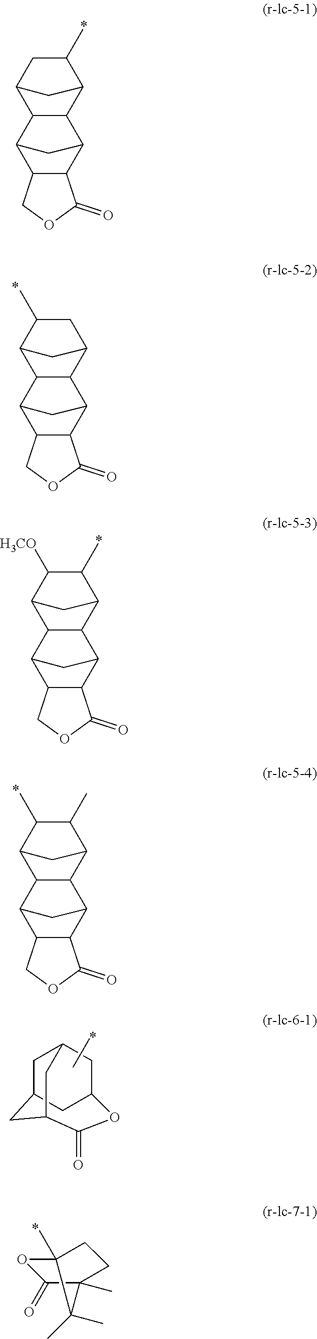

The carbonate-containing group for R″ is preferably a group represented by any of Formulae (ax3-r-1) to (ax3-r-3) below:

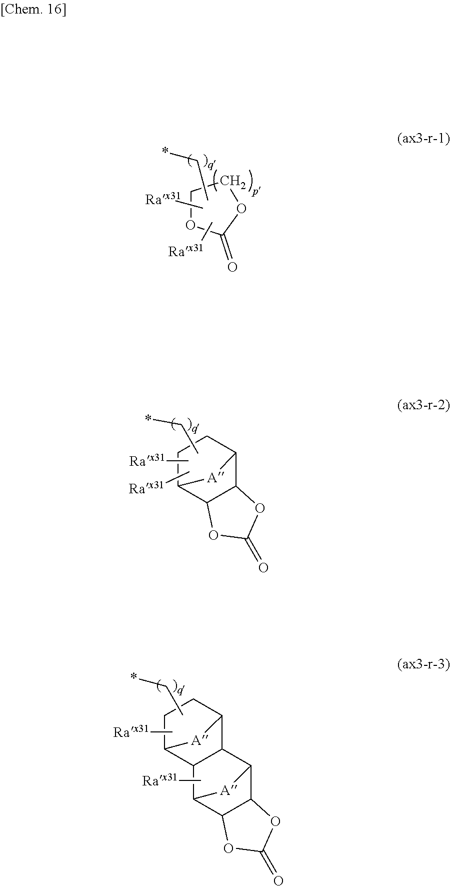

in which Ra′^{x31} are each independently a hydrogen atom, an alkyl group, an alkoxy group, a halogen atom, a halogenated alkyl group, a hydroxy group, —CO—O—R″, —O—CO—R″, a hydroxyalkyl group, or a cyano group;
   R″ is a hydrogen atom, an alkyl group that may have a substituent, a cyclic aliphatic hydrocarbon group that may have a substituent, a lactone-containing cyclic group, a carbonate-containing cyclic group, or a —SO₂-containing cyclic group;
   A″ is an alkylene group having 1 or more and 5 or less carbon atoms and optionally interrupted by an oxygen atom or a sulfur atom, an oxygen atom, or a sulfur atom;
   p′ is an integer of 0 or more and 3 or less; and
   q′ is 0 or 1.

The alkylene group for A″ in Formulae (ax3-r-1) to (ax3-r-3) may be linear or branched. Examples of the alkylene group for A″ include a methylene group, an ethan-1,2-diyl group, a propan-1,3-diyl group, a propan-1,2-diyl group, etc. Among these, a methyl group is preferred.

The alkylene group for A″ may be interrupted by an oxygen atom or a sulfur atom. Examples of an alkylene group interrupted by an oxygen atom or a sulfur atom include —CH₂—O—CH₂—, —CH₂—O—CH₂CH₂—, —CH₂—CH₂—O—CH₂—CH₂—, —CH₂—S—CH₂—, —CH₂—S—CH₂CH₂—, or —CH₂—CH₂—S—CH₂—CH₂—.

The alkyl group, the alkoxy group, the halogen atom, the halogenated alkyl group, the —CO—O—R″, the —O—CO—R″, and the hydroxyalkyl group for Ra′^{x31} are the same as the alkyl group, the alkoxy group, the halogen atom, the halogenated alkyl group, the —CO—O—R″, the —O—CO—R″, and the hydroxyalkyl group for Ra′²¹ in Formulae (a2-r-1) to (a2-r-7). However, the carbonate-containing cyclic group for R″ is a group represented by any of Formulae (ax3-r-1) to (ax3-r-3) above, and when Ra′^{x31} is —CO—O—R″ or —O—CO—R″, R″ is not the carbonate-containing cyclic group.

Suitable examples of the carbonate-containing cyclic group represented by any of Formulae (ax3-r-1) to (ax3-r-3) include groups shown below:

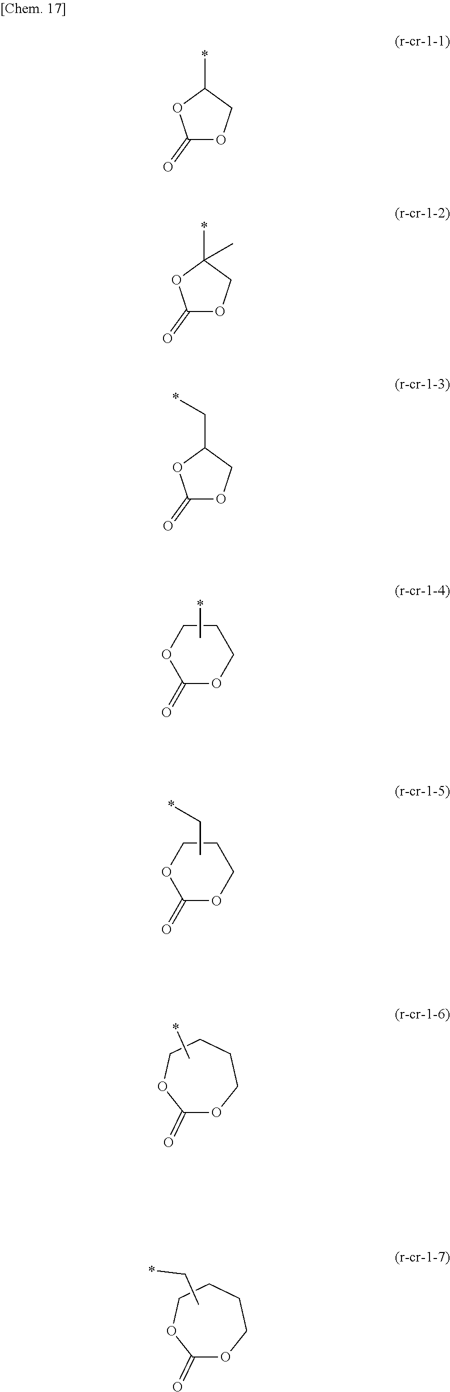

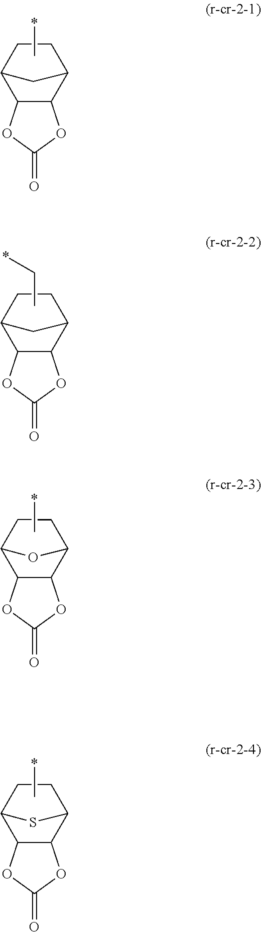

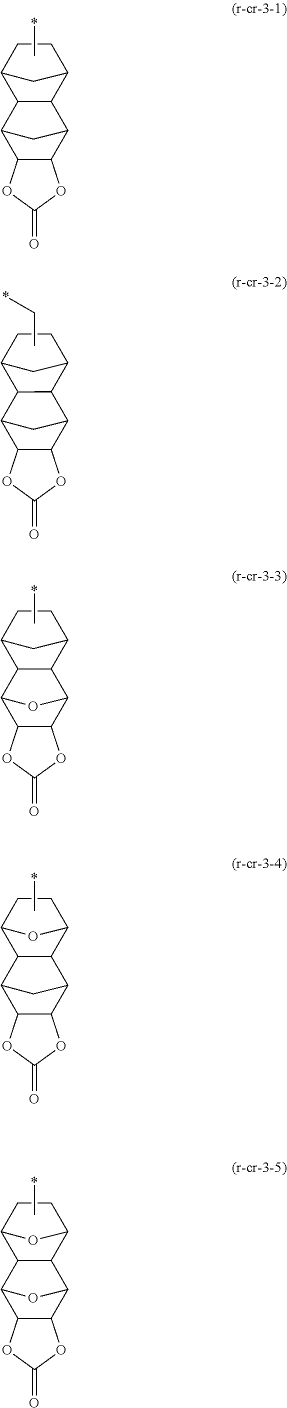

The —SO₂-containing group for R″ is preferably a group represented by any of Formulae (a5-r-1) to (a5-r-4) below:

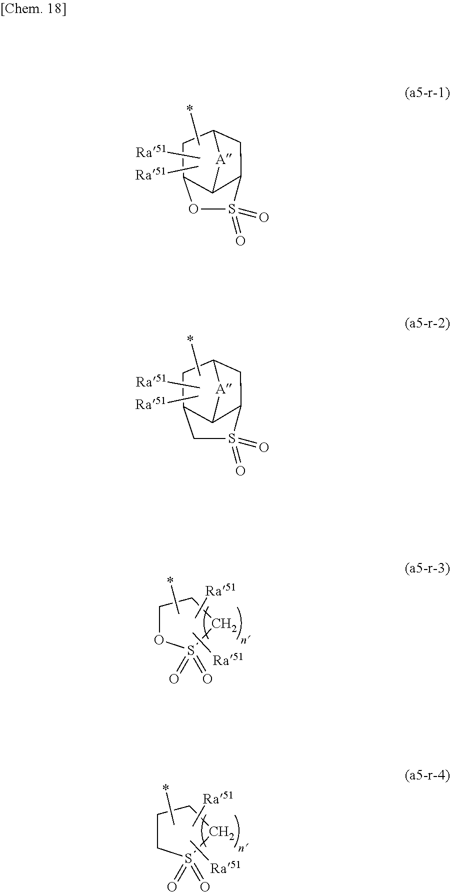

in which Ra′⁵¹ are each independently a hydrogen atom, an alkyl group, an alkoxy group, a halogen atom, a halogenated alkyl group, a hydroxy group, —CO—O—R″, —O—CO—R″, a hydroxyalkyl group, or a cyano group;
   R″ is a hydrogen atom, an alkyl group that may have a substituent, a cyclic aliphatic hydrocarbon group that may have a substituent, a lactone-containing cyclic group, a carbonate-containing cyclic group, or a —SO₂-containing cyclic group;
   A″ is an alkylene group having 1 or more and 5 or less carbon atoms that may be interrupted by an oxygen atom or a sulfur atom, an oxygen atom, or a sulfur atom; and
   n′ is an integer of 0 or more and 2 or less.

In Formulae (a5-r-1) to (a5-r-2), the alkylene group optionally interrupted by an oxygen atom or a sulfur atom for A″ is the same as the alkylene group optionally interrupted by an oxygen atom or a sulfur atom for A″ in Formulae (ax3-r-1) to (ax3-r-3).

The alkyl group, the alkoxy group, the halogen atom, the halogenated alkyl group, the —CO—O—R″, the —O—CO—R″, and the hydroxyalkyl group for Ra′⁵¹ are the same as the alkyl group, the alkoxy group, the halogen atom, the halogenated alkyl group, the —CO—O—R″, the —O—CO—R″, and the hydroxyalkyl group for Ra′²¹ in Formulae (a2-r-1) to (a2-r-7). However, the —SO₂-containing cyclic group for R″ is a group represented by any of Formulae (a5-r-1) to (a5-r-3) above, and when Ra′⁵¹ is —CO-0-R″ or —O—CO—R″, R″ is not the —SO₂-containing cyclic group.

Suitable examples of the —SO₂-containing cyclic group represented by any of Formulae (a5-r-1) to (a5-r-3) include groups shown below. Note that, Ac in formulae below is an acetyl group.

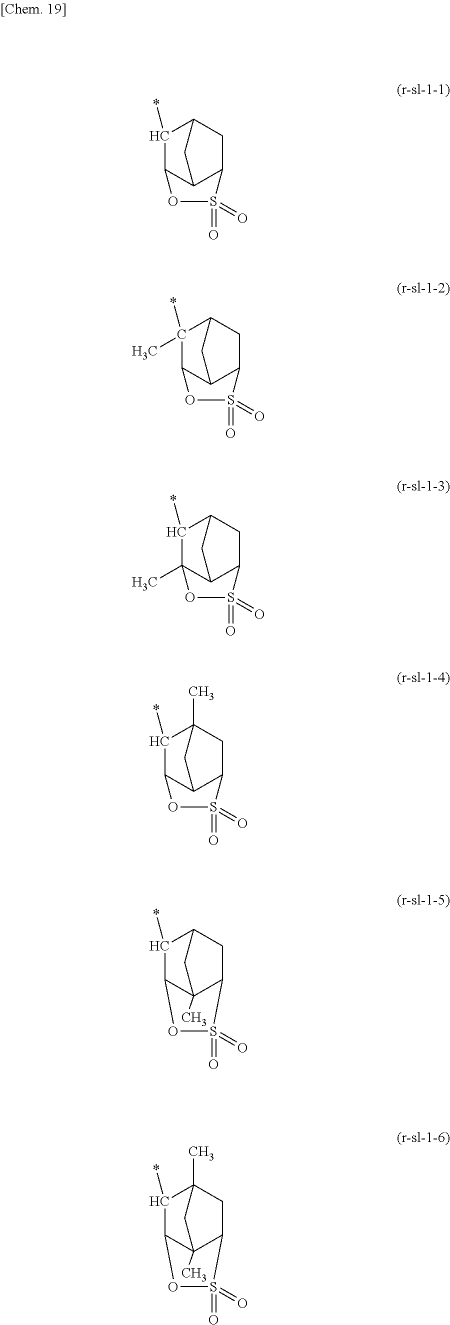 [SMILES: *C1C2CC3C1OS(=O)(=O)C3C2 ; *C1(C)C2CC3C1OS(=O)(=O)C3C2 ; *C1C2CC3C(C2)S(=O)(=O)OC13C ; *C1C2OS(=O)(=O)C3CC1(C)CC23 ; *C1C2CC3C(C)(C2)C1OS3(=O)=O ; *C1C2OS(=O)(=O)C3CC1(C)CC23C]

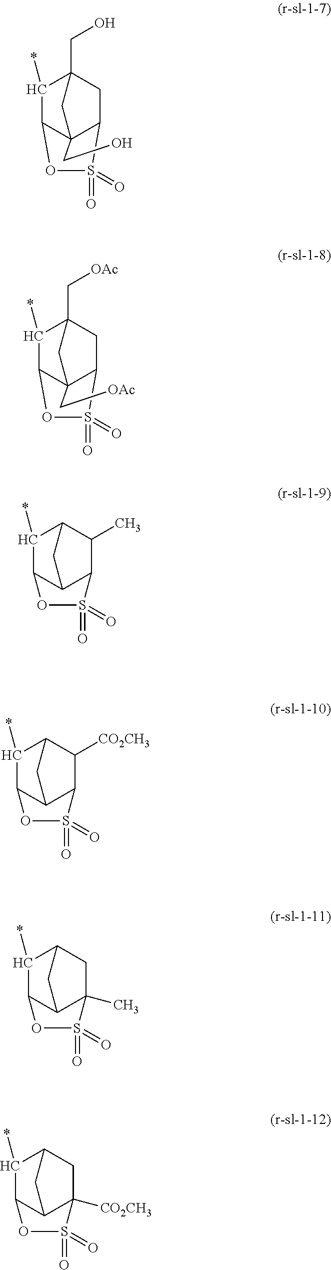 [SMILES: *C1C2OS(=O)(=O)C3CC1(CO)CC23CO ; *C1C2OS(=O)(=O)C3CC1(COC(C)=O)CC23COC(C)=O ; *C1C2CC3C1OS(=O)(=O)C3C2C ; *C1C2CC3C1OS(=O)(=O)C3C2C(=O)OC ; *C1C2CC3C1OS(=O)(=O)C3(C)C2 ; *C1C2CC3C1OS(=O)(=O)C3(C(=O)OC)C2]

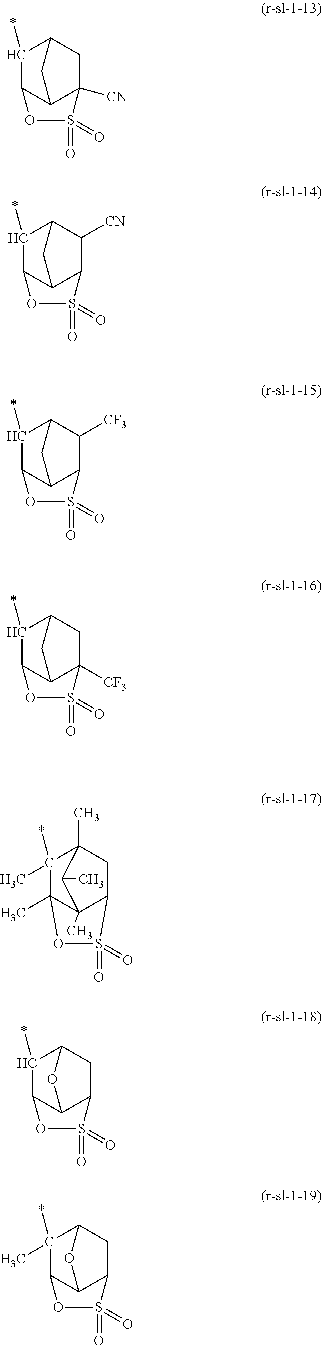

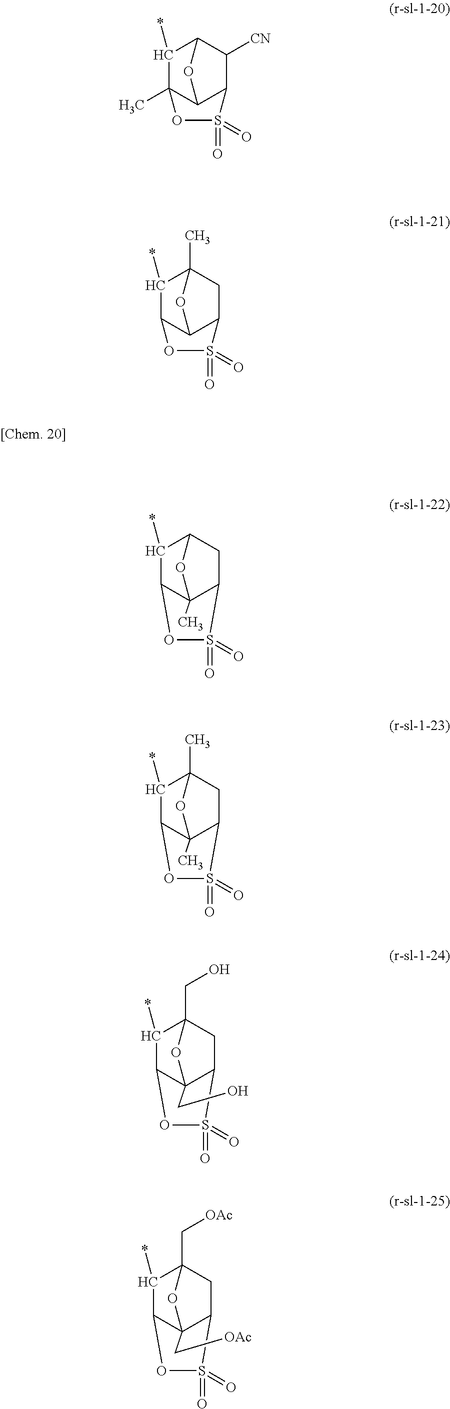 [SMILES: *C1C2OC3C(C2C#N)S(=O)(=O)OC13C ; *C1C2OS(=O)(=O)C3CC1(C)OC23 ; *C1C2CC3C(C)(O2)C1OS3(=O)=O ; *C1C2OS(=O)(=O)C3CC1(C)OC23C ; *C1C2OS(=O)(=O)C3CC1(CO)OC23CO ; *C1C2OS(=O)(=O)C3CC1(COC(C)=O)OC23COC(C)=O]

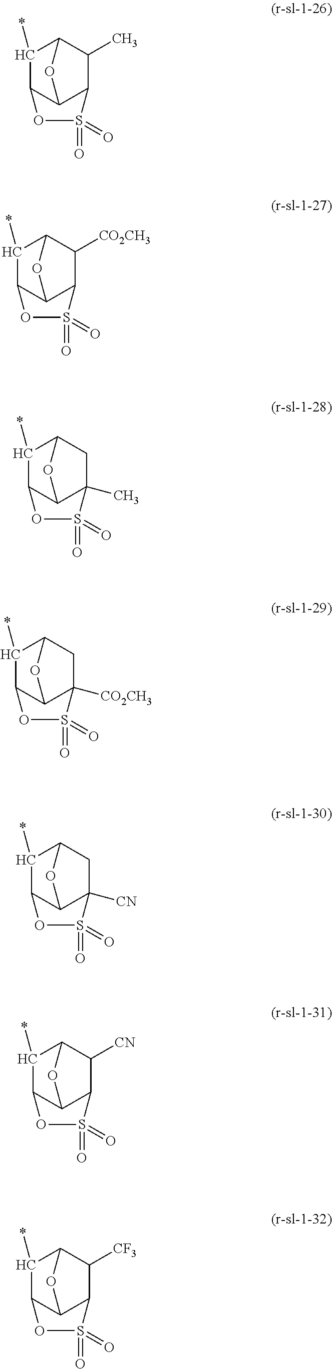

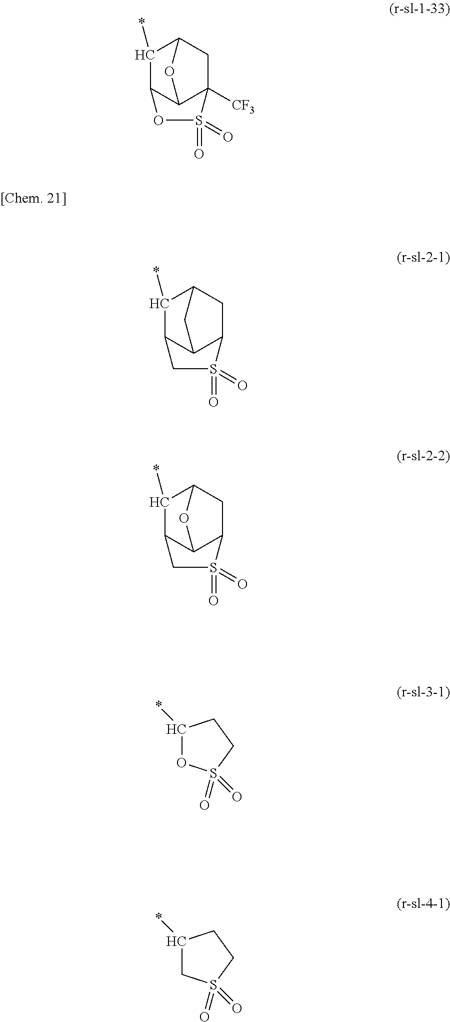 [SMILES: *C1C2CC3(C(F)(F)F)C(O2)C1OS3(=O)=O ; *C1C2CC3C1CS(=O)(=O)C3C2 ; *C1C2CC3C(O2)C1CS3(=O)=O ; *C1CCS(=O)(=O)O1 ; *C1CCS(=O)(=O)C1]

The hydroxyalkyl group for Ra′²¹ preferably has 1 or more and 6 or less carbon atoms. The hydroxyalkyl group may be linear or branched. A number of hydroxy groups included in the hydroxyalkyl group is not particularly limited and is preferably 1 or 2 and more preferably 1. Suitable examples of the hydroxyalkyl group include a hydroxymethyl group, a 2-hydroxyethyl group, or a 3-hydroxypropyl group.

In Formulae (a2-r-2), (a2-r-3), and (a2-r-5), A″ is an alkylene group having 1 or more and 5 or less carbon atoms and optionally interrupted by an oxygen atom or a sulfur atom, an oxygen atom, or a sulfur atom. A″ in Formulae (a2-r-2), (a2-r-3), and (a2-r-5) is the same as A″ described above for Formulae (ax3-r-1) to (ax3-r-3).

Specific examples of the lactone-containing group represented by any of Formulae (a2-r-1) to (a2-r-7) that is preferred as the heterocyclic group for R′²⁰¹ are the same as those of the lactone-containing cyclic group for R″ described for Formulae (a2-r-1) to (a2-r-7).

The above-described carbonate-containing cyclic group or the above-described —SO₂-containing cyclic group is also preferred as the heterocyclic group for R′²⁰¹.

A heterocyclic group represented by any of Formulae (r-hr-1) to (r-hr-16) below is also preferred as the heterocyclic group for R′²⁰¹.

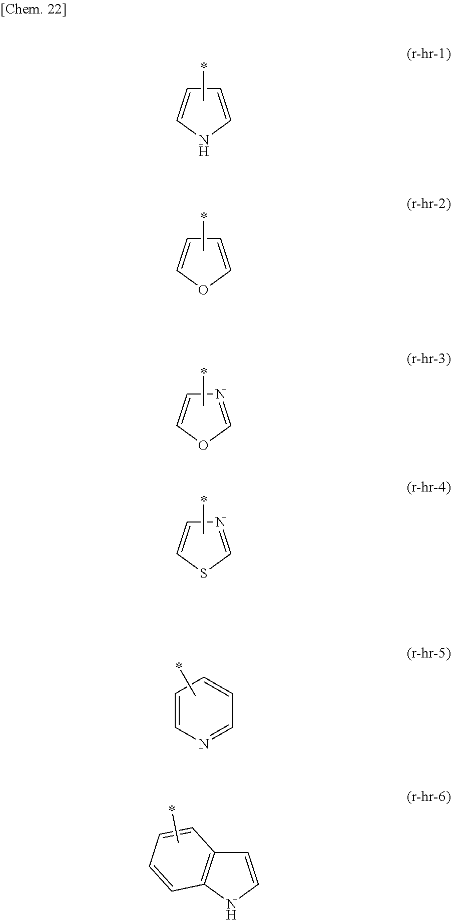

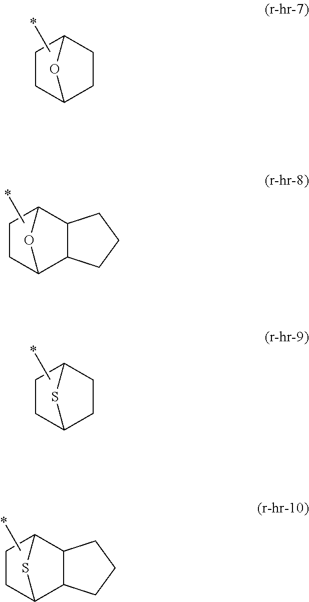

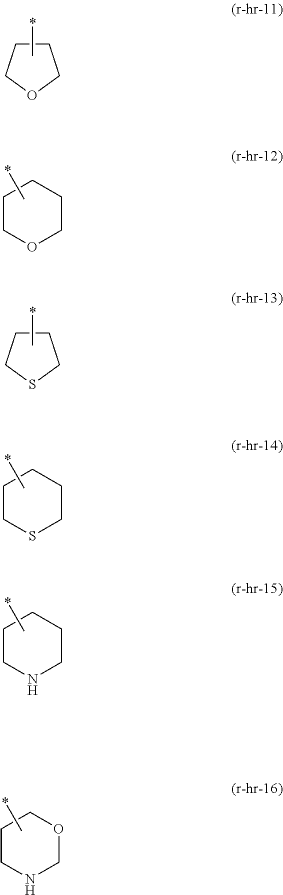

Examples of a substituent that the cyclic group for R′²⁰¹ may have include an alkyl group, an alkoxy group, a halogen atom, a halogenated alkyl group, a hydroxy group, an oxo group (═O), a nitro group, etc.

The alkyl group that may have a substituent for R′²⁰¹ may be linear or branched. A linear alkyl group has preferably 1 or more and 20 or less carbon atoms, more preferably 1 or more and 15 or less carbon atoms, and further preferably 1 or more and 10 or less carbon atoms. A branched alkyl group preferably has 3 or more and 20 or less carbon atoms, more preferably 3 or more and 15 or less carbon atoms, and further preferably 3 or more and 10 or less carbon atoms.

Specific examples of the alkyl group that may have a substituent for R′²⁰¹ include a 1-methylethyl group (isopropyl group), a 1-methylpropyl group (sec-butyl group), a 2-methylpropyl group (isobutyl group), a 1-methylbutyl group (sec-pentyl group), a 2-methylbutyl group, a 3-methylbutyl group (isopentyl group), a 1-ethylbutyl group, a 2-ethylbutyl group, a 1-methylpentyl group, a 2-methylpentyl group, a 3-methylpentyl group, or a 4-methylpentyl group (isohexyl group), etc.

The aralkyl group that may have a substituent for R′²⁰¹ preferably has 7 or more and 20 or less carbon atoms and more preferably 7 or more and 12 or less carbon atoms. Specific examples of the aralkyl group include a benzyl group, a phenethyl group, a 3-phenylpropyl group, a 4-phenylbutyl group, a naphthalene-1-ylmethyl group, a naphthalene-2-ylmethyl group, a naphthalene-1-ylethyl group, or a naphthalene-2-ylmethyl group, etc.

The alkenyl group that may have a substituent for R′²⁰¹ may be linear or branched. The alkenyl group has preferably 2 or more and 10 or less carbon atoms, more preferably 2 or more and 5 or less carbon atoms, and further preferably 2 or more and 4 or less carbon atoms.

Examples of a linear alkenyl group include a vinyl group, a 2-propenyl group (allyl group), a 1-propenyl group, a 3-butenyl group, a 2-butenyl group, a 1-butenyl group, etc. Examples of a branched alkenyl group include a 1-methylvinyl group, a 1-methyl-2-propenyl group, a 2-methyl-2-propenyl group, etc. The alkenyl group is preferably a linear alkenyl group, more preferably a vinyl group, a 2-propenyl group, or a 1-propenyl group, and further preferably a vinyl group.

Examples of a substituent that the cyclic group, the alkyl group, the aralkyl group, or the alkenyl group for R′²⁰¹ has include an alkyl group, an alkoxy group, a halogen atom, a halogenated alkyl group, a hydroxy group, an oxo group (═O), a cyano group, a nitro group, etc.

In a group represented by —SO₂—R^{b0} for R^{b1} in Formula (b0-1), R^{b0} is an alkyl group that may have a substituent, an alicyclic hydrocarbon group that may have a substituent, or an aromatic hydrocarbon group that may have a substituent.

The alkyl group that may have a substituent for R^{b0} may be linear or branched. Specific examples of the alkyl group that may have a substituent for R^{b0} include a methyl group, an ethyl group, an n-propyl group, an isopropyl group, an n-butyl group, an isobutyl group, a sec-butyl group, a tert-butyl group, an n-pentyl group, an isopentyl group, a neopentyl group, etc. Among these, a methyl group or an ethyl group is preferred, and a methyl group is more preferred.

For the alkyl group that may have a substituent for R^{b0}, examples of the substituent include a halogen atom, an alkoxy group having 1 or more and 5 or less carbon atoms, a hydroxy group, an oxo group (═O), a carboxy group, etc.

The alicyclic hydrocarbon group that may have a substituent for R^{b0} preferably has 3 or more and 20 or less carbon atoms and more preferably 3 or more and 12 or less carbon atoms. The alicyclic hydrocarbon group may be a monocyclic group or a polycyclic group. A monocyclic alicyclic hydrocarbon group is preferably a monocycloalkane or a group in which one hydrogen atom is removed from a polycycloalkane. The monocycloalkane preferably has 3 or more and 6 or less carbon atoms. Specific examples of the monocycloalkane include cyclobutane, cyclopentane, cyclohexane, etc. The polycycloalkane preferably has 7 or more and 20 or less carbon atoms. Specific examples of the polycycloalkane include adamantane, norbornane, isobornane, tricyclodecane, tetracyclododecane, etc.

For the alicyclic hydrocarbon atoms that may have a substituent for R^{b0}, examples of the substituent include —R^{P1}, —R^{P2}—O—R^{P1}, —R^{P2}—CO—R^{P1}, —R^{P2}—CO—O—R^{P1}, —R^{P2}—O—CO—R^{P1}, —R^{P2}—OH, —R^{P2}—CN, —R^{P2}—COOH, etc. R^{P1} is an alkyl group having 1 or more and 10 or less carbon atoms, a saturated cyclic aliphatic hydrocarbon group having 3 or more and 20 or less carbon atoms, or an aromatic hydrocarbon group having 6 or more and 30 or less carbon atoms. R^{P2} is a single bond, an alkylene group having 1 or more and 10 or less carbon atoms, a divalent saturated cyclic aliphatic hydrocarbon group having 3 or more and 20 or less carbon atoms, or a divalent aromatic hydrocarbon group having 6 or more and 30 or less carbon atoms. The above-described group for R^{P1} or R^{P2} may have a substituent. The substituent is preferably a fluorine atom.

Examples of the alkyl group having 1 or more and 10 or less carbon atoms for R^{P1} include a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, an n-nonyl group, an n-decyl group, etc.

Examples of the saturated cyclic aliphatic hydrocarbon group having 3 or more and 20 or less carbon atoms for R^{P1} include a cycloalkyl group such as a cyclopropyl group, a cyclobutyl group, a cyclopentyl group, a cyclohexyl group, a cycloheptyl group, a cyclooctyl group, a cyclodecyl group, or a cyclododecyl group; a polycyclic saturated cyclic aliphatic hydrocarbon group such as a bicyclo[2.2.2]octyl group, a tricyclo[5.2.1.0^{2,6}]decanyl group, a tricyclo[3.3.1.1^{3,7}]decanyl group, a tetracyclo[6.2.1.1^{3,6}.0^{2,7}]dodecanyl group, an adamantyl group, etc.

Examples of an aromatic hydrocarbon group having 6 or more and 30 or less carbon atoms for R^{P1} include a phenyl group, a naphthyl group, a fluorenyl group, an anthryl group, a phenanthryl group, a biphenyl group, etc.

Examples of the alkylene group having 1 or more and 10 or less carbon atoms for R^{P2} include a methylene group, a ethan-1,2-diyl group (ethylene group), a propan-1,3-diyl group, a propan-1,2-diyl group, a butan-1,4-diyl group, a pentan-1,5-diyl group, a hexan-1,6-diyl group, a heptan-1,7-diyl group, a octan-1,8-diyl group, a nonan-1,9-diyl group, a butan-1,10-diyl group, etc.

Examples of the divalent saturated cyclic aliphatic hydrocarbon group having 3 or more and 20 or less carbon atoms for R^{P2} include a group in which one hydrogen atom is removed from the above-described saturated cyclic aliphatic hydrocarbon group having 3 or more and 20 or less carbon atoms for R^{P1}.

Examples of the divalent aromatic hydrocarbon group having 6 or more and 30 or less carbon atoms for R^{P2} include a group in which one hydrogen atom is removed from the above-described aromatic hydrocarbon group having 6 or more and 30 or less carbon atoms for R^{P1}.

Examples of an aromatic hydrocarbon group that may have a substituent for R^{b0} include a phenyl group, a naphthyl group, a fluorenyl group, an anthryl group, a phenanthryl group, a biphenyl group, etc. The substituent that the aromatic hydrocarbon group for R^{b0} may have is the same as one that the alicyclic hydrocarbon group for R^{b0} may have.

In Formula (b0-1), R^{b2} and R^{b3} are each independently an aryl group that may have a substituent, an alkyl group that may have a substituent, or an alkenyl group that may have a substituent. The aryl group that may have a substituent for R^{b2} or R^{b3} is the same as the aryl group that may have a substituent for R^{b1}. Specific suitable examples of the aryl group that may have a substituent for R^{b2} or R^{b3} include a phenyl group, a naphthyl group, an anthryl group, a phenanthryl group, a biphenyl group, etc. Among these, a phenyl group or a naphthyl group is preferred, and a phenyl group is more preferred.

The alkyl group that may have a substituent for R^{b2} or R^{b3} may be linear or branched. The alkyl group that may have a substituent for R^{b2} or R^{b3} is preferably an alkyl group having 1 or more and 30 or less carbon atoms. The alkenyl group that may have a substituent for R^{b2} or R^{b3} may be linear or branched. The alkenyl group that may have a substituent for R^{b2} or R^{b3} is preferably an alkenyl group having 2 or more and 30 or less carbon atoms.

Examples of a substituent that the aryl group, the alkyl group, or the alkenyl group for R^{b2} or R^{b3} may have include an alkyl group, an alkoxy group, a halogen atom, a halogenated alkyl group, an oxo group (═O), a cyano group, an amino group, an aryl group, the groups represented by Formulae (ca-r-1) to (ca-r-7) above, the —SO₂—R^{b0}, etc.

Among the aryl group that may have a substituent, the alkyl group that may have a substituent, and the alkenyl group that may have a substituent for R^{b2} or R^{b3}, the aryl group that may have a substituent is preferred. When the aryl group has a substituent, the substituent is preferably a fluorine atom, a fluorinated alkyl group, or the group represented by —SO₂—R^{b0} and more preferably a fluorine atom, a fluorinated alkyl group, or a methanesulfonyl group (mesyl group). Therefore, R^{b2} or R^{b3} is particularly preferably an unsubstituted aryl group, an aryl group having a fluorine atom, an aryl group having a fluorinated alkyl group, or an aryl group having a methanesulfonyl group (mesyl group).

In Formula (b0-1), two of R^{b1} to R^{b3} may be linked to each other to form a ring together with a sulfur atom. When two of R^{b1} to R^{b3} is linked to each other, two of R^{b1} to R^{b3} may be linked via a heteroatom such as a sulfur atom, an oxygen atom, or a nitrogen atom, a group such as —SO—, —SO₂—, —O—SO₂—, —C(═O)—, —C(═O)—O—, —C(═O)—NH—, or —N(R^{N})—, etc. R^{N} is a hydrogen atom or an alkyl group having 1 or more and 5 or less carbon atoms.

A ring to be formed is preferably a 3-membered or more and 10-membered or less and more preferably a 5-membered or more and 7-membered or less monocycle including a sulfur atom. A monocycle formed by linking two of R^{b1} to R^{b3} to each other may be condensed to two or more other rings. The other rings may be a benzene ring, a cycloalkane ring, various aromatic heterocycles, or various aliphatic heterocycles, with a benzene ring being preferred.

Specific examples of the ring to be formed by linking two of R^{b1} to R^{b3} to each other include a thiophene ring, a thiazole ring, a benzothiophene ring, a dibenzothiophene ring, a 9H-thioxanthene ring, a thianthrene ring, a phenoxathiin ring, a tetrahydrothiophenium ring, a tetrahydrothiopyranium ring, etc.

The ring formed by linking two of R^{b1} to R^{b3} to each other may have a substituent. Examples of the substituent include an alkyl group, an alkoxy group, a halogen atom, a halogenated alkyl group, an oxo group (═O), a cyano group, an amino group, etc. Among these, a halogen atom or a halogenated alkyl group is preferred and a fluorine atom or a fluorinated alkyl group is more preferred.

A cationic moiety in a sulfonium salt represented by Formula (b0-1) is preferably a cation represented by Formula (ca-b01-1):

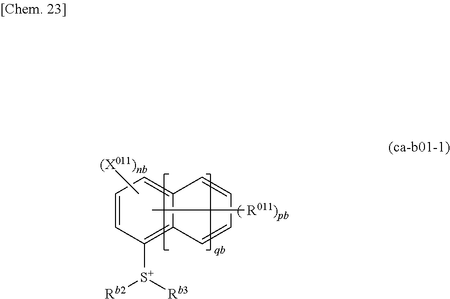

in which R^{b2} and R^{b3} are each independently an aryl group that may have a substituent, an alkyl group that may have a substituent, or an alkenyl group that may have a substituent; R^{b2} and R^{b3} may be linked to each other to form a ring together with a sulfur atom in the formula;
   X⁰¹¹ is a fluorine atom or a fluorinated alkyl group;
   R⁰¹¹ is a substituent;
   nb is an integer from 1 or more;
   pb is an integer from 0 or more;
   qb is an integer of 0 or more and 3 or less;
   provided that nb+pb≤qb×2+5.

In Formula (ca-b01-1), R^{b2} and R^{b3} are the same as R^{b2} and R^{b3} in Formula (b0-1).

In Formula (ca-b01-1), X⁰¹¹ is a fluorine atom or a fluorinated alkyl group. The fluorine atom and fluorinated alkyl group for X⁰¹¹ are the same as the fluorine atom and fluorinated alkyl group that R^{b1} in Formula (b0-1) may have as a substituent.

In Formula (ca-b01-1), R⁰¹¹ is a substituent. Examples of the substituent include an alkyl group, a halogen atom other than a fluorine atom, a halogenated alkyl group other than a fluorinated alkyl group, an oxo group (═O), a cyano group, an amino group, an aryl group, the groups represented by Formulae (ca-r-1) to (ca-r-7) above, the —SO₂—R^{b0}, etc. Among these substituents, —SO₂—R^{b0} is preferred and a methanesulfonyl group (mesyl group) is more preferred.

In Formula (ca-b01-1), nb is an integer of 1 or more, preferably 1 or more and 3 or less, and more preferably 1 or 2. In Formula (ca-b01-1), pb is an integer of 0 or more and preferably an integer of 0 or more and 2 or less. In Formula (ca-b01-1), qb is an integer of 0 or more and 3 or less.

A cationic moiety in a sulfonium salt represented by Formula (b0-1) is particularly preferably any of cations shown below.

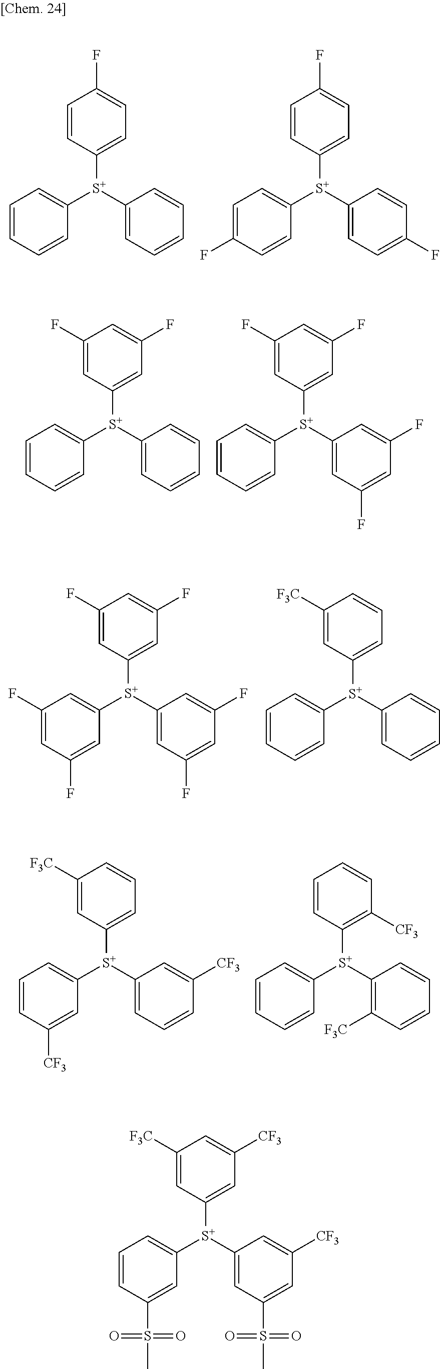

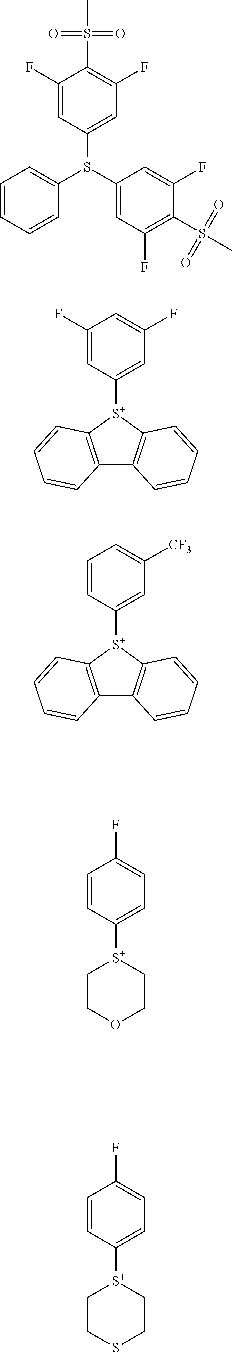 [SMILES: CS(=O)(=O)c1c(F)cc([S+](c2ccccc2)c2cc(F)c(S(C)(=O)=O)c(F)c2)cc1F ; Fc1cc(F)cc(-[s+]2c3ccccc3c3ccccc32)c1 ; FC(F)(F)c1cccc(-[s+]2c3ccccc3c3ccccc32)c1 ; Fc1ccc([S+]2CCOCC2)cc1 ; Fc1ccc([S+]2CCSCC2)cc1]

(Anionic Moiety in Formula (b0-1))

In Formula (b0-1), X₀₁⁻ is a counter anion to any of the above-described cations for the cationic moiety. An anion for X₀₁⁻ is not particularly limited unless the desired effect is impaired. The anion for X₀₁⁻ may be appropriately selected from anions constituting onium salts that have conventionally been incorporated into various photosensitive compositions. The anion for X₀₁⁻ may be an anion represented by Formula (b0-1-an1) below, an anion represented by Formula (b0-1-an2) below, or an anion represented by Formula (b0-1-an3) below:

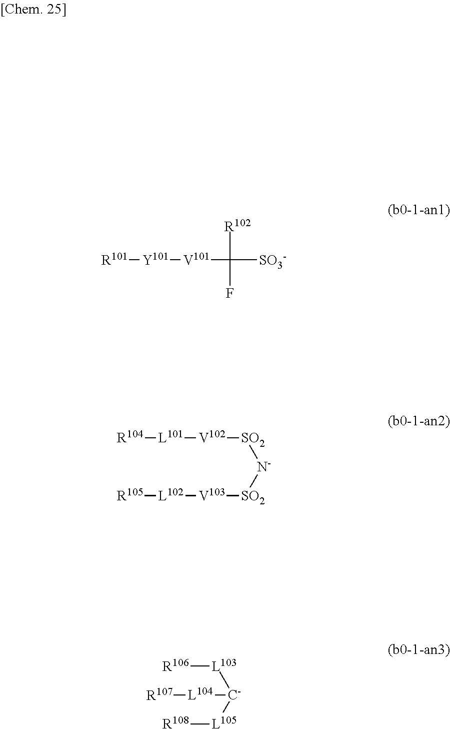

in which R¹⁰¹ and R¹⁰⁴ to R¹⁰⁸ are each independently a cyclic group that may have a substituent, an alkyl group that may have a substituent, or an alkenyl group that may have a substituent;
   R¹⁰⁴ and R¹⁰⁵ may be linked to each other to form a ring;
   R′¹⁰² is a fluorinated alkyl group having 1 or more and 5 or less carbon atoms or a fluorine atom;
   Y¹⁰¹ is a divalent linking group including an oxygen atom or a single bond;
   V¹⁰¹ to V¹⁰³ are each independently a single bond, an alkylene group, or a fluorinated alkyl group;
   L¹⁰¹ and L¹⁰² are each independently a single bond or an oxygen atom; and
   L¹⁰³ to L¹⁰⁵ are each independently a single bond, —CO—, or —SO₂—.
   Anion Represented by Formula (b0-1-an1) In Formula (b0-1-an1), R¹⁰¹ is a cyclic group that may have a substituent, an alkyl group that may have a substituent, or an alkenyl group that may have a substituent.

The cyclic group for R¹⁰¹ may be a cyclic hydrocarbon group or a heterocyclic group, with a cyclic hydrocarbon group being preferred. The cyclic hydrocarbon group may be an aromatic hydrocarbon group or a cyclic aliphatic hydrocarbon group. The heterocyclic group may be an aromatic heterocyclic group or an aliphatic heterocyclic group. The cyclic aliphatic hydrocarbon group or the aliphatic heterocyclic group may have one or more unsaturated bonds. The cyclic aliphatic hydrocarbon group is preferably a saturated cyclic aliphatic hydrocarbon group. The aliphatic heterocyclic group is preferably a saturated aliphatic heterocyclic group.

A number of carbon atoms in the aromatic hydrocarbon group or the aromatic heterocyclic group for R¹⁰¹ is preferably 3 or more and 30 or less, more preferably 5 or more and 30 or less, further preferably 5 or more and 20 or less, and particularly preferably 6 or more and 18 or less. A number of carbon atoms in the substituent is not included in the number of carbon atoms in the aromatic hydrocarbon group or the aromatic heterocyclic group. Examples of the aromatic hydrocarbon group for R¹⁰¹ include a phenyl group, a fluorenyl group, a naphthyl group, an anthryl group, a phenanthryl group, a biphenyl group, etc. Examples of a heteroatom that may be included in the aromatic heterocyclic group for R¹⁰¹ include an oxygen atom, a sulfur atom, a nitrogen atom, etc.

The cyclic aliphatic hydrocarbon group for R¹⁰¹ preferably has 3 or more and 20 or less carbon atoms and more preferably 3 or more and 12 or less carbon atoms. The cyclic aliphatic hydrocarbon group may be a polycyclic group or a monocyclic group. A cyclic aliphatic hydrocarbon group that is monocyclic is preferably a group in which one hydrogen atom is removed from a monocycloalkane. The monocycloalkane preferably has 3 or more and 6 or less carbon atoms. Specific examples of the cyclic aliphatic hydrocarbon group that is monocyclic include a cyclopentyl group, a cyclohexyl group, etc. A cyclic aliphatic hydrocarbon group that is polycyclic is preferably a group in which one hydrogen atom is removed from a polycycloalkane. The polycycloalkane preferably has 7 or more and 30 or less carbon atoms. Suitable examples of the polycycloalkane include a polycycloalkane having a polycyclic skeleton of a bridged ring system such as adamantane, norbornane, isobornane, tricyclodecane, or tetracyclododecane; a polycycloalkane having a polycyclic skeleton of a fused ring system such as a cyclic group having a steroid skeleton, etc. Specific suitable examples of the cyclic aliphatic hydrocarbon group that is polycyclic include an adamantyl group or a norbornyl group.

The cyclic group for R¹⁰¹ may be a fused ring group including a fused ring of an aliphatic hydrocarbon ring and an aromatic ring. Examples of the fused ring include a fused ring in which a polycycloalkane having a polycyclic skeleton of a bridged ring system is fused to one or more aromatic rings. Specific examples of the polycycloalkane of a bridged ring system include a bicycloalkane such as bicyclo[2.2.1]heptane (norbornane), bicyclo[2.2.2]octane, etc. The fused ring group is preferably a group including a fused ring in which two or three aromatic rings are fused to a bicycloalkane and more preferably a group including a fused ring in which two or three aromatic rings are fused to bicyclo[2.2.2]octane. Specific examples of the fused ring group for R¹⁰¹ include groups represented by Formulae (r-br-1) to (r-br-2) below. * represents an atomic bond to Y¹⁰¹ in Formula (b0-1-an1).

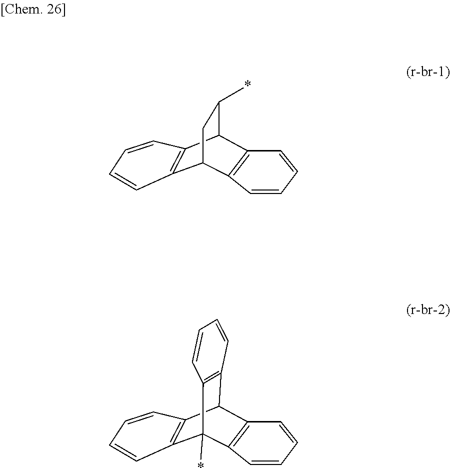 [SMILES: *C1CC2c3ccccc3C1c1ccccc12 ; *C12c3ccccc3C(c3ccccc31)c1ccccc12]

The cyclic group for R¹⁰¹ may be a lactone-containing group represented by any of Formulae (a2-r-1) to (a2-r-7) above, a —SO₂-containing cyclic group represented by any of Formula (a5-r-1) to (a5-r-4) above, or a heterocyclic group represented by any of Formula (r-hr-1) to (r-hr-16) above.

A substituent that the cyclic group for R¹⁰¹ may have includes an alkyl group, an alkoxy group, a halogen atom, a halogenated alkyl group, a hydroxy group, an oxo group (═O), or a nitro group. The alkyl group serving as the substituent is preferably an alkyl group having 1 or more and 5 or less carbon atoms and more preferably a methyl group, an ethyl group, an n-propyl group, an isopropyl group, an n-butyl group, an isobutyl group, a sec-butyl group, or a tert-butyl group. The alkoxy group serving as the substituent is preferably an alkoxy group having 1 or more and 5 or less carbon atoms, more preferably a methoxy group, an ethoxy group, an n-propyloxy group, an isopropyloxy group, an n-butyloxy group, an isobutyloxy group, a sec-butyloxy group, or a tert-butyloxy group, and further preferably a methoxy group or an ethoxy group. The halogen atom for the substituent is preferably a bromine atom, an iodine atom, or a fluorine atom and more preferably a bromine atom or an iodine atom. The halogenated alkyl group for the substituent may be a group in which a part or all of hydrogen atoms in the above-described alkyl group having 1 or more and 5 or less carbon atoms are substituted with a halogen atom.

A substituent that the cyclic group for R¹⁰¹ may have is preferably a hydroxy group, an alkoxy group, a bromine atom, or an iodine atom, and more preferably a hydroxy group, a bromine atom, or an iodine atom.

The alkyl group for R¹⁰¹ may be linear or branched.

A linear alkyl group has preferably 1 or more and 20 or less carbon atoms, more preferably 1 or more and 15 or less carbon atoms, and particularly preferably 1 or more and 10 or less carbon atoms. Specific examples of the linear alkyl group include a methyl group, an ethyl group, an n-propyl group, an n-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tridecyl group, an n-tetradecyl group, an n-pentadecyl group, an n-hexadecyl group, an n-heptadecyl group, an n-octadecyl group, an n-nonadecyl group, an icosyl group, etc.

A branched alkyl group has preferably 3 or more and 20 or less carbon atoms, more preferably 3 or more and 15 or less carbon atoms, and particularly preferably 3 or more and 10 or less carbon atoms. Specific examples of the branched alkyl group include a 1-methylethyl group (isopropyl group), a 1-methylpropyl group (sec-butyl group), a 2-methylpropyl group (isobutyl group), a 1-methylbutyl group (sec-pentyl group), a 2-methylbutyl group, a 3-methylbutyl group (isopentyl group), a 1-ethylbutyl group, a 2-ethylbutyl group, a 1-methylpentyl group, a 2-methylpentyl group, a 3-methylpentyl group, a 4-methylpentyl group (isohexyl group), etc.

The alkenyl group for R¹⁰¹ may be linear or branched.

The alkenyl group for R¹⁰¹ has preferably 2 or more and 10 or less carbon atoms, more preferably 2 or more and 5 or less carbon atoms, further preferably 2 or more and 4 or less carbon atoms, and particularly preferably 3 carbon atoms. Specific examples of a linear alkenyl group include a vinyl group, a 2-propenyl group (allyl group), a 1-propenyl group, a 3-butenyl group, a 2-butenyl group, a 1-butenyl group, etc. Examples of a branched alkenyl group include a 1-methylvinyl group, a 1-methyl-2-propenyl group, a 2-methyl-2-propenyl group, etc. The alkenyl group is preferably a linear alkenyl group, more preferably a vinyl group, a 2-propenyl group (allyl group), or a 1-propenyl group, and particularly preferably a vinyl group.

Examples of a substituent that the alkyl group or the alkenyl group for R¹⁰¹ may have include an alkoxy group, a halogen atom, a halogenated alkyl group, a hydroxy group, an oxo group (═O), a nitro group, an amino group, the cyclic group for R¹⁰¹, etc.

Among the above-described groups, R¹⁰¹ is preferably a cyclic group that may have a substituent. Furthermore, from the viewpoint of reduction of roughness, R¹⁰¹ is more preferably a polycyclic group that may have a substituent and further preferably a bridged ring system polycyclic group that may have a substituent. The polycyclic group may be a polycyclic hydrocarbon group or a polyheterocyclic group. From the viewpoint of enhancing sensitivity, R¹⁰¹ is preferably a cyclic group having an iodine atom or a bromine atom and more preferably an aromatic hydrocarbon group having an iodine atom or a bromine atom.

Examples of the polycyclic hydrocarbon group include a group in which one hydrogen atom is removed from a polycycloalkane having a polycyclic skeleton or a group in which one hydrogen atom is removed from a fused ring of an aromatic hydrocarbon ring to a polycycloalkane. Examples of the polycycloalkane include a polycycloalkane having a polycyclic skeleton of a bridged ring system such as adamantane, norbornane (bicycloheptane), bicyclooctane, etc.; a polycycloalkane having a polycyclic skeleton of a fused ring system such as a cyclic group having a steroid skeleton, etc. Specific suitable examples of the polycyclic aliphatic hydrocarbon group include an adamantyl group, a norbornyl group, etc.

Examples of the group in which one hydrogen atom is removed from a fused ring of an aromatic hydrocarbon ring to a polycycloalkane include a group in which one hydrogen atom is removed from a fused ring of the polycycloalkane and a benzene ring.

The polycyclic heterocyclic group is preferably a polycyclic heterocyclic group of a bridged ring system and more preferably a —SO₂-containing cyclic group represented by Formula (a5-r-1) above that is a polycyclic group of a bridged ring system.

In Formula (b0-1-an1), Y¹⁰¹ is a single bond or a divalent linking group including an oxygen atom. The divalent linking group including an oxygen atom for Y¹⁰¹ may include a heteroatom other than an oxygen atom such as a nitrogen atom, a sulfur atom, a phosphorus atom, a silicon atom, etc. in addition to a carbon atom, a hydrogen atom, and an oxygen atom. Examples of the divalent linking group including an oxygen atom include a divalent oxygen atom-containing group such as —O—, —CO—O—, —CO—NH—, —CO—, —O—CO—O—, —SO₂—, etc.; a combination of one or more divalent oxygen atom-containing groups and one or more alkylene groups, etc. Examples of the divalent linking group including an oxygen atom include linking groups represented by Formulae (y-a1-1) to (y-a1-7) below:

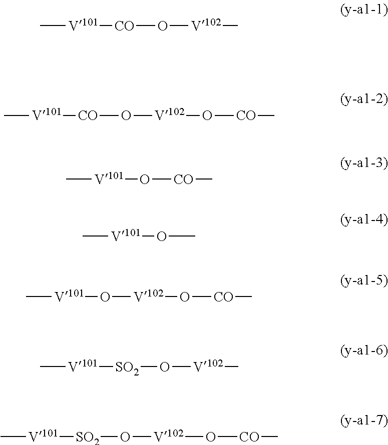

in which V′¹⁰¹ is a single bond or an alkylene group having 1 or more and 5 or less carbon atoms; and V′¹⁰² is a divalent saturated hydrocarbon group having 1 or more and 30 or less carbon atoms.

The divalent saturated hydrocarbon group for V′¹⁰² is preferably an alkylene group having 1 or more and 30 or less carbon atoms. The alkylene group for V′¹⁰² preferably has 1 or more and 10 or less carbon atoms and further preferably 1 or more and 5 or less carbon atoms.

The alkylene group for V′¹⁰¹ or the alkylene group for V′¹⁰² may be linear or branched, but is preferably linear. Specific suitable examples of the alkylene group for V¹⁰¹ or the alkylene group for V′¹⁰² include a methylene group [—CH₂—]; an alkyl methylene group such as —CH(CH₃)—, —CH(CH₂CH₃)—, —C(CH₃)₂—, —C(CH₃) (CH₂CH₃)—, —C(CH₃) (CH₂CH₂CH₃)—, or —C(CH₂CH₃)₂—; an ethylene group [—CH₂CH₂—]; an alkyl ethylene group such as —CH(CH₃) CH₂—, —CH(CH₃) CH(CH₃)—, —C(CH₃)₂CH₂—, —CH(CH₂CH₃) CH₂—; a trimethylene group (n-propylene group) [—CH₂CH₂CH₂—]; an alkyl trimethylene group such as —CH(CH₃) CH₂CH₂—, —CH₂CH(CH₃) CH₂—; a tetramethylene group [—CH₂CH₂CH₂CH₂—]; an alkyl tetramethylene group such as —CH(CH₃) CH₂CH₂CH₂—, —CH₂CH(CH₃) CH₂CH₂—; a pentamethylene group [—CH₂CH₂CH₂CH₂CH₂—], etc.

At least one methylene group in the alkylene group for V′¹⁰¹ or V′¹⁰² may be substituted with a divalent aliphatic cyclic group having 5 or more and 10 or less carbon atoms. The aliphatic cyclic group is preferably a cyclohexylene group, an adamantan-1,5-diyl group, or an adamantan-2,6-diyl group.

Y¹⁰¹ is preferably a single bond or an ester bond (—CO—O—).

In Formula (b0-1-an1), V¹⁰¹ is a single bond, an alkylene group, or a fluorinated alkylene group. The alkylene group or the fluorinated alkylene group for V¹⁰¹ preferably has 1 or more and 4 or less carbon atoms. Examples of the fluorinated alkyl group for V¹⁰¹ include a group in which a part or all of the hydrogen atoms in the alkylene group for V¹⁰¹ are substituted with a fluorine atom. V¹⁰¹ is preferably a single bond or a fluorinated alkylene group having 1 or more and 3 or less carbon atoms.

In (b0-1-an1), R¹⁰² is a fluorine atom or a fluorinated alkyl group having 1 or more and 5 or less carbon atoms. R¹⁰² is preferably a fluorine atom or a perfluoroalkyl group having 1 or more and 5 or less carbon atoms and more preferably a fluorine atom.

Anion Represented by Formula (b0-1-an2)

In Formula (b0-1-an2), R¹⁰⁴ and R¹⁰⁵ are each independently a cyclic group that may have a substituent, an alkyl group that may have a substituent, or an alkenyl group that may have a substituent. The cyclic group that may have a substituent, the alkyl group that may have a substituent, or the alkenyl group that may have a substituent for R¹⁰⁴ or R¹⁰⁵ is the same as the cyclic group that may have a substituent, the alkyl group that may have a substituent, or the alkenyl group that may have a substituent for R¹⁰¹ in Formula (b0-1-an1). However, R¹⁰⁴ and R¹⁰⁵ may be linked to each other to form a ring. R¹⁰⁴ or R¹⁰⁵ is preferably an alkyl group that may have a substituent and more preferably an alkyl group or a fluorinated alkyl group. The alkyl group has preferably 1 or more and 10 or less carbon atoms, more preferably 1 or more and 7 or less carbon atoms, and further preferably 1 or more and 3 or less carbon atoms. A smaller number of carbon atoms in the alkyl group for R¹⁰⁴ or R¹⁰⁵ is preferred from the viewpoint of solubility of a photoacid generating agent (B) in a solvent. When R¹⁰⁴ or R¹⁰⁵ is the fluorinated alkyl group, a higher ratio of a number of fluorine atoms to a sum of the number of fluorine atoms and a number of hydrogen atoms in the fluorinated alkyl group (fluorination ratio) is preferred from the viewpoint of strength of an acid generated by a photoacid generating agent (B). The fluorination ratio is preferably 70% or more and 100% or less, more preferably 90% or more and 100% or less, and further preferably 100%. V¹⁰² to V¹⁰³ in Formula (b0-1-an2) are each independently a single bond, an alkylene group, or a fluorinated alkyl group. The alkylene group and the fluorinated alkylene group for V¹⁰² or V¹⁰³ are the same as the alkylene group and the fluorinated alkylene group for V¹⁰¹ in Formula (b0-1-an1). In Formula (bo-1-an2), L¹⁰¹ and L¹⁰² are each independently a single bond or an oxygen atom.

Anion Represented by Formula (b0-1-an3)

In Formula (b0-1-an3), R¹⁰⁶ to R¹⁰⁸ are each independently a cyclic group that may have a substituent, an alkyl group that may have a substituent, or an alkenyl group that may have a substituent. The cyclic group that may have a substituent, the alkyl group that may have a substituent, and the alkenyl group that may have a substituent for R¹⁰⁶ to R¹⁰⁸ are the same as the cyclic group that may have a substituent, the alkyl group that may have a substituent, and the alkenyl group that may have a substituent for R¹⁰¹ in Formula (b0-1-an1). In Formula (b0-1-an3), L¹⁰³ to L¹⁰⁵ are each independently a single bond, —CO—, or —SO₂—.

X₀₁⁻ in Formula (b0-1) is preferably the anion represented by Formula (b0-1-an1), among the above-described anions.

The anion represented by Formula (b0-1-an1) is preferably any of anions below:

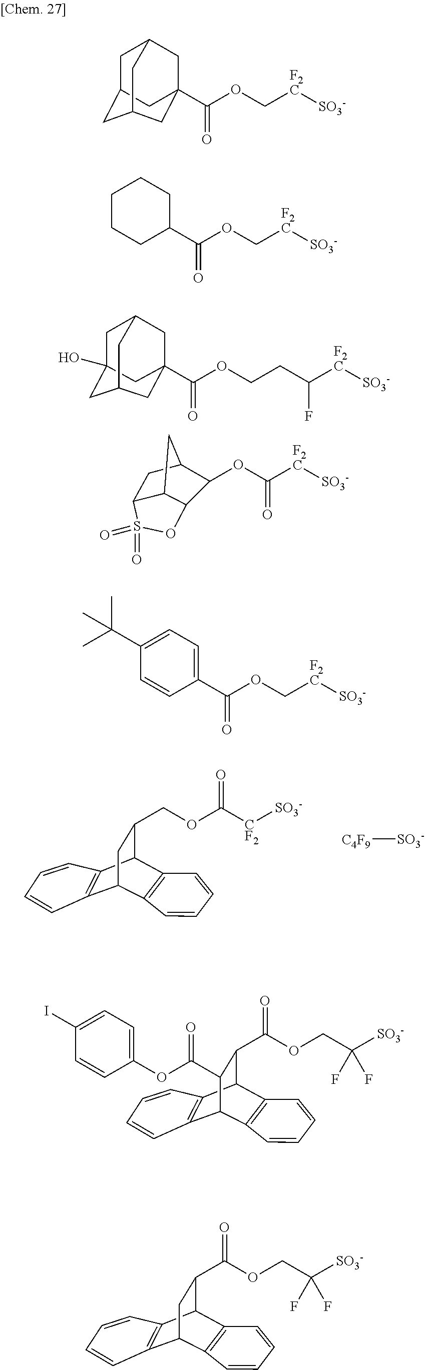

From the viewpoint of enhancing sensitivity, X₀₁⁻ in Formula (b0-1) is preferably an anion represented by Formula (b0-1-an4) below:

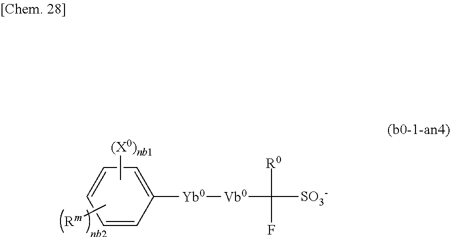

in which X⁰ is a bromine atom or an iodine atom;
   R^{m} is a hydroxy group, an alkyl group, a fluorine atom, or a chlorine atom;
   nb1 is an integer of 1 or more and 5 or less;
   nb2 is an integer of 0 or more and 4 or less;
   (nb1+nb2) is 1 or more and 5 or less;
   Yb⁰ is a divalent linking group or a single bond;
   Vb⁰ is a single bond, an alkylene group, or a fluorinated alkylene group; and
   R⁰ is a hydrogen atom, a fluorinated alkyl group having 1 or more and 5 or less carbon atoms, or a fluorine atom.

In Formula (b0-1-an4), X⁰ is a bromine atom or an iodine atom, with an iodine atom being preferred.

In Formula (b0-1-an4), R^{m} is a hydroxy group, an alkyl group, a fluorine atom, or a chlorine atom, with a hydroxy group being preferred. The alkyl group for R^{m} preferably has 1 or more and 5 or less carbon atoms. The alkyl group for R^{m} is preferably a methyl group or an ethyl group.

In Formula (b0-1-an4), nb1 is an integer of 1 or more and 5 or less.
nb2 is an integer of 0 or more and 4 or less.
(nb1+nb2) is 1 or more and 5 or less.
nb1 is preferably an integer of 1 or more and 3 or less, more preferably 2 or 3, and further preferably 3.
nb2 is preferably an integer of 0 or more and 3 or less, more preferably 0 or 1, and further preferably 0.

In Formula (b0-1-an4), Yb⁰ is a divalent linking group or a single bond. The divalent linking group for Yb⁰ is preferably a divalent linking group including an oxygen atom. The divalent linking group including an oxygen atom for Yb⁰ may include a heteroatom other than an oxygen atom such as a nitrogen atom, a sulfur atom, a phosphorus atom, a silicon atom, etc. in addition to a carbon atom, a hydrogen atom, and an oxygen atom. Examples of the divalent linking group including an oxygen atom include a divalent oxygen atom-containing group such as —O—, —CO—O—, —CO—NH—, —CO—, —O—CO—O—, or —SO₂—; a combination of one or more divalent oxygen atom-containing groups and one or more alkylene groups, etc.

In Formula (b0-1-an4), Vb⁰ is an alkylene group, or a fluorinated alkylene group, or a single bond. The alkylene group or the fluorinated alkylene group for Vb⁰ preferably has 1 or more and 4 or less carbon atoms and more preferably 1 or more and 3 or less carbon atoms. Examples of the fluorinated alkylene group for Vb⁰ include a group in which a part or all of hydrogen atoms in the alkylene group are substituted with a fluorine atom. Vb⁰ is preferably an alkylene group having 1 or more and 4 or less carbon atoms, a fluorinated alkyl group having 1 or more and 4 or less carbon atoms, or a single bond and more preferably a group in which a part or all of hydrogen atoms in an alkylene group having 1 or more and 3 or less carbon atoms are substituted with a fluorine atom, or a single bond.

In (b0-1-an4), R⁰ is a hydrogen atom, a fluorinated alkyl group having 1 or more and 5 or less carbon atoms, or a fluorine atom. R⁰ is preferably a fluorine atom or a perfluoroalkyl group having 1 or more and 5 or less carbon atoms and more preferably a fluorine atom.

From the viewpoint of enhancing sensitivity, X₀₁⁻ in Formula (b0-1) is more preferably an anion represented by Formula (b0-an0) below:

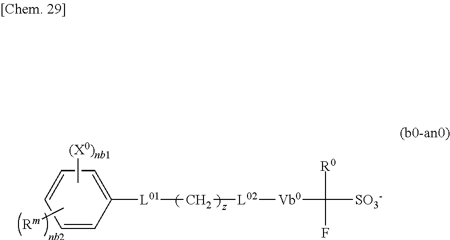

in which X⁰ is a bromine atom or an iodine atom;
   R^{m} is a hydroxy group, an alkyl group, a fluorine atom, or a chlorine atom;
   nb1 is an integer of 1 or more and 5 or less;
   nb2 is an integer of 0 or more and 4 or less;
   (nb1+nb2) is 1 or more and 5 or less;
   L⁰¹ and L⁰² are each independently a single bond, an alkylene group, —O—, —CO—, —O—CO—, —SO₂—, —NR^{a}—CO—, —NR^{a}—, —C(R^{a})₂—NR^{a}, or —C(R^{a}) (N(R^{a})₂)—;
   R^{a} are each independently a hydrogen atom or an alkyl group;
   z is an integer of 0 or more and 10 or less;
   Vb⁰ is a single bond, an alkylene group, or a fluorinated alkylene group; and
   R⁰ is a hydrogen atom, a fluorinated alkyl group having 1 or more and 5 or less carbon atoms, or a fluorine atom.

X⁰, R^{m}, nb1, nb2, Vb⁰, and R⁰ in Formula (b0-an0) are the same as X⁰, R^{m}, nb1, nb2, Vb⁰, and R⁰ in Formula (b0-1-an4), respectively.

In Formula (b0-an0), L⁰¹ and L⁰² are each independently a single bond, an alkylene group, —O—, —CO—, —O—CO—, —SO₂—, —NR^{a}—CO—, —NR^{a}—, —C(R^{a})₂—NR^{a}—, or —C(R^{a}) (N(R^{a})₂)—. R^{a} are each independently a hydrogen atom or an alkyl group. The alkylene group for L⁰¹ or L⁰² and the alkyl group for R^{a} each independently preferably has 1 or more and 4 or less carbon atoms and more preferably 1 or more and 3 or less carbon atoms.

In Formula (b0-an0), it is preferred that one of L⁰¹ and L⁰² be —O—CO—, and it is more preferred that L⁰¹ be —O—CO— and L⁰² be a single bond or —O—CO—.

In Formula (b0-an0), it is preferred that -L⁰¹-(CH₂)_{z}-L⁰²-Vb⁰- be —CO—O-Vb⁰-, —O—CO-Vb⁰-, or —CO—O— (CH₂) z-CO—O-Vb⁰-.

In Formula (b0-an0), z is an integer of 0 or more and 10 or less, preferably an integer of 0 or more and 5 or less, and more preferably an integer of 0 or more and 3 or less.

Suitable examples of the anion represented by Formula (b0-1-an4) include anions below:

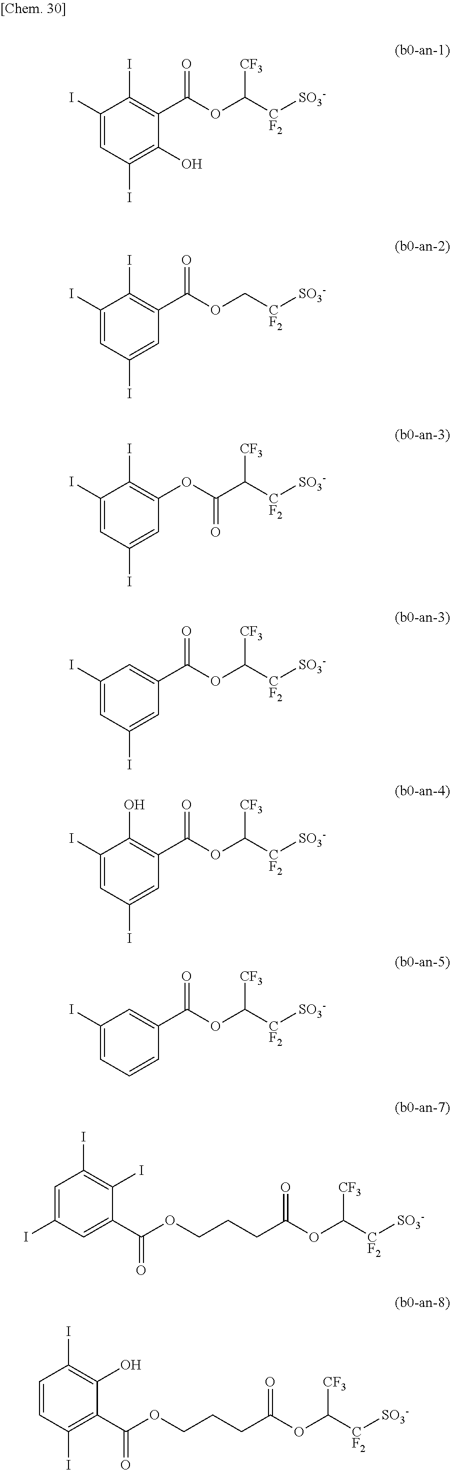

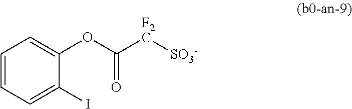

A sulfonium salt represented by Formula (b0-1) is preferably a sulfonium salt represented by Formula (b0-1-1) below:

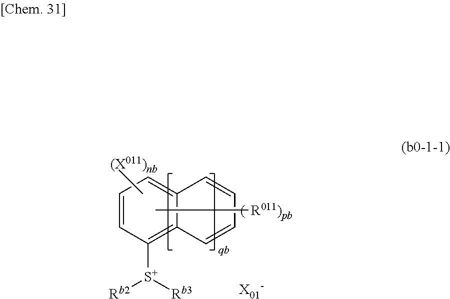

in which R^{b2} and R^{b3} are each independently an aryl group that may have a substituent, an alkyl group that may have a substituent, or an alkenyl group that may have a substituent;
   R^{b2} and R^{b3} may be linked to each other to form a ring together with a sulfur atom in the formula;
   X⁰²¹ is a fluorine atom or a fluorinated alkyl group;
   R⁰¹¹ is a substituent;
   nb is an integer from 1 or more;
   pb is an integer from 0 or more;
   qb is an integer of 0 or more and 3 or less;
   provided that nb+pb≤qb×2+5; and
   X₀₁⁻ is a counter anion.

An anionic moiety in Formula (b0-1-1) is the same as the anionic moiety in Formula (b0-1). A cationic moiety in Formula (b0-1-1) is the same as the cationic moiety in Formula (ca-b01-1).

A sulfonium salt represented by Formula (b0-1) is preferably an onium salt composed of an organosulfonic acid anion having 1 or more and 40 or less carbon atoms and an organosulfonium ion. Specific suitable examples of the sulfonium salt represented by Formula (b0-1) include sulfonium salts below:

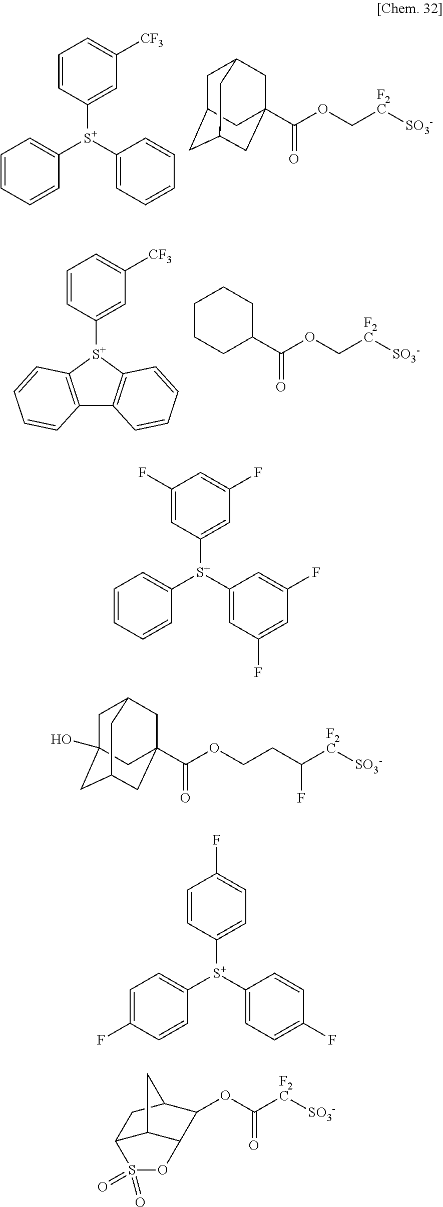

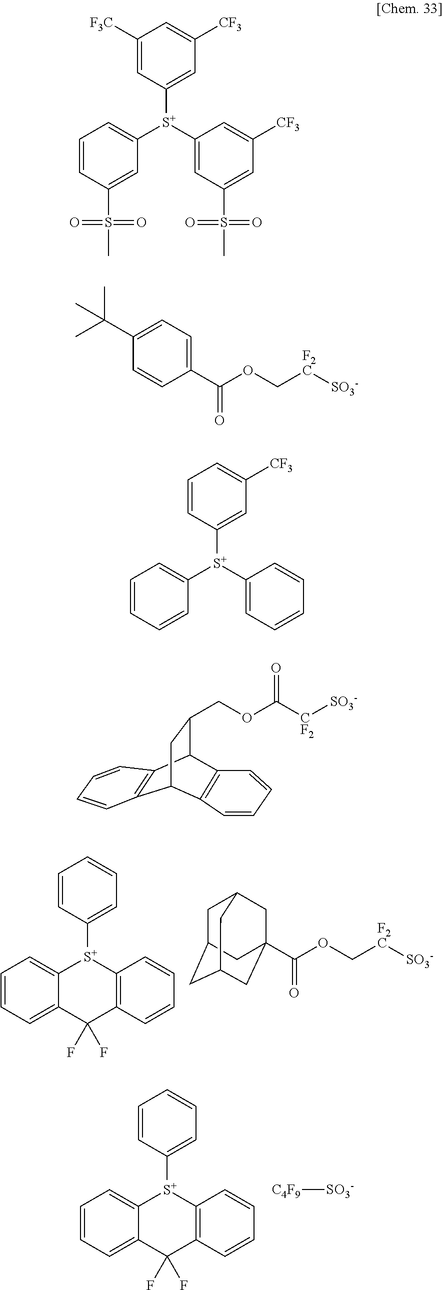

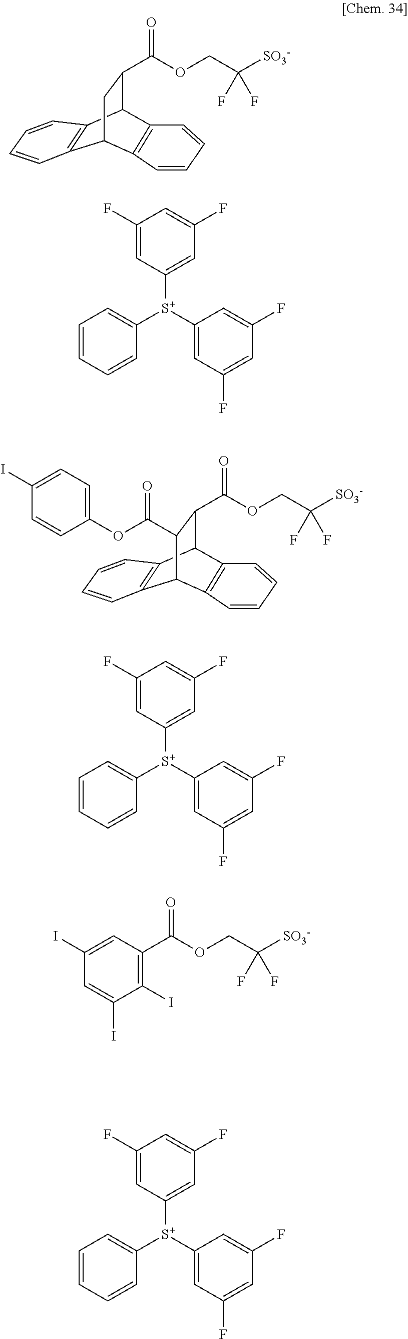

### [Photo Acid Generating Agent (B2) Including Iodonium Cation]

A photoacid generating agent (B2) is a photoacid generating agent including an iodonium cation. Specific preferred examples of the photoacid generating agent (B2) include an iodonium salt represented by Formula (b0-2) below:

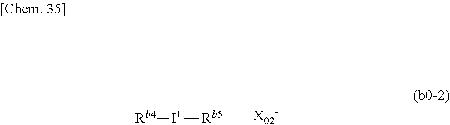

in which R^{b4} is an aryl group having a fluorine atom or an aryl group having a fluorinated alkyl group;
R^{b5} is an aryl group that may have a substituent, an alkyl group that may have a substituent, or an alkenyl group that may have a substituent; and
X₀₂⁻ is an organosulfonic acid anion having 1 or more and 40 or less carbon atoms.

### Cationic Moiety

In Formula (b0-2), R^{b4} is an aryl group having a fluorine atom or an aryl group having a fluorinated alkyl group. An aryl group having a fluorine atom or an aryl group having a fluorinated alkyl group for R^{b4} is the same as the aryl group having a fluorine atom or the aryl group having a fluorinated alkyl group for R^{b1} in Formula (b0-1) above. In Formula (b0-2), R^{b5} is an aryl group that may have a substituent, an alkyl group that may have a substituent, or an alkenyl group that may have a substituent. The aryl group that may have a substituent, the alkyl group that may have a substituent, or the alkenyl group that may have a substituent for R^{b5} may be the same as the aryl group that may have a substituent, the alkyl group that may have a substituent, or the alkenyl group that may have a substituent for R^{b2} or R^{b3} in Formula (b0-1) above.

In Formula (b0-2), R^{b4} is preferably a phenyl group having a fluorine atom or a phenyl group having a group in which a part or all of hydrogen atoms in an alkyl group having 1 or more and 5 or less carbon atoms are substituted with a fluorine atom and more preferably a phenyl group having a fluorine atom. In Formula (b0-2), R^{b5} is preferably a phenyl group having a fluorine atom or a phenyl group having a group in which a part or all of hydrogen atoms in an alkyl group having 1 or more and 5 or less carbon atoms are substituted with a fluorine atom and more preferably a phenyl group having a fluorine atom.

Specific preferred examples of the cationic moiety in the iodonium salt represented by Formula (b0-2) are shown below:

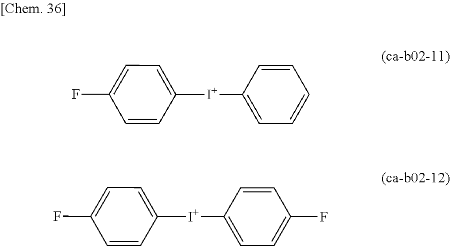 [SMILES: Fc1ccc([I+]c2ccccc2)cc1 ; Fc1ccc([I+]c2ccc(F)cc2)cc1]

### Anionic Moiety

In Formula (b0-2), X₀₂⁻ is a counter anion and may be the same as X₀₁⁻ in Formula (b0-1) above.

Specific preferred examples of the iodonium salt represented by Formula (b0-2) are shown below:

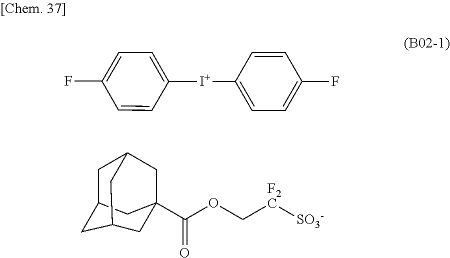

A photoacid generating agent (B) may be only one of a photoacid generating agent (B1) and a photoacid generating agent (B2) or a combination of a photoacid generating agent (B1) and a photoacid generating agent (B2). Furthermore, the photoacid generating agent (B) may include another photoacid generating agent (B3) that does not fall under the photoacid generating agent (B1) or the photoacid generating agent (B2) in addition to at least one of the photoacid generating agent (B1) and the photoacid generating agent (B2) or without the photoacid generating agent (B1) or the photoacid generating agent (B2). A type of the other photoacid generating agent (B3) is not particularly limited unless the desired effect is impaired. Examples of the other photoacid generating agent (B3) include a variety of photoacid generating agents, for example, an onium salt acid generating agent or oxime sulfonate acid generating agent that does not fall under the photoacid generating agent (B1) or the photoacid generating agent (B2); a diazomethane acid generating agent such as bisalkyl- or bisaryl-sulfonyl diazomethane or poly(bissulfonyl)diazomethane; a nitrobenzyl sulfonate acid generating agent; an iminosulfonate acid generating agent; a disulfone acid generating agent, etc.

A proportion of a mass of the photoacid generating agent (B1) to a mass of the photoacid generating agent (B) is preferably 50% by mass or more, more preferably 70% by mass or more, further preferably 80% by mass or more, further more preferably 90% by mass or more, and particularly preferably 100% by mass.

An amount of the photoacid generating agent (B) to be used is not particularly limited unless the desired effect is impaired. The amount of the photoacid generating agent (B) is preferably 5 parts by mass or more and 50 parts by mass or less, more preferably 10 parts by mass or more and 45 parts by mass or less, and further preferably 15 parts by mass or more and 40 parts by mass or less relative to 100 parts by mass of a silicon-containing resin (A).

### <Cross-Linking Agent (C)>

A photosensitive composition includes a cross-linking agent (C). The cross-linking agent (C) is a compound that can cross-link the above-described silicon-containing resin (A) under action of an acid generated by the photoacid generating agent (B). Examples of the cross-linking agent (C) include a melamine cross-linking agent, a urea cross-linking agent, an alkyleneurea cross-linking agent, a glycoluril cross-linking agent, a phenol cross-linking agent, an epoxy cross-linking agent, etc. Note that, the term “lower” as used below means that a number of carbon atoms is 1 or more and 5 or less.

Examples of the melamine cross-linking agent include a compound in which a part or all of hydrogen atoms in an amino group that melamine has are substituted with a hydroxymethyl group, a compound in which a part or all of hydrogen atoms in an amino group that melamine has are substituted with a lower alkoxymethyl group, etc. Specifically, hexamethoxymethyl melamine, hexaethoxymethyl melamine, hexapropoxymethyl melamine, or hexabutoxybutyl melamine is preferred and hexamethoxymethyl melamine is more preferred.

Examples of the urea cross-linking agent include a compound in which a part or all of hydrogen atoms in an amino group that urea has are substituted with a hydroxymethyl group, a compound in which a part or all of hydrogen atoms in an amino group that urea has are substituted with a lower alkoxymethyl group. Specifically, bismethoxymethylurea, bisethoxymethylurea, bispropoxymethylurea, or bisbutoxymethylurea is preferred and bismethoxymethylurea is more preferred.

Examples of the alkyleneurea may be a compound represented by Formula (CA-1) below:

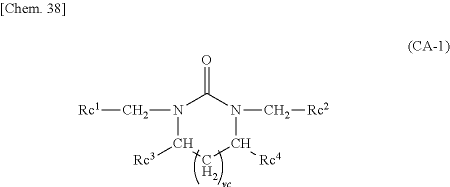

in which R^{C1} and R^{C2} are each independently a hydroxy group or a lower alkoxy group;
R^{C3} and R^{C4} are each independently a hydrogen atom, a hydroxy group, or a lower alkoxy group; and
vc is an integer of 0 or more and 2 or less.

When R^{C1} and R^{C2} are the lower alkoxy group, the lower alkoxy group is preferably an alkoxy group having 1 or more and 4 or less carbon atoms. The lower alkoxy group may be a linear alkoxy group or a branched alkoxy group. R^{C1} and R^{C2} may be the same as or different from each other, and are more preferably the same as each other. When R^{C3} and R^{C4} are the lower alkoxy group, the lower alkoxy group is preferably an alkoxy group having 1 or more and 4 or less carbon atoms. The lower alkoxy group may be a linear alkoxy group or a branched alkoxy group. R^{C3} and R^{C4} may be the same as or different from each other, and are more preferably the same as each other. vc is preferably 0 or 1. The alkyleneurea cross-linking agent is particularly preferably a compound in which vc is 0 (ethyleneurea cross-linking agent) and/or vc is 1 (propyleneurea cross-linking agent).

Specific examples of the alkyleneurea cross-linking agent include, for example, an ethyleneurea cross-linking agent such as monohydroxymethylated ethyleneurea, dihydroxymethylated ethyleneurea, monomethoxymethylated ethyleneurea, dimethoxymethylated ethyleneurea, monoethoxymethylated ethyleneurea, diethoxymethylated ethyleneurea, monopropoxymethylated ethyleneurea, dipropoxymethylated ethyleneurea, monobutoxymethylated ethyleneurea, or dibutoxymethylated ethyleneurea; a propyleneurea cross-linking agent such as monohydroxymethylated propyleneurea, dihydroxymethylated propyleneurea, monomethoxymethylated propyleneurea, dimethoxymethylated propyleneurea, monoethoxymethylated propyleneurea, diethoxymethylated propyleneurea, monopropoxymethylated propyleneurea, dipropoxymethylated propyleneurea, monodibutoxymethylated propyleneurea, or dibutoxymethylated propyleneurea; 1,3-di(methoxymethyl)4,5-dihydroxy-2-imidazolidinone, 1,3-di(methoxymethyl)-4,5-dimethoxy-2-imidazolidinone, etc.

Examples of the glycoluril cross-linking agent include a glycoluril derivative in which a N-position thereof is substituted with one or both of a hydroxyalkyl group and an alkoxyalkyl group having 1 or more and 4 or less carbon atoms. The glycoluril derivative can be obtained by a condensation reaction of glycoluril with formalin, or by a reaction of this condensation reaction product with a lower alcohol. Specific examples of the glycoluril cross-linking agent include, for example, hydroxymethylated glycoluril such as monohydroxymethylated glycoluril, dihydroxymethylated glycoluril, trihydroxymethylated glycoluril, or tetrahydroxymethylated glycoluril; methoxymethylated glycoluril such as monomethoxymethylated glycoluril, dimethoxymethylated glycoluril, trimethoxymethylated glycoluril, or tetramethoxymethylated glycoluril; ethoxymethylated glycoluril such as monoethoxymethylated glycoluril, diethoxymethylated glycoluril, triethoxymethylated glycoluril, or tetraethoxymethylated glycoluril; propoxymethylated glycoluril such as monopropoxymethylated glycoluril, dipropoxymethylated glycoluril, tripropoxymethylated glycoluril, or tetrapropoxymethylated glycoluril; butoxymethylated glycoluril such as monobutoxymethylated glycoluril, dibutoxymethylated glycoluril, tributoxymethylated glycoluril, or tetrabutoxymethylated glycoluril; etc.

The phenol cross-linking agent is not particularly limited as long as it is a compound that has a plurality of phenolic core structures in the same molecule and in which a position adjacent to an attachment position of a phenolic hydroxy group on an aromatic ring is substituted with a methylol group and/or an alkoxyalkyl group. Having the plurality of phenolic core structures improves cross-linking reactivity. A number of the phenolic core structures is preferably 2 or more and 5 or less, more preferably 2 or more and 4 or less, and further preferably 2 or 3.

The epoxy cross-linking agent is not particularly limited as long as it is a cross-linking agent having an epoxy group, and can be arbitrarily selected from known epoxy cross-linking agents. The epoxy cross-linking agent is preferably a cross-linking agent having two or more epoxy groups from the viewpoint of good cross-linking reactivity. A number of epoxy groups in the epoxy cross-linking agent is preferably 2 or more, more preferably 2 or more and 4 or less, and most preferably 2 per molecule.

The cross-linking agent (C) is preferably a cross-linking agent (C1) having a methylol group and/or an alkoxyalkyl group. Among others, a cross-linking agent selected from the group consisting of a glycoluril cross-linking agent and a phenol cross-linking agent is more preferred. Such a cross-linking agent may be suitably a compound represented by Formula (c1-1) below:

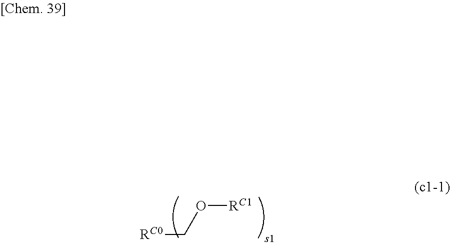

in which s1 is an integer of 1 or more and 10 or less; R^{c0} is a glycoluril structure or a polynuclear phenol structure; and R^{C1} is an alkyl group having 1 or more and 5 or less carbon atoms or a hydrogen atom.

s1 is an integer of 1 or more and 10 or less, preferably an integer of 2 or more and 10 or less, and more preferably an integer of 4 or more and 9 or less. The glycoluril structure for R^{C0} is a structure represented by Formula (R^{C0}-1) below:

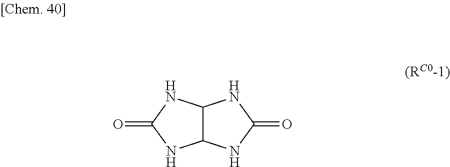

The polynuclear phenol structure for R^{C0} is a structure including two or more structures selected from the group consisting of a phenol structure and a naphthol structure.

Specific suitable examples of the cross-linking agent (C) include compounds below:

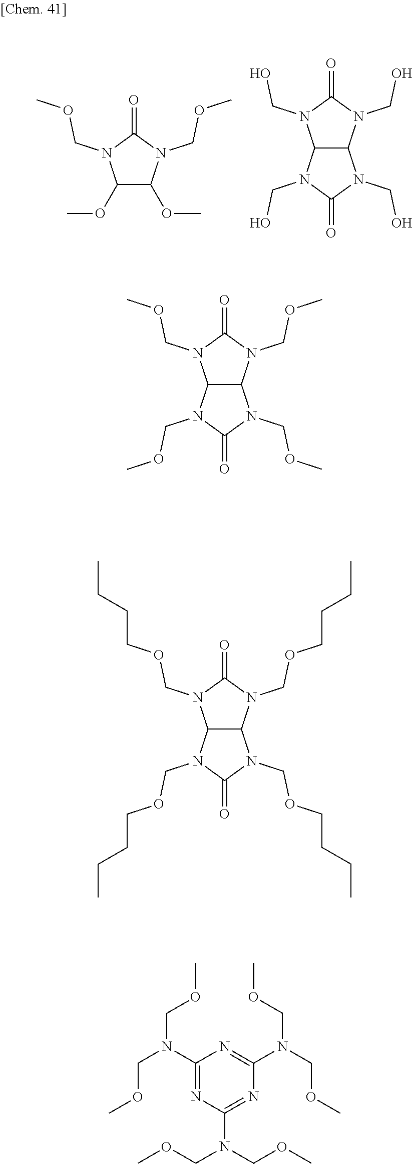

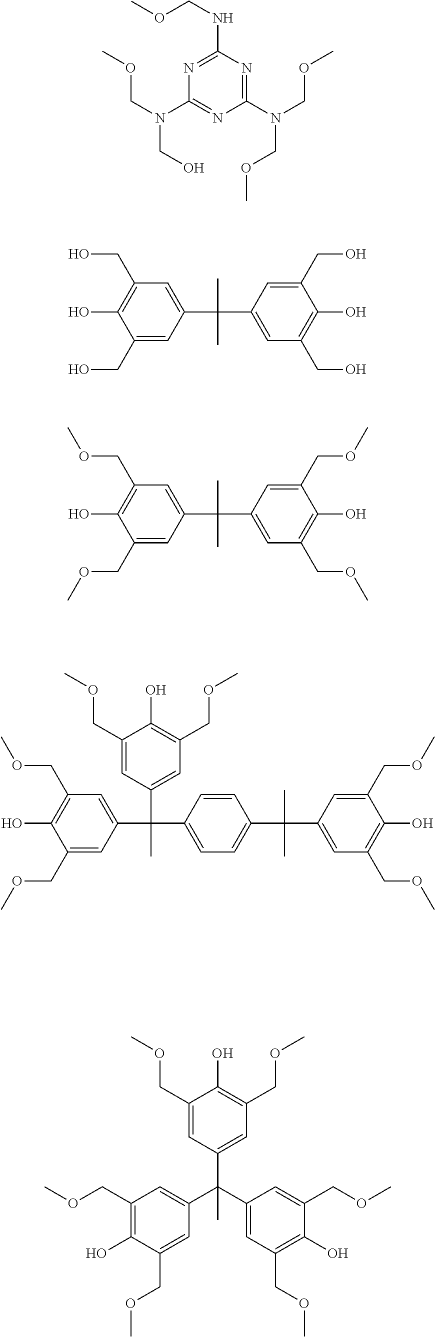

The cross-linking agent (C) may be used alone or two or more thereof may be used in combination. An amount of the cross-linking agent (C) is preferably 1 part by mass or more and 50 parts by mass or less, more preferably 3 parts by mass or more and 40 parts by mass or less, further preferably 5 parts by mass or more and 30 parts by mass or less, and particularly preferably 5 parts by mass or more and 25 parts by mass or less relative to 100 parts by mass of a silicon-containing resin (A). When the cross-linking agent (C) is used in an amount equal to or higher than a lower limit of the above preferred range, cross-link formation progresses sufficiently to easily obtain dissolution contrast, and a good cured film with excellent resolution performance and an excellent lithographic property of a photosensitive composition, and low swelling is easily formed. When the cross-linking agent (C) is used in an amount equal to or lower than an upper limit of the above preferred range, a photosensitive composition has good storage stability and degradation of sensitivity over time is easily suppressed.

<Base Component (D) that Controls Diffusion of Acid Generated by Photoacid Generating Agent (B) Upon Exposure>

A photosensitive composition preferably further includes a base component (D) that traps an acid generated upon exposure. Addition of the base component (D) to the photosensitive composition controls diffusion of an acid generated by a photoacid generating agent (B). Examples of the base component (D) include, for example, a photodegradable base (D1) that degrades upon exposure to lose its acid diffusion controllability (hereinafter referred to as “component (D1)”), a nitrogen-containing organic compound (D2) that do not falls under the component (D1) (hereinafter referred to as component (D2)), etc. Among these, the component (D1) that is a photodegradable base is preferred since it is easy to enhance properties of an increase in sensitivity, roughness reduction, and suppression of coating defect generation.

### [Component (D1)]

A photosensitive composition including a component (D1) can further improve contrast between an exposed area and an unexposed area when a patterned resin film is formed using the photosensitive composition. The component (D1) is not particularly limited as long as it is a compound that degrades upon exposure to lose its acid diffusion controllability. The component (D1) is preferably a compound represented by Formula (d1-1) below (hereinafter referred to as “component (d1-1)”), a compound represented by Formula (d1-2) below (hereinafter referred to as “component (d1-2)”), or a compound represented by Formula (d1-3) below (hereinafter referred to as “component (d1-3)”). The component (d1-1), the component (d1-2), or the component (d1-3) does not serve as a quencher since it loses its basicity in an exposed area on a coated film made of a photosensitive composition. On the other hand, the component (d1-1), the component (d1-2), or the component (d1-3) serves as a quencher on an unexposed area of a coated film made of a photosensitive composition.

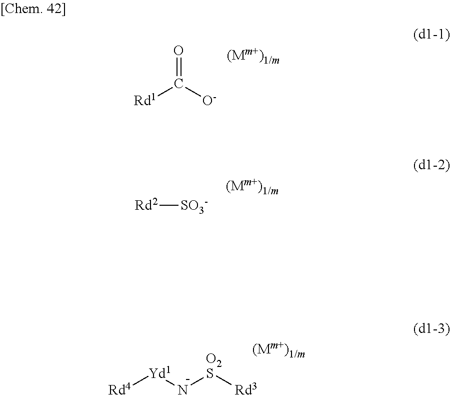

In Formula (d1-1), Rd¹ is a cyclic group that may have a substituent, an alkyl group that may have a substituent, or an alkenyl group that may have a substituent, which is bonded to a carbonyl group in Formula (d1-1) via a single bond or a linking group represented by any of Formulae (y-a1-1) to (y-a1-5) above.

In Formula (d1-2), Rd² is a cyclic group that may have a substituent, an alkyl group that may have a substituent, or an alkenyl group that may have a substituent. However, no fluorine atoms are bonded to a carbon atom adjacent to a sulfur atom in Rd² in Formula (d1-2).

In Formula (d1-3), Rd³ and Rd⁴ are each independently a cyclic group that may have a substituent, an alkyl group that may have a substituent, or an alkenyl group that may have a substituent. Yd¹ is a single bond or a divalent linking group.

In Formulae (d1-1) to (d1-3), m is an integer of 1 or more; and M^{m+} are each independently an m-valent organic cation.

(Component (d1-1))

### Anionic Moiety

In Formula (d1-1), Rd¹ is a cyclic group that may have a substituent, an alkyl group that may have a substituent, or an alkenyl group that may have a substituent, which is bonded to a carbonyl group in Formula (d1-1) via a single bond or a linking group represented by any of Formulae (y-a1-1) to (y-a1-5) above. The cyclic group that may have a substituent, the alkyl group that may have a substituent, and the alkenyl group that may have a substituent in Formula (d1-1) are the same as the cyclic group that may have a substituent, the alkyl group that may have a substituent, and the alkenyl group that may have a substituent for R′²⁰¹ in Formulae (ca-r-1) to (ca-r-7) above. Rd¹ is preferably an aromatic hydrocarbon group that may have a substituent, an aliphatic cyclic group that may have a substituent, or an alkyl group that may have a substituent, which is bonded to a carbonyl group in Formula (d1-1) via a single bond or a linking group represented by any of Formulae (y-a1-1) to (y-a1-5) above. Examples of a substituent that any of the above-described groups may have include a hydroxy group, an oxo group (═O), an alkyl group, an aryl group, a fluorine atom, an iodine atom, a bromine atom, a fluorinated alkyl group, a lactone-containing cyclic group represented by Formulas (a2-r-1) to (a2-r-7) above, etc. Examples of the aromatic hydrocarbon group include a phenyl group, a naphthyl group, etc. The aliphatic cyclic group is more preferably a group in which one hydrogen atom is removed from a polycycloalkane such as adamantane, norbornane, isobornane, tricyclodecane, or tetracyclododecane, etc. The alkyl group preferably has 1 or more and 10 or less carbon atoms. Specific examples of the alkyl group include a linear alkyl group such as a methyl group, an ethyl group, an n-propyl group, an n-butyl group, an n-pentyl group, an n-hexyl group, an n-heptyl group, an n-octyl group, an n-nonyl group, or an n-decyl group; or a branched alkyl group such as a 1-methylethyl group (isopropyl group), a 1-methylpropyl group (sec-butyl group), a 2-methylpropyl group (isobutyl group), a 1-methylbutyl group (sec-pentyl group), a 2-methylbutyl group, a 3-methylbutyl group (isopentyl group), a 1-ethylbutyl group, a 2-ethylbutyl group, a 1-methylpentyl group, a 2-methylpentyl group, a 3-methylpentyl group, a 4-methylpentyl group (isohexyl group).

When the alkyl group is a fluorinated alkyl group having a fluorine atom as a substituent, the fluorinated alkyl group has preferably 1 or more and 11 or less carbon atoms, more preferably 1 or more and 8 or less carbon atoms, and further preferably 1 or more and 4 or less carbon atoms. The fluorinated alkyl group may contain an atom other than a fluorine atom. Examples of the atom other than a fluorine atom include an oxygen atom, a sulfur atom, a nitrogen atom, etc.

An anionic moiety constituting a component (d1-1) is preferably a carboxylic acid anion having 1 or more and 40 or less carbon atoms. Examples of an anion suitable as the anionic moiety constituting a component (d1-1) include anions below:

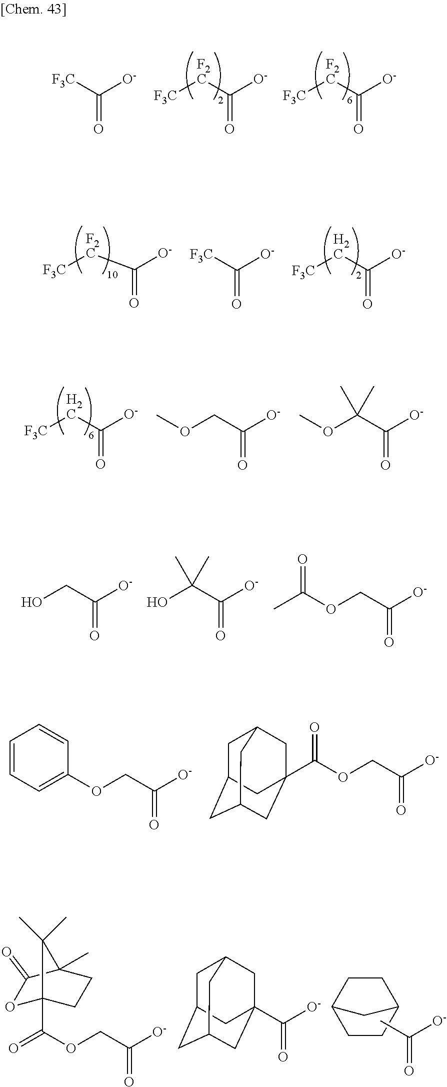

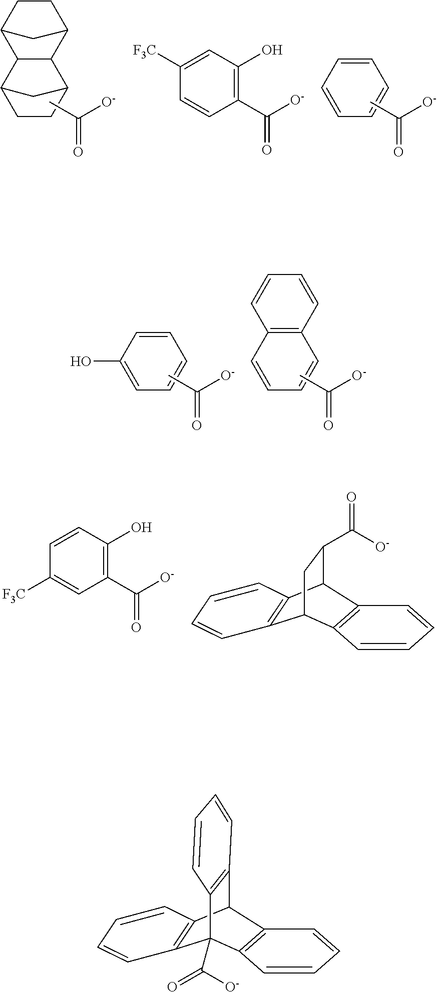

### Cationic Moiety

In Formula (d1-1), M^{m+} is an m-valent organic cation. The organic cation for M^{m+} is preferably an organosulfonium ion or an organoiodonium ion. Suitable examples of the organic cation for M^{m+} include cations below:

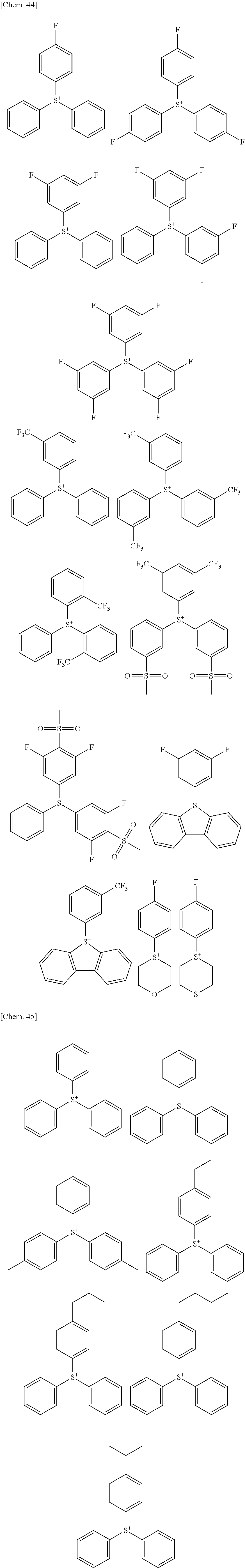

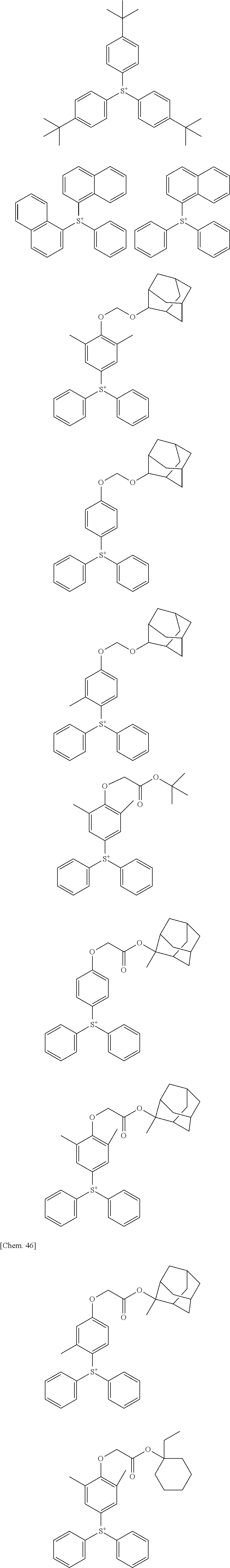

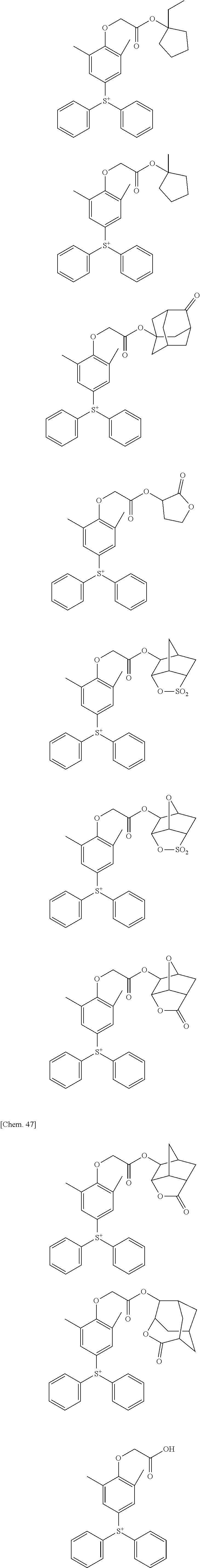

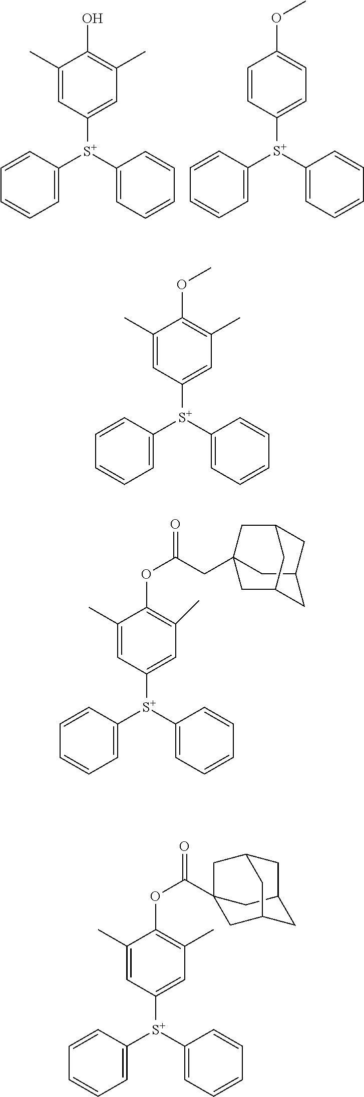 [SMILES: Cc1cc([S+](c2ccccc2)c2ccccc2)cc(C)c1O ; COc1ccc([S+](c2ccccc2)c2ccccc2)cc1 ; COc1c(C)cc([S+](c2ccccc2)c2ccccc2)cc1C ; Cc1cc([S+](c2ccccc2)c2ccccc2)cc(C)c1OC(=O)CC12CC3CC(CC(C3)C1)C2 ; Cc1cc([S+](c2ccccc2)c2ccccc2)cc(C)c1OC(=O)C12CC3CC(CC(C3)C1)C2]

In formulae below, g2 and g3 refer to a number of repetitions of a methylene group.

g2 and g3 are each independently an integer of 0 or more and 20 or less.

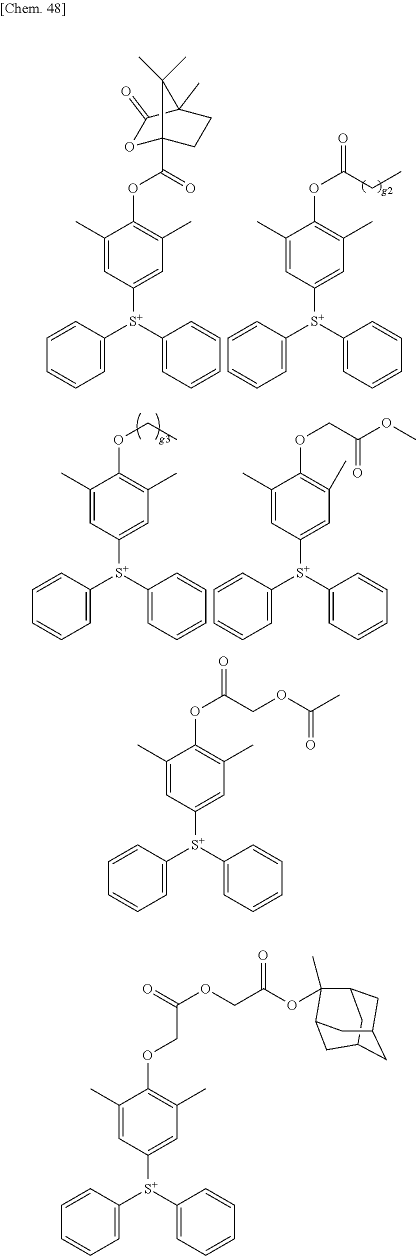

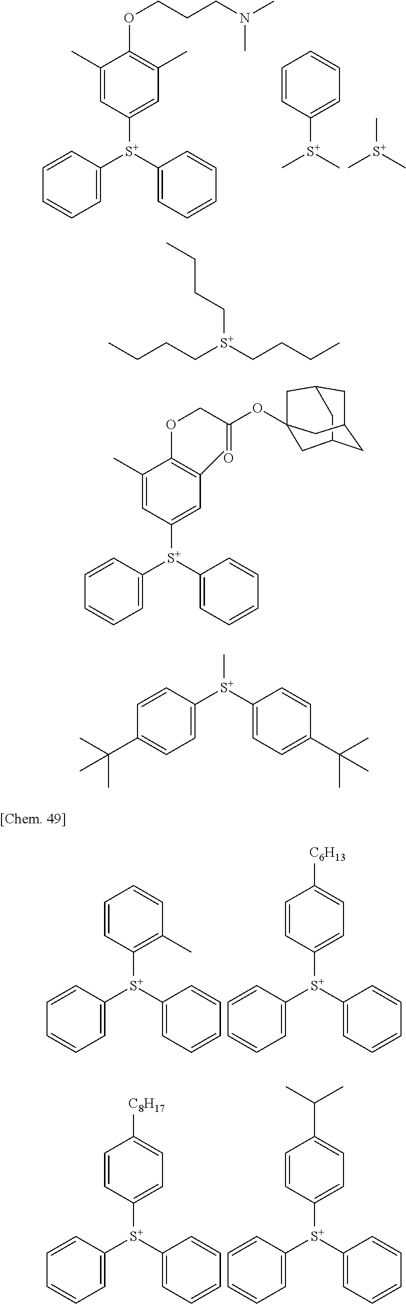

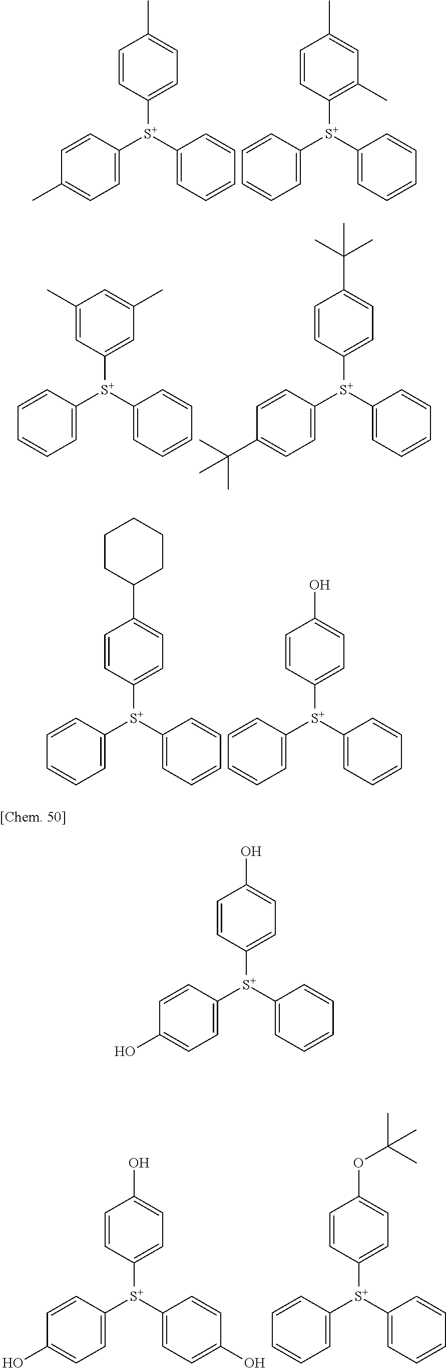

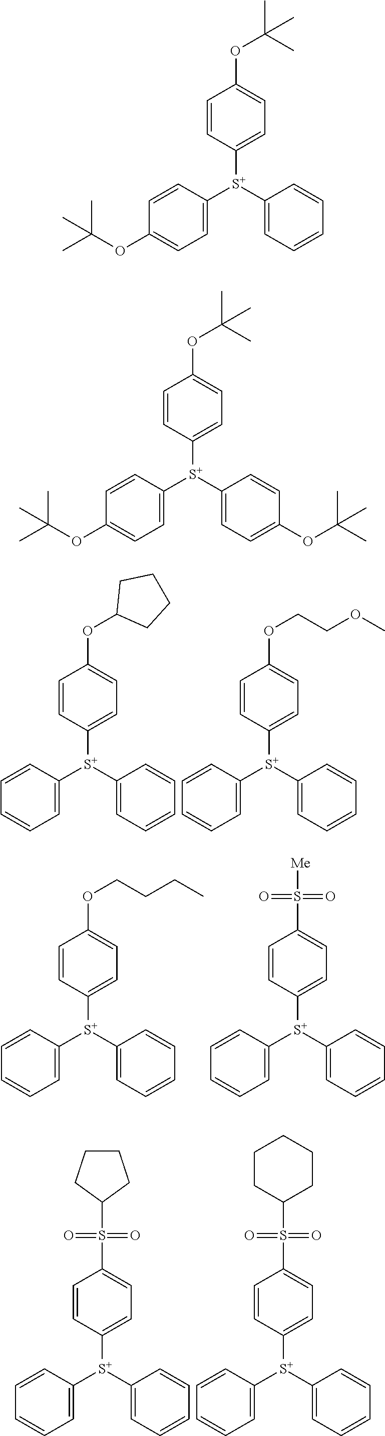

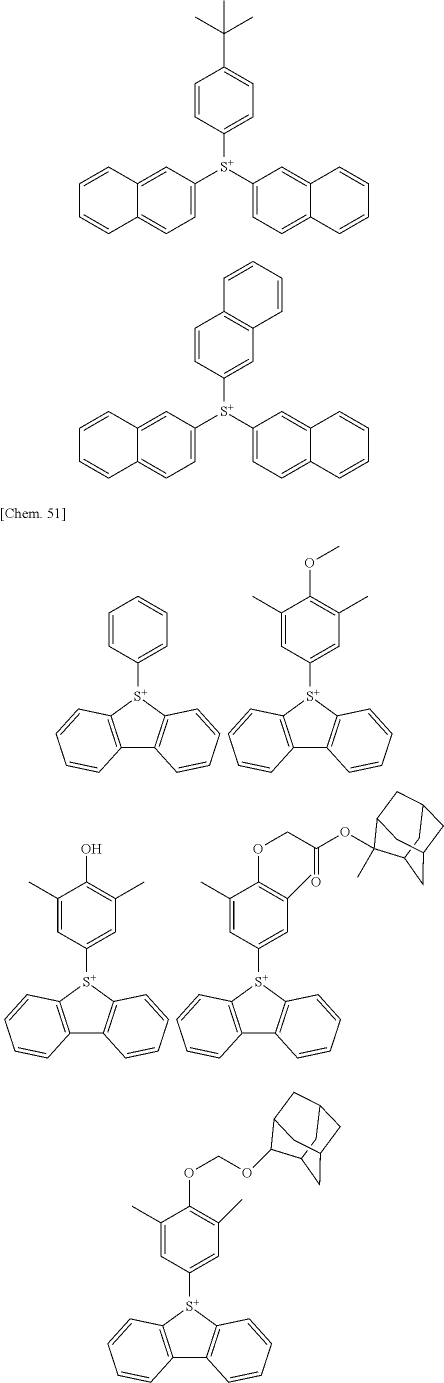

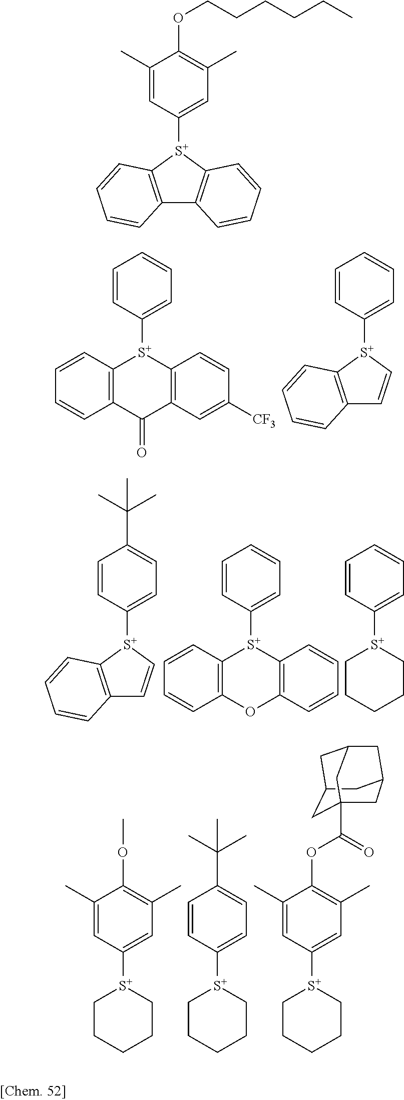

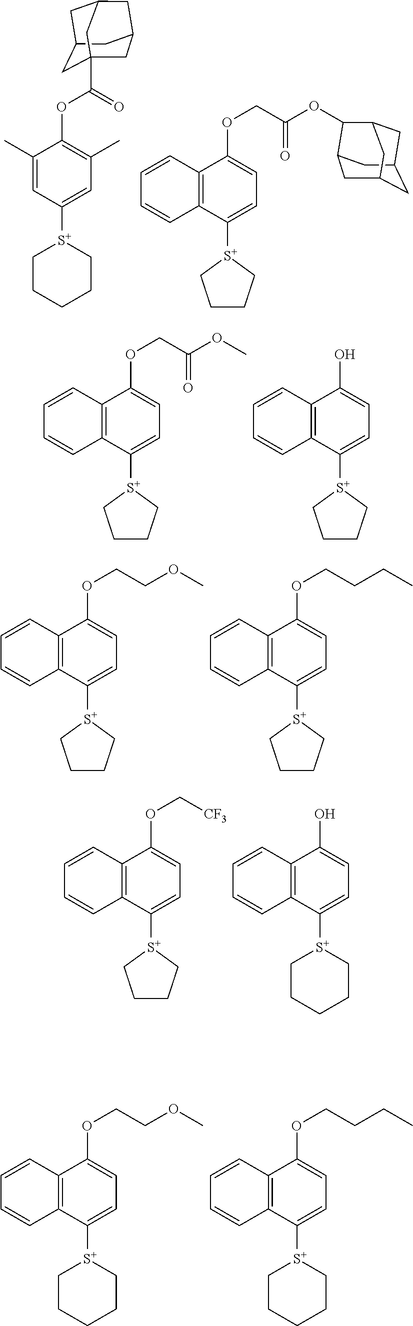

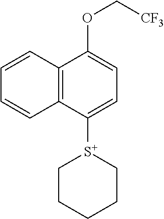 [SMILES: FC(F)(F)COc1ccc([S+]2CCCCC2)c2ccccc12]

Among the above-described cations, a cation falling under a cation as the cationic moiety in Formula (b0-1) is preferred. Therefore, the cationic moiety is preferably cations below:

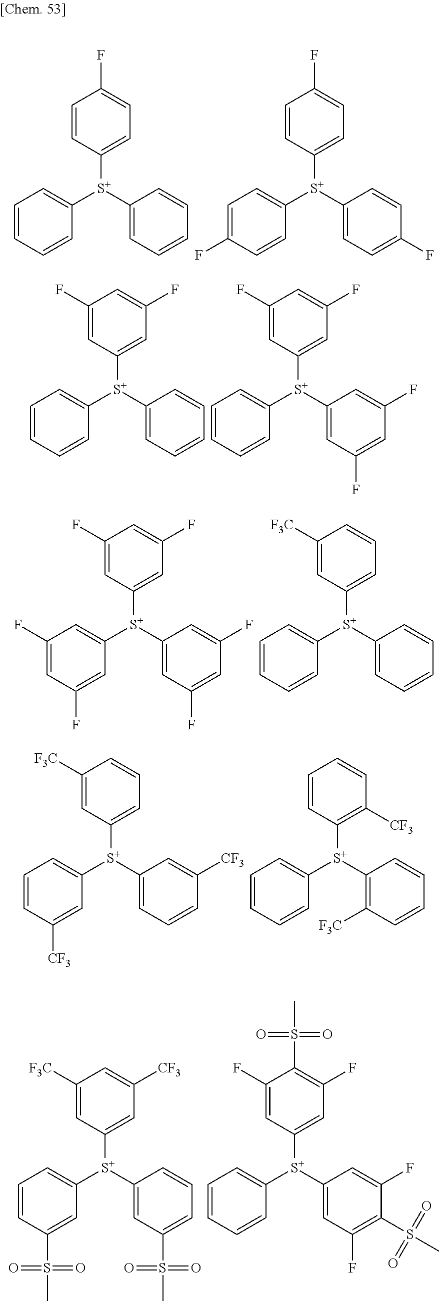

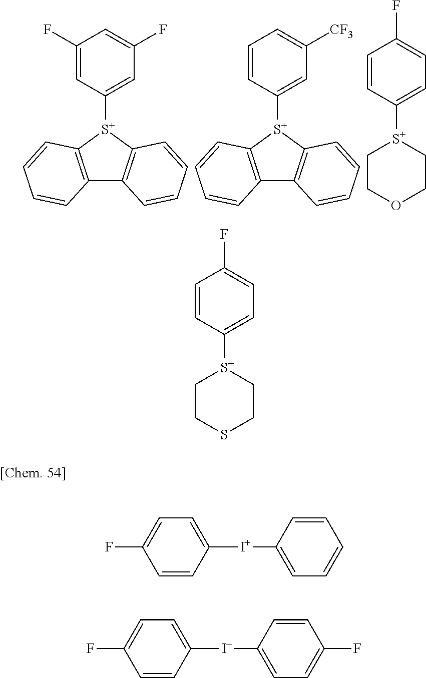 [SMILES: Fc1cc(F)cc(-[s+]2c3ccccc3c3ccccc32)c1 ; FC(F)(F)c1cccc(-[s+]2c3ccccc3c3ccccc32)c1 ; Fc1ccc([S+]2CCOCC2)cc1 ; Fc1ccc([S+]2CCSCC2)cc1 ; Fc1ccc([I+]c2ccccc2)cc1 ; Fc1ccc([I+]c2ccc(F)cc2)cc1]

From the viewpoint of enhancing sensitivity, the component (d1-1) preferably includes a compound represented by Formula (d0-1) below (hereinafter also referred to as “component (D0)”):

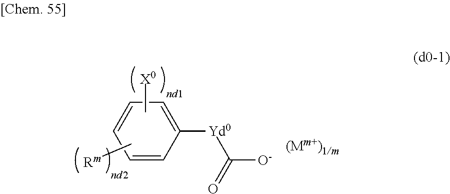

in which X⁰ is a bromine atom or an iodine atom; R^{m} is a hydroxy group, an alkyl group, a fluorine atom, or a chlorine atom;
   nd1 is an integer of 1 or more and 5 or less;
   nd2 is an integer of 0 or more and 4 or less;
   (nd1+nd2) is 1 or more and 5 or less;
   Yd⁰ is a divalent linking group or a single bond;
   M^{m+} is an m-valent organic cation; and
   m is an integer from 1 or more.

### Anionic Moiety in Component (D0)

In formula (d0-1), X⁰ is a bromine atom or an iodine atom and preferably an iodine atom.

In formula (d0-1), R^{m} is a hydroxy group, an alkyl group, a fluorine atom, or a chlorine atom. The alkyl group for R^{m} is preferably an alkyl group having 1 or more and 5 or less carbon atoms and more preferably a methyl group or an ethyl group.

In Formula (d0-1), nd1 is an integer of 1 or more and 5 or less.

nd2 is an integer of 0 or more and 4 or less.
(nd1+nd2) is 1 or more and 5 or less.
nd1 is preferably an integer of 1 or more and 3 or less. From the viewpoint of radiation absorption, nd1 is more preferably 2 or 3 and further preferably 3.
nd2 is preferably an integer of 0 or more and 3 or less, more preferably 0 or 1, and further preferably 0.

In Formula (d0-1), Yd⁰ is a divalent linking group or a single bond. The divalent linking group for Yd⁰ is preferably a divalent linking group including an oxygen atom. The divalent linking group including an oxygen atom for Yd⁰ may include a heteroatom other than an oxygen atom such as a nitrogen atom, a sulfur atom, a phosphorus atom, a silicon atom, etc. in addition to a carbon atom, a hydrogen atom, and an oxygen atom. Examples of the divalent linking group including an oxygen atom include a divalent oxygen atom-containing group such as —O—, —CO—O—, —CO—NH—, —CO—, —O—CO—O—, or —SO₂—; a combination of one or more divalent oxygen atom-containing groups and one or more alkylene groups, etc. Yd⁰ is preferably a divalent linking group including an oxygen atom or a single bond and more preferably a single bond.

Suitable examples of the anionic moiety in the component (D0) include anions below:

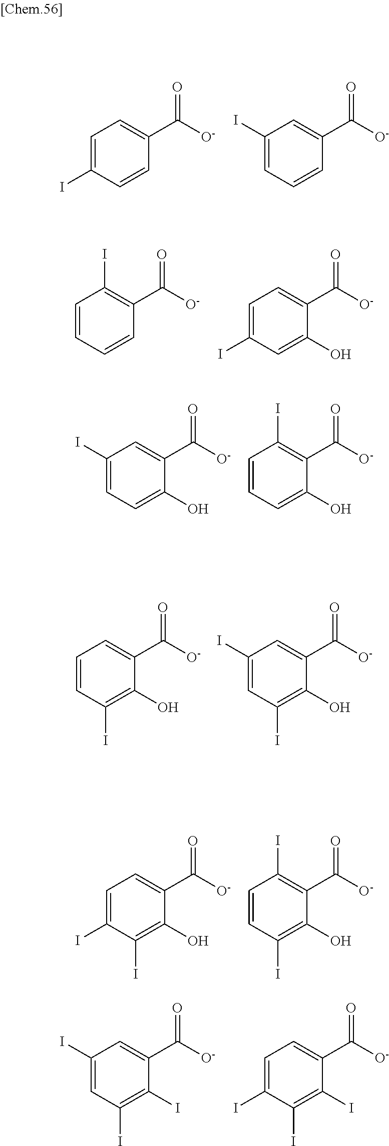

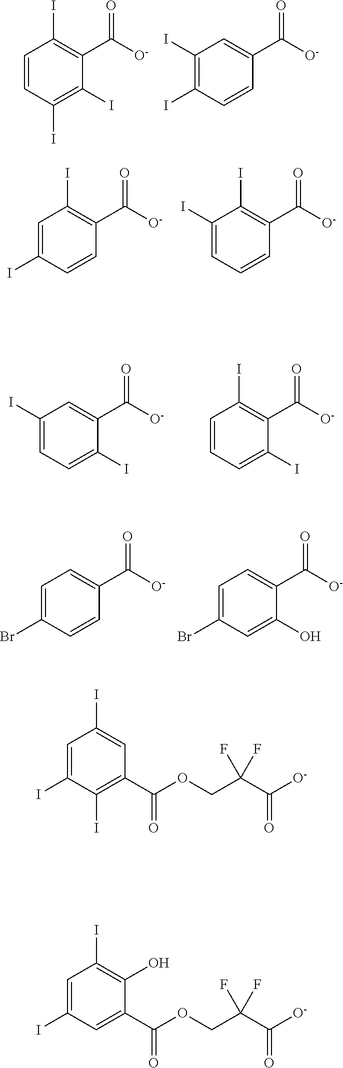

### Anionic Moiety in Component (D0)

In Formula (d0-1), M^{m+} is an m-valent organic cation. Suitable examples of M^{m+} are the same as those of M^{m+} in Formula (d1-1).

Specific suitable examples of the component (D0) include the following compounds. The component (D0) is not limited to the following compounds.

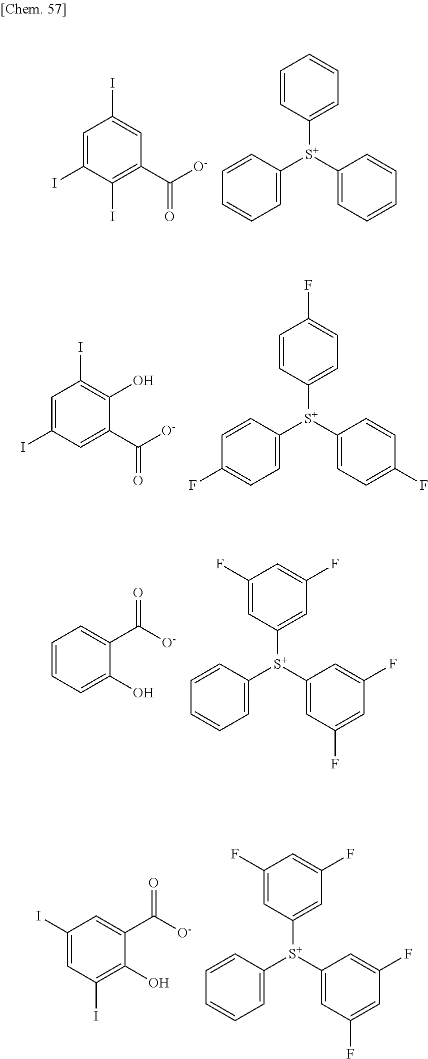

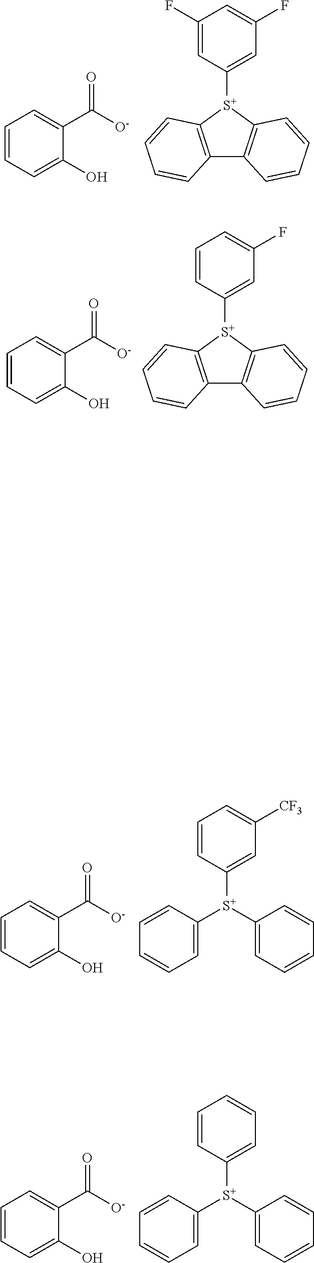

The component (d1-1) may be used alone or two or more thereof may be used in combination.

(Component (d1-2)}

### Anionic Moiety

In Formula (d1-2), Rd² is a cyclic group that may have a substituent, an alkyl group that may have a substituent, or an alkenyl group that may have a substituent. The cyclic group that may have a substituent, the alkyl group that may have a substituent, and the alkenyl group that may have a substituent for Rd² are the same as the cyclic group that may have a substituent, the alkyl group that may have a substituent, and the alkenyl group that may have a substituent for R′²⁰¹. However, no fluorine atoms are bonded to a carbon atom adjacent to a sulfur atom in Rd². This makes an anion in the component (d1-2) a moderately weak acidic anion and thus improves a quenching ability of the component (d1-2). Rd² is preferably an alkyl group that may have a substituent or an aliphatic cyclic group that may have a substituent. The alkyl group preferably has 1 or more and 10 or less carbon atoms and more preferably 3 or more and 10 or less carbon atoms. The aliphatic cyclic group is preferably a group in which one hydrogen atom is removed from adamantane, norbornane, isobornane, tricyclodecane, tetracyclododecane, etc.; a group in which one hydrogen atom is removed from camphor, etc. Such an aliphatic cyclic group may have a substituent. The hydrocarbon group for Rd² may have a substituent. The substituent may be the same as a substituent that the hydrocarbon group for Rd¹ in Formula (d1-1) may have.

Specific examples of an anion suitable as the anionic moiety constituting the component (d1-2) include the anions below:

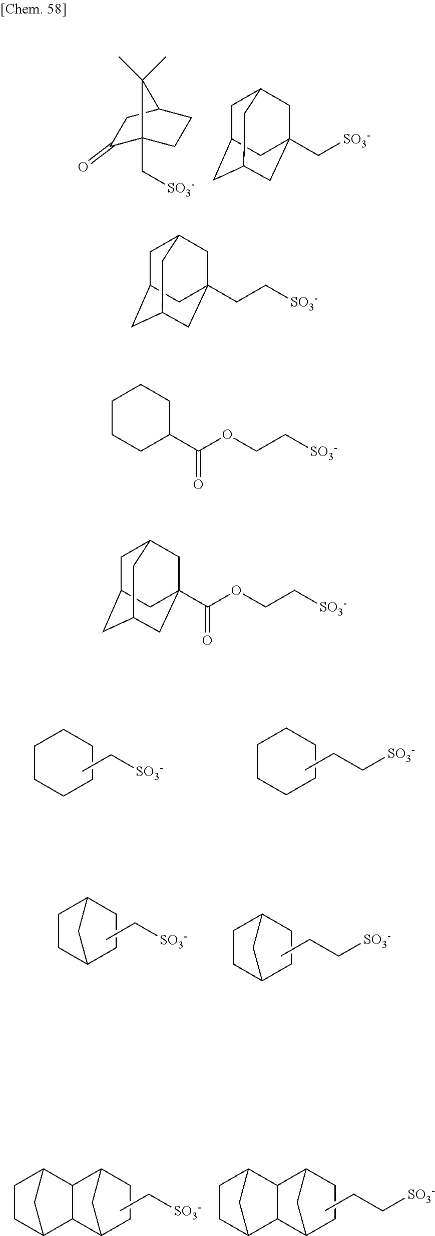

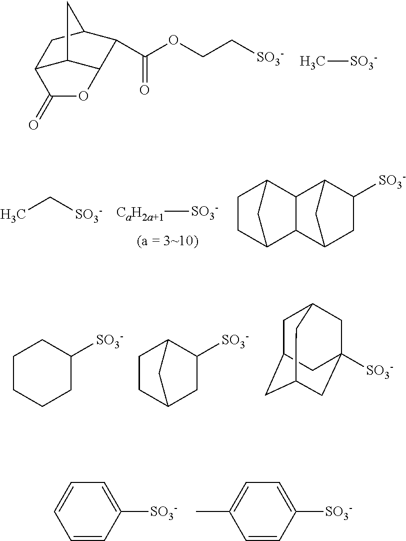

### Cationic Moiety

In Formula (d1-2), M^{m+} is an m-valent organic cation. M^{m+} in Formula (d1-2) is the same as M^{m+} in Formula (d1-1).

The component (d1-2) may be used alone or two or more thereof may be used in combination.

(Component (d1-3))

### Anionic Moiety

In Formula (d1-3), Rd³ is a cyclic group that may have a substituent, an alkyl group that may have a substituent, or an alkenyl group that may have a substituent. The cyclic group that may have a substituent, the alkyl group that may have a substituent, and the alkenyl group that may have a substituent for Rd³ are the same as the cyclic group that may have a substituent, the alkyl group that may have a substituent, and the alkenyl group that may have a substituent for R′²⁰¹. Rd³ is preferably a cyclic group including a fluorine atom, an alkyl group that may have a substituent, or an alkenyl group that may have a substituent and more preferably a fluorinated alkyl group. The fluorinated alkyl group is preferably the same as the fluorinated alkyl group for Rd¹.

In Formula (d1-3), Rd⁴ is a cyclic group that may have a substituent, an alkyl group that may have a substituent, or an alkenyl group that may have a substituent. The cyclic group that may have a substituent, the alkyl group that may have a substituent, and the alkenyl group that may have a substituent for Rd⁴ are the same as the cyclic group that may have a substituent, the alkyl group that may have a substituent, and the alkenyl group that may have a substituent for R′²⁰¹. The alkyl group for Rd⁴ preferably has 1 or more and 5 or less carbon atoms. The alkyl group for Rd⁴ may be linear or branched. Specific examples of the alkyl group include a methyl group, an ethyl group, an n-propyl group, an isopropyl group, an n-butyl group, an isobutyl group, a sec-butyl group, a tert-butyl group, an n-pentyl group, an isopentyl group, a neopentyl group, etc. At least one of hydrogen atoms in the alkyl group for Rd⁴ may be substituted with a hydroxy group, a cyano group, etc.

The alkenyl group for Rd⁴ is preferably a vinyl group, a 2-propenyl group (allyl group), a 1-propenyl group, a 1-methyl-2-propenyl group, a 2-methyl-2-propenyl group, etc.

The cyclic group for Rd⁴ is preferably an alicyclic group in which one hydrogen atom is removed from a monocycloalkane or a polycycloalkane such as cyclopentane, cyclohexane, adamantane, norbornane, isobornane, tricyclodecane, or tetracyclododecane; an aromatic group such as a phenyl group or a naphthyl group, etc.

In Formula (d1-3), Yd¹ is a single bond or a divalent linking group. The divalent linking group for Yd¹ is not particularly limited and examples thereof include a divalent hydrocarbon group that may have a substituent, a divalent linking group including a heteroatom, etc. The divalent hydrocarbon group may be an aromatic hydrocarbon group, an aliphatic hydrocarbon atom, or a combination of an aromatic hydrocarbon group and an aliphatic hydrocarbon group. Yd¹ is preferably a carbonyl group, an ester bond, an amide bond, an alkylene group, or a combination thereof. The alkylene group may be linear or branched. The alkylene group is preferably a methylene group or an ethylene group.

Examples of an anion suitable as the anionic moiety constituting the component (d1-3) include anions below:

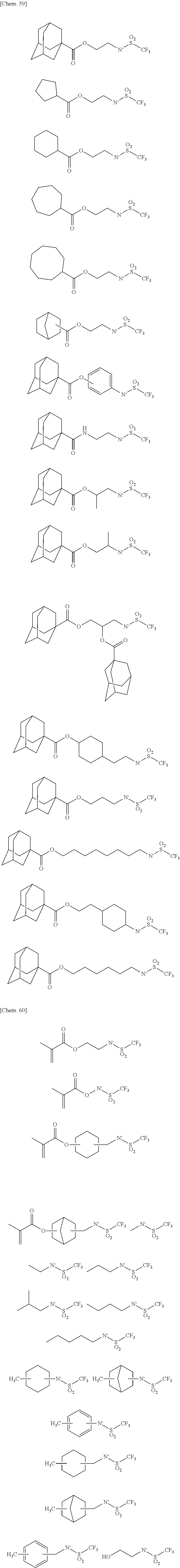

### Cationic Moiety

In Formula (d1-3), M^{m+} is an m-valent organic cation. M^{m+} in Formula (d1-3) is the same as M^{m+} in Formula (d1-1).

As the component (D1), any of the component (d1-1), the component (d1-2), and the component (d1-3) may be used alone or two or more thereof may be used in combination. Among the component (d1-1), the component (d1-2), and the component (d1-3), the component (d1-1) is preferred. Among the components (d1-1), a carboxylate composed of a carboxylic acid anion having 1 or more and 40 or less carbon atoms and an organosulfonium ion or an organoiodonium ion is preferred.

### [Component (D2)]

A photosensitive composition may contain, as the component (D), a nitrogen-containing organic compound component that does not fall under the component (D1) (hereinafter referred to as “component (D2)”). The component (D2) is not particularly limited as long as it is a compound that serves as an acid diffusion controlling agent and does not fall under the component (D1).

The component (D2) is preferably an aliphatic amine. The aliphatic amine is preferably a secondary aliphatic amine or a tertiary aliphatic amine. The aliphatic amine refers to an amine having one or more aliphatic groups. The aliphatic group preferably has 1 or more and 12 or less carbon atoms. Examples of the aliphatic amine include an amine in which at least one of hydrogen atoms in ammonia (NH₃) is substituted with an alkyl group having 1 or more and 12 or less carbon atoms or a hydroxyalkyl group having 1 or more and 12 or less carbon atoms; or a cyclic amine, etc.

Specific examples of an alkyl amine or an alkanol amine include a monoalkylamine such as n-hexylamine, n-heptylamine, n-octylamine, n-nonylamine, or n-decylamine; a dialkylamine such as diethylamine, di-n-propylamine, di-n-heptylamine, or di-n-octylamine; a trialkylamine such as trimethylamine, triethylamine, tri-n-propylamine, tri-n-butylamine, tri-n-pentylamine, tri-n-hexylamine, tri-n-hepylamine, tri-n-octylamine, tri-n-nonylamine, tri-n-decylamine, or tri-n-dodecylamine; an alkanolamine such as diethanolamine, triethanolamine, diisopropanolamine, triisopropanolamine, di-n-octanolamine, or tri-n-octanolamine, etc.

Among these, trialkylamine having 1 or more and 3 or less alkyl groups each having 5 or more and 10 or less carbon atoms is preferred, trialkylamine having three alkyl groups having 5 or more and 10 or less carbon atoms is more preferred, and further preferably tri-n-pentyl amine or tri-n-octylamine.

The cyclic amine may be, for example, a heterocyclic compound including a nitrogen atom as a heteroatom. The heterocyclic compound may be a monocyclic compound or a polycyclic compound. Examples of an aliphatic monocyclic amine include piperidine, piperazine, N-tert-butoxycarbonylpyrrolidine, etc. An aliphatic polycyclic amine preferably has 6 or more and 10 or less carbon atoms. Specific examples of the aliphatic polycyclic amine include 1,5-diazabicyclo[4.3.0]-5-nonene, 1,8-diazabicyclo[5.4.0]-7-undecene, hexamethylenetetetramine, 1,4-diazabicyclo[2.2.2]octane, etc.

Other examples of the aliphatic amine include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxypropoxy)ethyl}amine, tris[2-{2-(2-hydroxyethoxy)ethoxy}ethyl]amine, triethanolamine triacetate, etc. Among these, triethanolamine triacetate is preferred.

The component (D2) may be an amine including an aromatic group. Examples of the amine including an aromatic group include 4-dimethylaminopyridine, pyrrole, indole, pyrazole, imidazole, or a derivative thereof; tribenzylamine; 2,6-diisopropylaniline, etc.

The component (D2) may be used alone or two or more thereof may be used in combination.

When a photosensitive composition contains a base component (D), an amount of the base component (D) contained in the photosensitive composition is preferably 5 parts by mass or more and 60 parts by mass or less, more preferably 10 parts by mass or more and 50 parts by mass or less, and further preferably 15 parts by mass or more and 45 parts by mass or less relative to 100 parts by mass of a silicon-containing resin (A).

<At Least One Compound Selected from the Group Consisting of Organic Carboxylic Acid, and Oxoacid of Phosphorus and Derivative Thereof (E)>

A photosensitive composition may contain at least one compound (E) selected from the group consisting of an organic carboxylic acid, and an oxoacid of phosphorus and a derivative thereof, as an optional component, for the purpose of preventing sensitivity reduction, forming a patterned silicon-containing resin film with a good pattern shape, improving post-exposure delay stability, etc. The organic carboxylic acid is preferably acetic acid, malonic acid, citric acid, malic acid, succinic acid, benzoic acid, salicylic acid, etc. The oxoacid of phosphorus is preferably phosphoric acid, phosphonic acid, or phosphinic acid and more preferably phosphonic acid. Examples of a derivative of the oxoacid of phosphorus include, for example, an ester compound in which a hydrogen atom in the above-described oxoacid is substituted with a hydrocarbon group, etc. Examples of the hydrocarbon group include an alkyl group having 1 or more and 5 or less carbon atoms, an aryl group having 6 or more and 15 or less carbon atoms, etc. Examples of a derivative of phosphoric acid include a phosphate ester such as di-n-butyl phosphate ester or diphenyl phosphate ester. Examples of a derivative of phosphonic acid include a phosphonate ester such as dimethyl phosphonate ester, di-n-butyl phosphonate ester, phenyl phosphonate, diphenyl phosphonate ester, or dibenzyl phosphonate ester. Examples of a derivative of phosphinic acid include phosphinate ester, phenyl phosphinate, etc. The compound (E) may be used alone, or two or more thereof may be used in combination. When a photosensitive composition contains the compound (E), an amount of the compound (E) is usually in a range of 0.01 parts by mass or more and 10 parts by mass or less relative to 100 parts by mass of a silicon-containing resin (A).

### <Fluoroadditive (F)>

A photosensitive composition may contain a fluoroadditive (F) as a hydrophobic resin. The fluoroadditive (F) is used to impart water repellency to a silicon-containing resin film formed with the photosensitive composition. It is used in the photosensitive composition as a separate resin from a silicon-containing resin (A) to improve a lithographic property. The fluoroadditive (F) may be, for example, the fluorine-containing polymer compounds described in Japanese Unexamined Patent Application, Publication Nos. 2010-002870, 2010-032994, 2010-277043, 2011-13569, and 2011-128226. More specifically, the fluoroadditive (F) is a polymer having a constituent unit (f1) represented by Formula (f1-1) below. This polymer is preferably a polymer consisting of constituent units (f1) represented by Formula (f1-1) below (homopolymer); a copolymer of a constituent unit including an acid-degradable group having polarity that increases under action of an acid and the constituent unit (f1); or a copolymer of a constituent unit including an acid-degradable group having polarity that increases under action of an acid, the constituent unit (f1), and a constituent unit derived from acrylic acid or methacrylic acid. Herein, the constituent unit including an acid-degradable group having polarity that increases under action of an acid, which is to be copolymerized with the constituent unit (f1), is preferably a constituent unit derived from 1-ethyl-1-cyclooctyl(meth)acrylate or a constituent unit derived from 1-methyl-1-adamantyl(meth)acrylate.

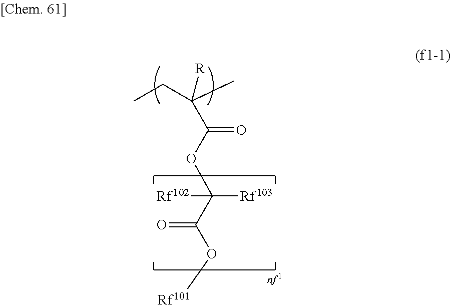

In Formula (f1-1), R is a hydrogen atom or an alkyl group having 1 or more and 5 or less carbon atoms; Rf¹⁰² and Rf¹⁰³ are each independently a hydrogen atom, a halogen atom, an alkyl group having 1 or more and 5 or less carbon atoms, or a halogenated alkyl group having 1 or more and 5 or less carbon atoms, Rf¹⁰² and Rf¹⁰³ may be the same as or different from each other; nf¹ is an integer 0 or more and 5 or less; and Rf¹⁰¹ is an organic group including a fluorine atom.

R attached to a carbon atom at an α-position is a hydrogen atom or an alkyl group having 1 or more and 5 or less carbon atoms. R is preferably a hydrogen atom or a methyl group. The halogen atom for Rf¹⁰² or Rf¹⁰³ is preferably a fluorine atom. The alkyl group having 1 or more and 5 or less carbon atoms for Rf¹⁰² or Rf¹⁰³ is preferably a methyl group or an ethyl group. Specific examples of the halogenated alkyl group having 1 or more and 5 or less carbon atoms for Rf¹⁰² or Rf¹⁰³ include a group in which a part or all of hydrogen atoms in an alkyl group having 1 or more and 5 or less carbon atoms are substituted with a halogen atom. The halogen atom is preferably a fluorine atom. Rf¹⁰² or Rf¹⁰³ is preferably a hydrogen atom, a fluorine atom, or an alkyl group having 1 or more and 5 or less carbon atoms and more preferably a hydrogen atom, a fluorine atom, a methyl group, or an ethyl group. nf¹ is an integer of 0 or more and 5 or less, preferably an integer of 0 or more and 3 or less, and more preferably 1 or 2.

Rf¹⁰¹ is an organic group including a fluorine atom. The organic group including a fluorine atom is preferably a hydrocarbon group including a fluorine atom. A structure of the hydrocarbon group including a fluorine atom may be linear, branched, cyclic, or a combination of these structures. The hydrocarbon group including a fluorine atom preferably has 1 or more and 20 or less carbon atoms, more preferably 1 or more and 15 or less carbon atoms, and further preferably 1 or more and 10 or less carbon atoms. In the hydrocarbon group including a fluorine atom, 25% or more, more preferably 50% or more, and particularly preferably 60% or more of hydrogen atoms in the hydrocarbon group are fluorinated. Rf¹⁰¹ is more preferably a fluorinated hydrocarbon group having 1 or more and 6 or less carbon atoms and further preferably a trifluoromethyl group, —CH₂—CF₃, —CH₂—CF₂—CF₃, —CH(CF₃)₂, —CH₂—CH₂—CF₃, or —CH₂—CH₂—CF₂—CF₂—CF₂—CF₃.

A weight average molecular weight (Mw) (in terms of polystyrene by gel permeation chromatography) of the fluoroadditive (F) is preferably 1000 or more and 50000 or less, more preferably 5000 or more and 40000 or less, and further preferably 10000 or more and 30000 or less. A dispersity (Mw/Mn) of the fluoroadditive (F) is preferably 1.0 or more and 5.0 or less, more preferably 1.0 or more and 3.0 or less, and further preferably 1.0 or more and 2.5 or less.

The fluoroadditive (F) may be used alone or two or more thereof may be used in combination. When a photosensitive composition contains the fluoroadditive (F), an amount of the fluoroadditive (F) is usually 0.5 parts by mass or more and 10 parts by mass or less relative to 100 parts by mass of a silicon-containing resin (A).

### <Organic Solvent (S)>

A photosensitive composition may include an organic solvent (S). The photosensitive composition preferably includes the organic solvent (S) for the purpose of adjusting coatability. The organic solvent (S) may be any solvent appropriately selected from solvents conventionally known as a solvent for a chemically-amplified photosensitive composition as long as it can dissolve components to be used and form a homogeneous solution. Examples of the organic solvent (S) include a lactone such as γ-butyrolactone; a ketone such as acetone, methyl ethyl ketone, cyclohexanone, methyl-n-pentyl ketone, methyl isopentyl ketone, or 2-heptanone; a polyhydric alcohol such as ethylene glycol, diethylene glycol, propylene glycol, or dipropylene glycol; a derivative of a polyhydric alcohol, for example, a compound having an ester bond such as ethylene glycol monoacetate, diethylene glycol monoacetate, propylene glycol monoacetate, or dipropylene glycol monoacetate, a compound having an ether bond such as a monoalkyl ether such as monomethyl ether, monoethyl ether, monopropyl ether, or monobutyl ether, or a monophenyl ether of the polyhydric alcohol or the compound having an ester bond [among these, propylene glycol monomethyl ether acetate (PGMEA) or propylene glycol monomethyl ether (PGME) is preferred]; a cyclic ether such as dioxane, an ester such as methyl lactate, ethyl lactate (EL), methyl acetate, ethyl acetate, butyl acetate, methyl pyruvate, ethyl pyruvate, methyl methoxy propionate, or ethyl ethoxy propionate; an aromatic organic solvent such as anisole, ethyl benzyl ether, cresyl methyl ether, diphenyl ether, dibenzyl ether, phenetole, butyl phenyl ether, ethyl benzene, diethyl benzene, pentyl benzene, isopropyl benzene, toluene, xylene, cymene, or mesitylene; dimethylsulfoxide (DMSO), etc. The organic solvent (S) may be used alone, or two or more thereof may be used as a mixed solvent. Among the above-described organic solvents (S), PGMEA, PGME, γ-butyrolactone, EL, or cyclohexanone is preferred.

A mixed solvent of PGMEA and a polar solvent is also preferred as the organic solvent (S). A blending ratio (by mass) thereof may be appropriately determined taking into consideration compatibility of PGMEA and the polar solvent, etc., but is preferably in a range of 1:9 to 9:1 and more preferably 2:8 to 8:2. More specifically, when EL or cyclohexanone is blended as the polar solvent, a mass ratio of PGMEA:EL or cyclohexanone is preferably 1:9 to 9:1 and more preferably 2:8 to 8:2. Furthermore, when PGME is blended as the polar solvent, a mass ratio of PGMEA:PGME is preferably 1:9 to 9:1 and more preferably 2:8 to 8:2. In addition, a mixed solvent of PGMEA, PGME, and cyclohexanone is also preferred. In addition to those described above, a mixed solvent of at least one selected from PGMEA or EL with γ-butyrolactone is also preferred as the organic solvent (S). In this case, they are preferably mixed in a mass ratio of the former to the latter of 70:30 to 95:5.

An amount of the organic solvent (S) to be used is not particularly limited and appropriately set depending on a thickness of a coated film as long as a photosensitive composition has a solid content concentration so as to be applied to a substrate, etc. The photosensitive composition preferably has a solid content concentration of 0.1% by mass or more and 10% by mass or less and more preferably 0.2% by mass or more and 5% by mass or less.

### <Other Components>

In addition to the components described above, a photosensitive composition may include other components such as an additional resin, a dissolution inhibiting agent, a plasticizing agent, a stabilizing agent, a coloring agent, an anti-halation agent, a dye, etc., as appropriate. For example, the photosensitive composition may include a hydroxystyrene resin or a silicon-free resin such as a novolac resin as the additional resin in combination with the above-described silicon-containing resin (A).

### <<Method for Producing Patterned Silicon-Containing Resin Film (Cured Film)>>

A method for producing a patterned silicon-containing resin film (cured film) includes coating a support with a photosensitive composition to form a coated film (hereinafter also referred to as “coated film formation step”); exposing the coated film in a position-selective manner (hereinafter also referred to as “exposure step”); and developing the thus-exposed coated film (hereinafter also referred to as “development step”).

### <Coated Film Formation Step>

First, a support is coated with the photosensitive composition using, for example, a spinner to form a coated film. The support is not particularly limited and any conventionally known support can be used. Examples thereof include a substrate for an electronic component, a support in which a predetermined wiring pattern is formed on the substrate, etc. More specifically, a silicon wafer; a substrate made of a metal such as copper, chromium, iron, or aluminum; or a glass substrate may be used. A metal such as copper, aluminum, nickel, or gold can be used as a material for a wiring pattern. The support may be a support in which an inorganic and/or organic film may be provided on the above-described substrate. The inorganic film may be, for example, an inorganic antireflection film (inorganic BARC). The organic film may be, for example, an organic antireflection film (organic BARC), an underlayer organic film formed by a multilayer resist method.

After application of a photosensitive composition, a film formed of the photosensitive composition is subjected to a bake (post-apply bake (PAB)) treatment, if necessary. Conditions for the bake treatment are not particularly limited as long as a patterned silicon-containing resin film with a desired shape and property can be formed. A condition for the bake treatment is preferably, for example, heating at a temperature condition of 80° C. or more and 150° C. or less for 40 seconds or more and 120 seconds or less, preferably 60 seconds or more and 90 seconds or less.

### <Exposure Step>

Next, the coated film is exposed in a position-selective manner by, for example, exposure through a mask with a predetermined pattern (mask pattern) or by electron beam lithography with direct irradiation without a mask pattern, using an exposure device such as an electron beam lithography device or an extreme ultraviolet (EUV) exposure device. The coated film is composed of a photosensitive composition that cures upon exposure. For this reason, when a mask is used, a negative photomask that is patterned so that a position to be cured on the coated film is exposed is used as the mask.

A wavelength of a light beam to be used for the exposure is not particularly limited. The exposure can be performed using radiation such as an ArF excimer laser, a KrF excimer laser, an F₂ excimer laser, extreme ultraviolet (EUV) light, vacuum ultraviolet (VUV) light, an electron beam (EB), an X-ray, a soft X-ray, etc. The above-described method of producing a patterned cured film is particularly useful for exposing the coated film to extreme ultraviolet (EUV) light or an electron beam (EB).

A method for exposing the coated film may be normal exposure (dry exposure) in air or inert gas such as nitrogen, or liquid immersion lithography. After the exposure, the thus-exposed coated film is subjected to a bake (post-exposure bake (PEB)) treatment, if necessary. A condition for the bake treatment is preferably, for example, heating at a temperature condition of 80° C. or more and 150° C. or less for 40 seconds or more and 120 seconds or less, preferably 60 seconds or more and 90 seconds or less.

### <Development Step>

Then, the coated film that has been exposed in a position-selective manner is developed. Development results in a patterned silicon-containing resin film. The development is typically performed by an alkali development process or a solvent development process.

When the development is performed by the alkaline development process, an alkaline developing solution is used. The alkaline developing solution may be an aqueous tetramethylammonium hydroxide (TMAH) solution in a concentration of 0.1% by mass or more and 10% by mass or less.

When development is performed by the solvent development process, a developing solution containing an organic solvent (organic developing solution) is used. The organic solvent contained in the organic developing solution to be used for a developing treatment in the solvent development process may be any organic solvent as long as it can dissolve a silicon-containing resin (A) (pre-exposure silicon-containing resin (A)), and can be appropriately selected from known organic solvents. Specific examples thereof include a polar solvent such as a ketone solvent, an ester solvent, an alcohol solvent, a nitrile solvent, an amide solvent, or an ether solvent, as well as a hydrocarbon solvent or a halogenated hydrocarbon solvent. The ketone solvent is an organic solvent containing C—C(═O)—C in its structure. The ester solvent is an organic solvent containing C—C(═O)—O—C in its structure. The alcohol solvent is an organic solvent containing an alcoholic hydroxy group in its structure. The phrase “alcoholic hydroxy group” means a hydroxy group attached to a carbon atom in an aliphatic hydrocarbon group. The nitrile solvent is an organic solvent containing a nitrile group in its structure. The amide solvent is an organic solvent containing a carboxylic amide group in its structure. The ether solvent is an organic solvent containing C—O—C in its structure. There is an organic solvent including a plurality of functional groups that each characterizes any of the above-described solvents in its structure. In this case, it falls under all solvent types that include the functional groups that the organic solvent has. For example, diethylene glycol monomethyl ether falls under both the alcohol solvent and the ether solvent among the above-described classes. The hydrocarbon solvent is a solvent composed of a hydrocarbon. The halogenated hydrocarbon solvent is a solvent composed of a hydrocarbon having only a halogen atom as a substituent. The halogen atom is preferably a fluorine atom. The organic solvent contained in the organic developing solution is preferably a polar solvent such as a ketone solvent, an ester solvent, or a nitrile solvent.

Examples of the ketone solvent include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetylcarbinol, acetophenone, methyl naphthyl ketone, isophorone, methyl amyl ketone (2-heptanone), etc. Among these, methyl amyl ketone (2-heptanone) is preferred.

Examples of the ester solvent include, for example, methyl acetate, butyl acetate, ethyl acetate, isopropyl acetate, amyl acetate, isoamyl acetate, ethyl methoxyacetate, ethyl ethoxyacetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentylacetate, 3-methyl-3-methoxypentylacetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, propyl-3-methoxypropionate, γ-butyrolactone, etc. Among these, the ester solvent is preferably butyl acetate.

Examples of the nitrile solvent include acetonitrile, propionitrile, valeronitrile, butyronitrile, etc.

The organic developing solution can contain a known additive, if necessary. The additive may be, for example, a surfactant. The surfactant is not particularly limited. For example, an ionic or non-ionic fluorosurfactant and/or silicon surfactant may be used.

The development can be performed by any known developing method. Suitable examples of the developing method include a method in which a support is immersed in a developing solution for a certain period of time (dip method), a method in which a developing solution is raised on a surface of a support by surface tension and held for a certain period of time (paddle method), a method in which a developing solution is sprayed on a surface of a support (spray method), a method in which a developing solution is continuously dispensed on a support rotating at a certain speed while scanning a developing solution dispensing nozzle at a certain speed (dynamic dispense method), etc.

After the development, the resulting patterned silicon-containing resin film is preferably subjected to a rinse treatment. For the alkali development process, the film is preferably rinsed with pure water. For the solvent development process, the film is preferably rinsed with a rinse solution containing an organic solvent. The rinse treatment can be performed by any known rinsing method. Examples of the rinsing method include, for example, a method in which a rinse solution is continuously applied on a support rotating at a constant speed (rotary coating method), a method in which a support is immersed in a rinse solution for a certain period of time (dip method), a method in which a rinse solution is sprayed on a surface of a support (spray method), etc. In the case of the solvent development process, a developing solution or a rinse solution adhering to a patterned silicon-containing resin film after development or after development and a rinse treatment may be removed with a supercritical fluid. Usually, after development or a rinse treatment, a patterned silicon-containing resin film is dried. If necessary, a bake treatment (post-bake) may be performed on a patterned silicon-containing resin film after the development.

As mentioned above, the present inventors provide [1] to [11] below.

[1]A photosensitive composition including:
a silicon-containing resin (A);
a photoacid generating agent (B); and
a cross-linking agent (C),
the silicon-containing resin (A) having an aromatic group substituted with one or more iodine atoms.
   [2] The photosensitive composition according to [1], in which the silicon-containing resin (A) has a constituent unit represented by Formula (a1) below:

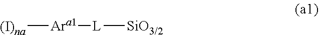

in which
L is a divalent linking group having 1 or more and 40 or less carbon atoms;
provided that when the divalent linking group for L is bonded to an aromatic hydrocarbon ring in Ar^{a1}, there is no aromatic hydrocarbon group at an end of the divalent linking group for L that is bonded to the aromatic hydrocarbon ring in Ar^{a1};
Ar^{a1} is a group having an aromatic hydrocarbon ring that is optionally substituted with one or more groups selected from a hydroxy group, an alkoxy group, or a hydrocarbon group that may have a substituent;
I is bonded to the aromatic hydrocarbon ring that Ar^{a1} has; and na is an integer of 1 or more and 3 or less.
   [3] The photosensitive composition according to [1] or [2], in which the silicon-containing resin (A) has a phenolic hydroxy group.
   [4] The photosensitive composition according to any one of [1] to [3], in which the photoacid generating agent (B) is an onium salt composed of an organosulfonic acid anion having from 1 or more and 40 or less carbon atoms and an organosulfonium ion or an organoiodonium ion.
   [5] The photosensitive composition according to any one of [1] to [4], further including a base component (D) that controls diffusion of an acid generated by the photoacid generating agent (B) upon exposure, the base component (D) being a carboxylate composed of a carboxylic acid anion having 1 or more and 40 or less carbon atoms and an organosulfonium ion or an organoiodonium ion.
   [6] The photosensitive composition according to any one of [1] to [5], in which a proportion of a mass of the silicon-containing resin (A) to a mass of a solid content of the photosensitive composition is 10% by mass or more.
   [7]A method for producing a patterned silicon-containing resin film, the method including:
coating a support with the photosensitive composition according to any one of [1] to [6] to form a coated film;
exposing the coated film in a position-selective manner; and developing the thus-exposed coated film.
   [8] The method for producing a patterned silicon-containing resin film according to [7], in which the coated film is exposed to extreme ultraviolet irradiation in a position-selective manner.
   [9]A silicon-containing resin having an aromatic group substituted with one or more iodine atoms.
   [10] The silicon-containing resin according to [9], in which the silicon-containing resin has a constituent unit represented by Formula (a1) below:

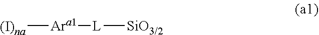

in which
L is a divalent linking group having 1 or more and 40 or less carbon atoms;
provided that when the divalent linking group for L is bonded to an aromatic hydrocarbon ring in Ar^{a1}, there is no aromatic hydrocarbon group at an end of the divalent linking group for L that is bonded to the aromatic hydrocarbon ring in Ar^{a1};
Ar^{a1} is an aromatic hydrocarbon ring that is optionally substituted with one or two groups selected from a hydroxy group, an alkoxy group, or a hydrocarbon group that may have a substituent; and na is an integer of 1 or more and 3 or less.
   [11] The silicon-containing resin according to [9] or [10], in which the silicon-containing resin has a phenolic hydroxy group.

### Examples

Hereinafter, the present invention will be described in more detail with reference to Examples, but the present invention is not limited to Examples.

### <<Preparation of Photosensitive Composition (Negative Photosensitive Composition)>>

Photosensitive compositions of Examples were prepared by mixing and dissolving components as shown in Table 1.

TABLE 1

| | Component (A) | Component (B) | Component (C) | Component (D) | Component (E) | Component (S) |
|---|---|---|---|---|---|---|
| Example 1 | A-1[100] | B-1[24] | C-1[10] | D-1[26] | E-1[3] | S-1[15800], S-2[4000] |
| Example 2 | A-2[100] | B-1[24] | C-1[10] | D-1[26] | E-1[3] | S-1[15800], S-2[4000] |
| Example 3 | A-3[100] | B-1[24] | C-1[10] | D-1[26] | E-1[3] | S-1[15800], S-2[4000] |
| Example 4 | A-4[100] | B-1[24] | C-1[10] | D-1[26] | E-1[3] | S-1[15800], S-2[4000] |
| Example 5 | A-5[100] | B-1[24] | C-1[10] | D-1[26] | E-1[3] | S-1[15800], S-2[4000] |
| Example 6 | A-6[100] | B-1[24] | C-1[10] | D-1[26] | E-1[3] | S-1[15800], S-2[4000] |
| Example 7 | A-7[100] | B-1[24] | C-1[10] | D-1[26] | E-1[3] | S-1[15800], S-2[4000] |
| Example 8 | A-8[100] | B-1[24] | C-1[10] | D-1[26] | E-1[3] | S-1[15800], S-2[4000] |
| Example 9 | A-9[100] | B-1[24] | C-1[10] | D-1[26] | E-1[3] | S-1[15800], S-2[4000] |
| Example 10 | A-2[100] | B-2[37] | C-1[10] | D-1[26] | E-1[3] | S-1[15800], S-2[4000] |
| Example 11 | A-3[100] | B-2[37] | C-1[10] | D-1[26] | E-1[3] | S-1[15800], S-2[4000] |
| Example 12 | A-5[100] | B-2[37] | C-1[10] | D-1[26] | E-1[3] | S-1[15800], S-2[4000] |
| Example 13 | A-6[100] | B-2[37] | C-1[10] | D-1[26] | E-1[3] | S-1[15800], S-2[4000] |
| Example 14 | A-2[100] | B-3[40] | C-1[10] | D-1[26] | E-1[3] | S-1[15800], S-2[4000] |
| Example 15 | A-3[100] | B-3[40] | C-1[10] | D-1[26] | E-1[3] | S-1[15800], S-2[4000] |
| Example 16 | A-5[100] | B-3[40] | C-1[10] | D-1[26] | E-1[3] | S-1[15800], S-2[4000] |
| Example 17 | A-6[100] | B-3[40] | C-1[10] | D-1[26] | E-1[3] | S-1[15800], S-2[4000] |
| Example 18 | A-2[100] | B-1[24] | C-1[10] | D-2[32] | E-1[3] | S-1[15800], S-2[4000] |
| Example 19 | A-3[100] | B-1[24] | C-1[10] | D-2[32] | E-1[3] | S-1[15800], S-2[4000] |
| Example 20 | A-5[100] | B-1[24] | C-1[10] | D-2[32] | E-1[3] | S-1[15800], S-2[4000] |
| Example 21 | A-6[100] | B-1[24] | C-1[10] | D-2[32] | E-1[3] | S-1[15800], S-2[4000] |
| Example 22 | A-2[100] | B-1[24] | C-1[20] | D-1[26] | E-1[3] | S-1[15800], S-2[4000] |
| Example 23 | A-5[100] | B-1[24] | C-1[20] | D-1[26] | E-1[3] | S-1[15800], S-2[4000] |
| Example 24 | A-2[100] | B-2[37] | C-1[20] | D-1[26] | E-1[3] | S-1[15800], S-2[4000] |
| Example 25 | A-5[100] | B-2[37] | C-1[20] | D-1[26] | E-1[3] | S-1[15800], S-2[4000] |
| Example 26 | A-2[100] | B-1[24] | C-1[10] | D-1[32] | E-1[3] | S-1[15800], S-2[4000] |
| Example 27 | A-5[100] | B-1[24] | C-1[10] | D-1[32] | E-1[3] | S-1[15800], S-2[4000] |
| Comparative Example 1 | A-10[100] | B-1[24] | C-1[10] | D-1[26] | E-1[3] | S-1[15800], S-2[4000] |
| Comparative Example 2 | A-11[100] | B-1[24] | C-1[10] | D-1[26] | E-1[3] | S-1[15800], S-2[4000] |
| Comparative Example 3 | A-10[100] | B-2[37] | C-1[10] | D-1[26] | E-1[3] | S-1[15800], S-2[4000] |
| Comparative Example 4 | A-11[100] | B-2[37] | C-1[10] | D-1[26] | E-1[3] | S-1[15800], S-2[4000] |
| Comparative Example 5 | A-10[100] | B-3[40] | C-1[10] | D-1[26] | E-1[3] | S-1[15800], S-2[4000] |
| Comparative Example 6 | A-11[100] | B-3[40] | C-1[10] | D-1[26] | E-1[3] | S-1[15800], S-2[4000] |
| Comparative Example 7 | A-10[100] | B-1[24] | C-1[10] | D-2[32] | E-1[3] | S-1[15800], S-2[4000] |
| Comparative Example 8 | A-11[100] | B-1[24] | C-1[10] | D-2[32] | E-1[3] | S-1[15800], S-2[4000] |
| Comparative Example 9 | A-10[100] | B-1[24] | C-1[20] | D-1[32] | E-1[3] | S-1[15800], S-2[4000] |
| Comparative Example 10 | A-11[100] | B-1[24] | C-1[20] | D-1[32] | E-1[3] | S-1[15800], S-2[4000] |

The abbreviations in Table 1 have meanings as described below. The numerical values in brackets are blended amounts (in part(s) by mass) of components.

A component (A) is any of silicon-containing resins A-1 to A-11 represented by formulae below. The numbers below constituent units in formulae below represent proportions (molar ratios) of the constituent units in a silicon-containing resin. A weight average molecular weight (Mw) and a molecular weight dispersity (Mw/Mn) of each of A-1 to A-11 in terms of standard polystyrene as measured by GPC are as follows.
A-1: Mw of 8200 and Mw/Mn of 1.39.
A-2: Mw of 8600 and Mw/Mn of 1.27.
A-3: Mw of 5700 and Mw/Mn of 1.26.
A-4: Mw of 8600 and Mw/Mn of 1.36.
A-5: Mw of 6900 and Mw/Mn of 1.36.
A-6: Mw of 6500 and Mw/Mn of 1.33.
A-7: Mw of 7300 and Mw/Mn of 1.38.
A-8: Mw of 2500 and Mw/Mn of 1.37.
A-9: Mw of 4900 and Mw/Mn of 1.21.
A-10: Mw of 2400 and Mw/Mn of 1.41.
A-11: Mw of 3600 and Mw/Mn of 1.25.

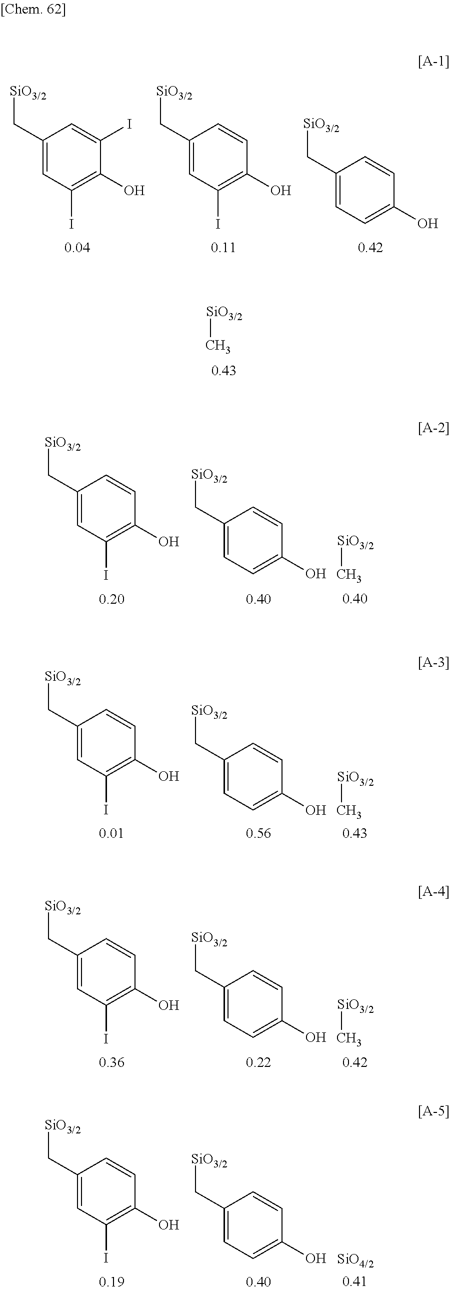

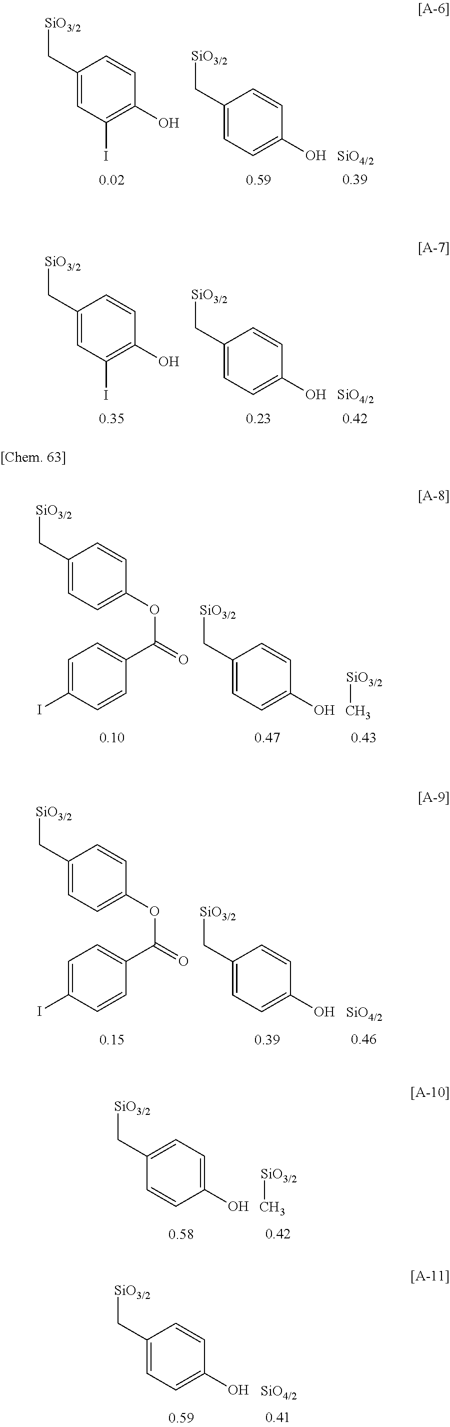

A component (B) is any of photoacid generating agents B-1 to B-3 represented by formulae below.

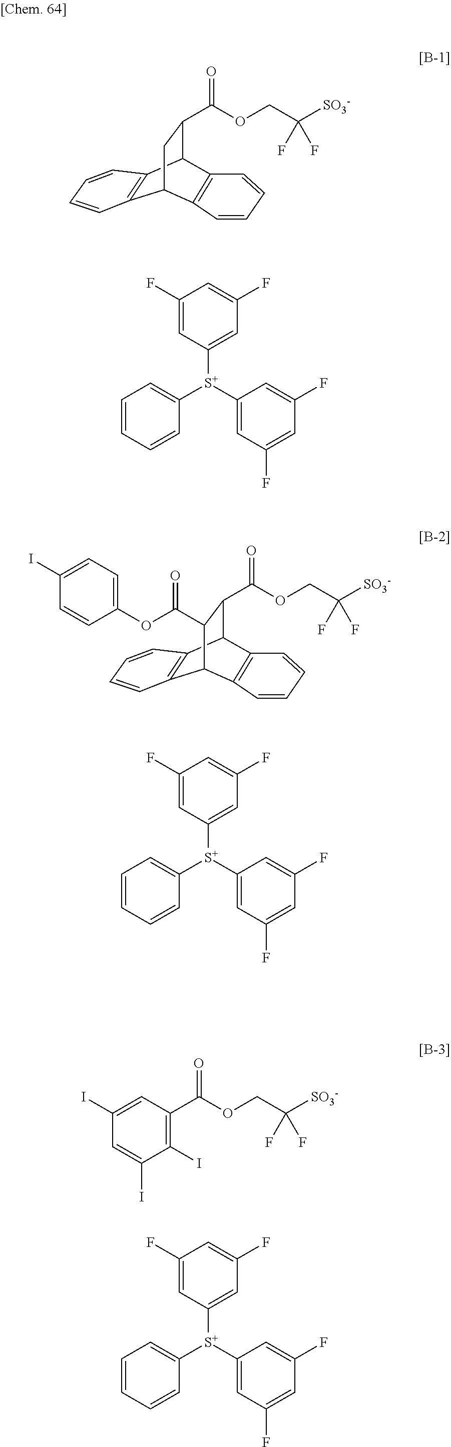

A component (C) is a cross-linking agent C-1 represented by formula below.

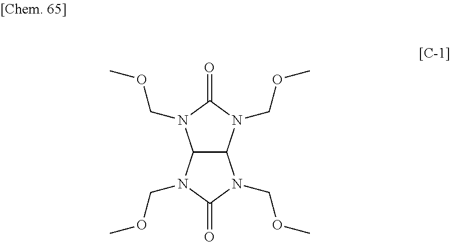

A component (D) is any of base components D-1 to D-2 represented by formulae below.

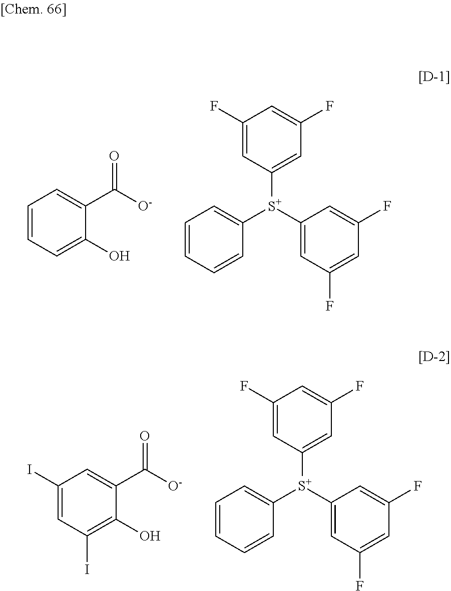 [SMILES: O=C([O-])c1ccccc1O ; Fc1cc(F)cc([S+](c2ccccc2)c2cc(F)cc(F)c2)c1 ; O=C([O-])c1cc(I)cc(I)c1O ; Fc1cc(F)cc([S+](c2ccccc2)c2cc(F)cc(F)c2)c1]

A component (E) is an additive E-1: salicylic acid.

A component (S) is any of organic solvents S-1 to S-2 as described below.
S-1: Propylene glycol monomethyl ether
S-2: Propylene glycol monomethyl ether acetate

### <Synthesis of Silicon-Containing Resins A-1 to A-11>

### (Synthesis of A-1)

First, 50 g of a 26 wt % solution of a silicon-containing resin A-10 in propylene glycol monomethyl ether acetate, 100 g of a 5 wt % solution of an iodine element in tetrahydrofuran, and 472 g of a 1.0 wt % aqueous sodium hydroxide solution were added and mixed to be uniform, and the resulting mixture was stirred at 30° C. for 6 hours. After cooling to room temperature, 224 g of a 10% aqueous sodium bisulfite solution was added thereto and the resultant was stirred for 30 minutes at room temperature. The resulting solution was left to stand and an aqueous layer was removed. Then, 180 g of methyl isobutyl ketone and 90 g of pure water were added thereto and left to stand, and then an aqueous layer was removed. The resultant was washed twice with 45 g of pure water. The resulting organic phase was concentrated to dryness using a rotary evaporator. Then, 112 g of propylene glycol monomethyl ether acetate was added thereto and concentrated to dryness using a rotary evaporator, which was repeated three times. Then, propylene glycol monomethyl ether acetate was added thereto so as to give a concentration of 15% and dissolved to obtain 74 g of a 15% solution of a silicon-containing resin A-1 (terminal trimethylsilyl group) in propylene glycol monomethyl ether acetate. The resultant was identified as having the above structure (A-1) from a molecular weight as measured by GPC of 8200, a degree of iodine substitution of 33.6%, and ¹H-NMR, ¹³C-NMR, and ²⁹Si-NMR analysis results. Note that, the degree of iodine substitution of each of A-1 to A-7 was calculated from each integration value of quantitative ¹³C-NMR using Expression (i) below. Note that, since iodine can theoretically be introduced into a phenol group at two positions, the degree of iodine substitution is 200% when iodine is introduced into all phenol groups.

$$Degree of iodine substitution ( \% ) = ( h + n \times 2 ) / ( d + h + n \times 2 ) \times 100 \qquad ( i )$$

Furthermore, the degree of iodine substitution of each of A-8 to A-9 was calculated from each integration value of quantitative 13C-NMR using Expression (ii) below. Note that, the degree of iodine substitution is 100% when all phenolic groups are reacted.

$$Degree of iodine substitution = h / ( d + h ) \times 100 \qquad ( ii )$$

[¹H-NMR (600 MHz, DMSO-d₆)
a: 1H, 8.8-9.0 ppm
b: 0.27H, 9.6-9.9 ppm
c: 0.95H, 9.0-9.2 ppm
d, e: 2.26H, 7.2-7.8 ppm
f, g, h: 2,73H, 6.2-7.2 ppm
i, j, k: 2.72H, 1.4-2.3 ppm
l, m: 10.7H, −1.5-0.7 ppm

[²⁹Si-NMR (120 MHz, acetone-d₆)]
A: 1.00Si, 12-8 ppm
B to E: 10.17Si, −58-75 ppm

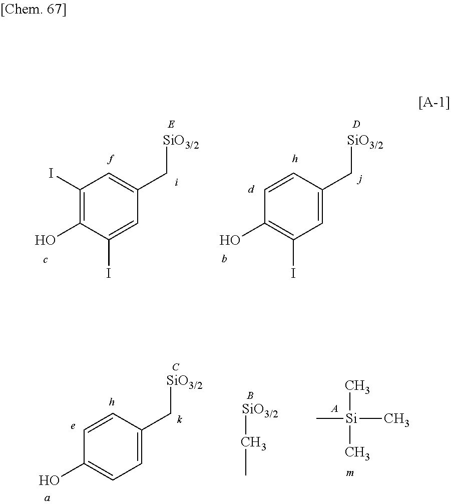

[¹³C-NMR (150 MHz, acetone-d₆)]
a: 1.02C, 128 ppm
b, e, j: 1.53C, 130 ppm
C, i: 1.27C, 84 ppm
d: 1.00C, 156 ppm
f, l: 0.36C, 138 ppm
g, m: 0.35C, 115 ppm
h: 0.27C, 154 ppm
k: 0.09C, 134 ppm
n: 0.09C, 152 ppm
o, p, q: 1.36C, 23 ppm
r: 1.01C, −5 ppm
s: 0.85C, 2 ppm

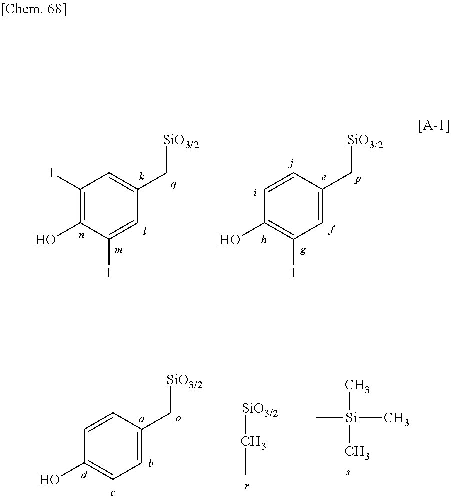

### (Synthesis of A-2)

A-2 (terminal trimethylsilyl group) was synthesized in the same manner as in the synthesis of A-1, except that 100 g of the 5 wt % solution of an iodine element in tetrahydrofuran was changed to 14 g of a 20 wt % solution of iodine monochloride in acetic acid and 86 g of tetrahydrofuran. The resultant was identified as having the above structure (A-2) from a molecular weight as measured by GPC of 8600, a degree of iodine substitution of 33.4%, and 1H-NMR, 13C-NMR, and ²⁹Si-NMR analysis results.

### (Synthesis of A-3)

A-3 (terminal trimethylsilyl group) was synthesized in the same manner as in the synthesis of A-2, except that 14 g of the 20 wt % solution of iodine monochloride in acetic acid was changed to 1.5 g. The resultant was identified as having the above structure (A-3) from a molecular weight as measured by GPC of 5700, a degree of iodine substitution of 2.45%, and ¹H-NMR, 13C-NMR, and ²⁹Si-NMR analysis results.

### (Synthesis of A-4)

A-4 (terminal trimethylsilyl group) was synthesized in the same manner as in the synthesis of A-2, except that 14 g of the 20 wt % solution of iodine monochloride in acetic acid was changed to 45 g. The resultant was identified as having the above structure (A-4) from a molecular weight as measured by GPC of 8600, a degree of iodine substitution of 61.6%, and ¹H-NMR, 13C-NMR, and ²⁹Si-NMR analysis results.

### (Synthesis of A-5)

A-5 (terminal trimethylsilyl group) was synthesized in the same manner as in the synthesis of A-2, except that the 26 wt % solution of a silicon-containing resin A-10 in propylene glycol monomethyl ether acetate was changed to 100 g of a 26 wt % solution of a silicon-containing resin A-11 in propylene glycol monomethyl ether acetate. The resultant was identified as having the above structure (A-5) from a molecular weight as measured by GPC of 6900, a degree of iodine substitution of 31.3%, and ¹H-NMR, 13C-NMR, and ²⁹Si-NMR analysis results.

[¹H-NMR (600 MHz, DMSO-d₆)
a: 1.00H, 8.6-9.0 ppm
b: 0.50H, 9.2-9.9 ppm
c, d, e, f: 5.48H, 6.2-7.5 ppm
g, h: 3.01H, 1.2-2.5 ppm
i: 2.24H, −1.5-0.7 ppm

[²⁹Si-NMR (120 MHz, acetone-d6)]
A: 1.00Si, 12-8 ppm
B: 2.82Si, −100-120 ppm
C, D: 4.01Si, −58-75 ppm

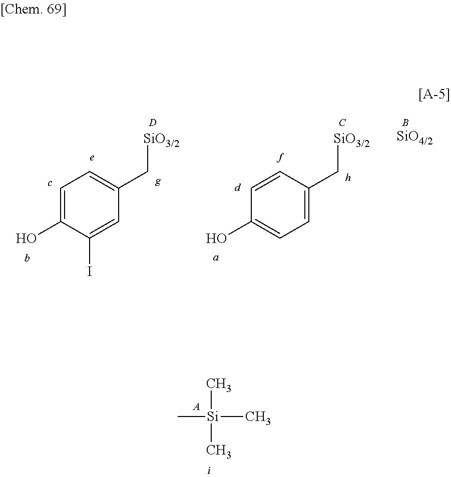

[¹³C-NMR (150 MHz, acetone-d6)]
a, e: 0.98C, 128 ppm
b, f, j: 1.47C, 130 ppm
c, i, g: 1.53C, 84 ppm
d, h: 1.00C, 156 ppm
k, l: 1.03C, 30 ppm
m: 0.25C, 4 ppm

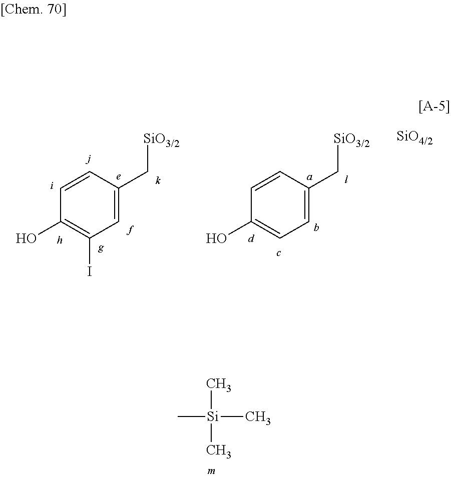

### (Synthesis of A-6)

A-6 (terminal trimethylsilyl group) was synthesized in the same manner as in the synthesis of A-5, except that 14 g of the 20 wt % solution of iodine monochloride in acetic acid was changed to 1.5 g. The resultant was identified as having the above structure (A-6) from a molecular weight as measured by GPC of 6500, a degree of iodine substitution of 3.08%, and 1H-NMR, 13C-NMR, and 29Si-NMR analysis results.

### (Synthesis of A-7)

A-7 (terminal trimethylsilyl group) was synthesized in the same manner as in the synthesis of A-5, except that 14 g of the 20 wt % solution of iodine monochloride in acetic acid was changed to 50 g. The resultant was identified as having the above structure (A-7) from a molecular weight as measured by GPC of 7300, a degree of iodine substitution of 60.55%, and ¹H-NMR, 13C-NMR, and 29Si-NMR analysis results.

### (Synthesis of A-8)

First, 50 g of a 26 wt % solution of a silicon-containing resin A-10 in propylene glycol monomethyl ether acetate, 3.0 g of 4-iodobenzoic acid, 0.15 g of 4-dimethylaminopyridine, and 10 g of dehydrated N,N-dimethylformamide were added and mixed to be uniform, and the resulting mixture was stirred at 0° C. for 30 minutes. Thereafter, 10 g of a 30 wt % solution of 1-(3-dimethylaminopropyl)-3-ethylcarbodiimide hydrochloride in DMF was added dropwise for 5 minutes with ice-cold stirring. The resultant was continuously stirred for 30 minutes while cooling with ice, heated to room temperature, and stirred for 84 hours. Then, 180 g of methyl isobutyl ketone, isopropanol, and 90 g of a saturated aqueous sodium bicarbonate solution were added to the resulting solution and left to stand, an aqueous layer was removed, and the resultant was washed twice with 45 g of pure water. The resulting organic phase was concentrated to dryness using a rotary evaporator. Then, 112 g of propylene glycol monomethyl ether acetate was added thereto and concentrated to dryness using a rotary evaporator, which was repeated three times. Then, propylene glycol monomethyl ether acetate was added thereto so as to give a concentration of 15% and dissolved to obtain 96 g of a 15% solution of an iodinated silicon-containing resin A-8 (terminal trimethylsilyl group) in propylene glycol monomethyl ether acetate. The resultant was identified as having the above structure (A-8) from a molecular weight as measured by GPC of 2500, a degree of iodine substitution of 11.4%, and 1H-NMR, 13C-NMR, and ²⁹Si-NMR analysis results.

[¹H-NMR (600 MHz, DMSO-d₆)
a, b, e, f: 4.95H, 6.2-7.4 ppm
c: 1.00H, 8.8-9.0 ppm
d, g: 0.842H, 7.6-8.0 ppm
h, i: 4.43h, 1.4-2.3 ppm
j, k: 4.38H, −1.5-0.7 ppm

[²⁹Si-NMR (120 MHz, acetone-d₆)]
A: 1.00Si, 12-8 ppm
B to D: 8.31Si, −58-75 ppm

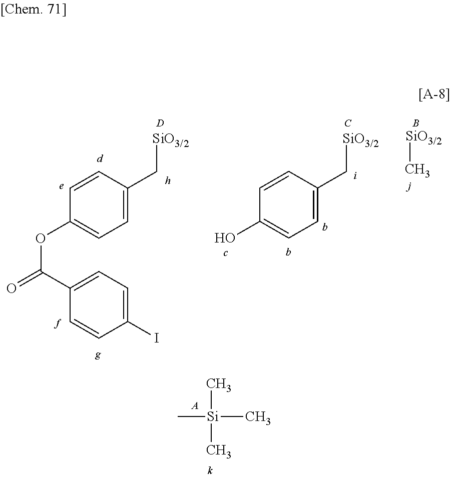

[¹³C-NMR (150 MHz, acetone-d6)]
a: 1.05C, 128 ppm
b, f, k, j: 2.73C, 130 ppm
c: 2.07C, 115 ppm
d: 1.00C, 156 ppm
e: 0.22C, 137 ppm
g: 0.45C, 124 ppm
h: 0.22C, 148 ppm
i: 0.22C, 164 ppm
k: 0.45C, 133 ppm
l: 0.43C, 139 ppm
m: 0.22C, 102 ppm
n, o: 1.24C, 23 ppm
p: 0.91C, −5 ppm
q: 0.72C, 2 ppm

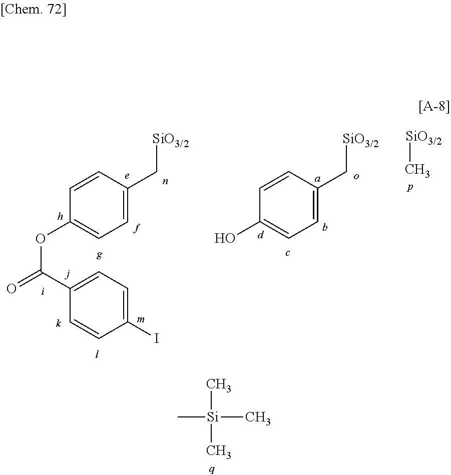

### (Synthesis of A-9)

A-9 (terminal trimethylsilyl group) was synthesized in the same manner as in the synthesis of A-8, except that 50 g of the 26 wt % solution of a silicon-containing resin A-10 in propylene glycol monomethyl ether acetate was changed to 50 g of a 26 wt % solution of a silicon-containing resin A-11 in propylene glycol monomethyl ether acetate. The resultant was identified as having the above structure (A-9) from a molecular weight as measured by GPC of 4900, a degree of iodine substitution of 33.1%, and 1H-NMR, 13C-NMR, and ²⁹Si-NMR analysis results.

### <<Formation of Patterned Silicon-Containing Resin Film (Cured Films)>>

A 12-inch silicon wafer was coated with a resist organic underlayer film composition “AL412” (manufactured by Brewer Science) using a spin coater, and the resulting coated film was baked at 205° C. for 60 seconds on a hot plate to form a 22 nm-thick organic underlayer film. The organic underlayer film was coated with each of the photosensitive compositions of Examples using a spin coater, and the resulting coated film was subjected to a pre-bake (PAB) treatment at 90° C. for 60 seconds on a hot plate to form a 22 nm-thick coated film.

Next, the coated film was irradiated with EUV light (13.5 nm) through a photo mask using the EUV exposure device NXE3400 (manufactured by ASML, numerical aperture (NA)=0.33, illumination conditions: Annular α-in =0.60, σ-out=0.82). Thereafter, the resultant was subjected to a post-exposure bake (PEB) treatment at 90° C. for 60 seconds.

Then, alkaline development was performed at 23° C. for 10 seconds with a 2.38% by mass aqueous tetramethylammonium hydroxide (TMAH) solution (trade name: NMD-3, manufactured by TOKYO OHKA KOGYO CO., LTD.). Thereafter, a water rinse was performed with pure water for 30 seconds, followed by shaking and drying. As a result, a line-and-space pattern (LS pattern) with a line width of 14 nm was formed.

### [Evaluation of Optimal Exposure (Eop) (Evaluation of Sensitivity)]

Optimal exposure Eop (mJ/cm²) that results in an LS pattern with a line width of 14 nm by the above-described formation of a patterned cured film was determined. The results are shown in FIG. 2.

### [Evaluation of Linewise Roughness (LWR)]

The LS pattern with a line width of 14 nm formed by the above-described formation of a patterned cured film was determined for 3σ, which was a measure of LWR. The term “3σ” refers to a threefold value (3σ) (unit: nm) of the standard deviation (σ) determined from measurement results of 400 line positions in a longitudinal direction of the line using a scanning electron microscope (accelerating voltage: 800 V, product name: S-9380, manufactured by Hitachi High-Tech Corporation). The results are shown in FIG. 2. A smaller value of 3σ means that roughness of a line sidewall is smaller and an LS pattern with a more uniform width was obtained.

TABLE 2

| | Eop | LWR |
|---|---|---|
| | (mJ/cm²) | (nm) |
| Example 1 | 48 | 2.27 |
| Example 2 | 48 | 2.18 |
| Example 3 | 51 | 2.48 |
| Example 4 | 46 | 2.52 |
| Example 5 | 49 | 2.20 |
| Example 6 | 53 | 2.47 |
| Example 7 | 46 | 2.52 |
| Example 8 | 51 | 2.29 |
| Example 9 | 52 | 2.30 |
| Example 10 | 47 | 2.14 |
| Example 11 | 50 | 2.23 |
| Example 12 | 48 | 2.20 |
| Example 13 | 51 | 2.26 |
| Example 14 | 45 | 2.24 |
| Example 15 | 48 | 2.28 |
| Example 16 | 45 | 2.27 |
| Example 17 | 49 | 2.29 |
| Example 18 | 47 | 2.20 |
| Example 19 | 50 | 2.26 |
| Example 20 | 47 | 2.22 |
| Example 21 | 50 | 2.26 |
| Example 22 | 51 | 2.18 |
| Example 23 | 49 | 2.19 |
| Example 24 | 47 | 2.14 |
| Example 25 | 48 | 2.15 |
| Example 26 | 48 | 2.11 |
| Example 27 | 49 | 2.13 |
| Comparative Example 1 | 56 | 2.70 |
| Comparative Example 2 | 55 | 2.68 |
| Comparative Example 3 | 53 | 2.60 |
| Comparative Example 4 | 54 | 2.61 |
| Comparative Example 5 | 50 | 2.66 |
| Comparative Example 6 | 51 | 2.66 |
| Comparative Example 7 | 52 | 2.60 |
| Comparative Example 8 | 53 | 2.62 |
| Comparative Example 9 | 57 | 2.57 |
| Comparative Example 10 | 56 | 2.56 |

Table 2 demonstrates that the photosensitive compositions of Examples 1 to 27 can form a fine pattern with high sensitivity and reduced roughness.

What is claimed is:

1. A photosensitive composition comprising:
a silicon-containing resin (A);
a photoacid generating agent (B); and
a cross-linking agent (C),
wherein the silicon-containing resin (A) has an aromatic group substituted with one or more iodine atoms.

2. The photosensitive composition according to claim 1, wherein the silicon-containing resin (A) has a constituent unit represented by Formula (a1): 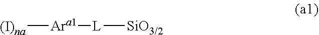
wherein L is a divalent linking group having 1 or more and 40 or less carbon atoms;
provided that when the divalent linking group for L is bonded to an aromatic hydrocarbon ring in Ar^{a1}, there is no aromatic hydrocarbon group at an end of the divalent linking group for L that is bonded to the aromatic hydrocarbon ring in Ar^{a1};
Ar^{a1} is a group having an aromatic hydrocarbon ring that is optionally substituted with one or more groups selected from the group consisting of a hydroxy group, an alkoxy group, and a hydrocarbon group that may have a substituent;
I is bonded to the aromatic hydrocarbon ring that Ar^{a1} has; and
na is an integer of 1 or more and 3 or less.

3. The photosensitive composition according to claim 1, wherein the silicon-containing resin (A) has a phenolic hydroxy group.

4. The photosensitive composition according to claim 1, wherein the photoacid generating agent (B) is an onium salt comprising an organosulfonic acid anion having from 1 or more and 40 or less carbon atoms and an organosulfonium ion or an organoiodonium ion.

5. The photosensitive composition according to claim 1, further comprising a base component (D) that controls diffusion of an acid generated by the photoacid generating agent (B) upon exposure, wherein the base component (D) is a carboxylate comprising a carboxylic acid anion having 1 or more and 40 or less carbon atoms and an organosulfonium ion or an organoiodonium ion.

6. The photosensitive composition according to claim 1, wherein a proportion of a mass of the silicon-containing resin (A) to a mass of a solid content of the photosensitive composition is 10% by mass or more.

7. A method for producing a patterned silicon-containing resin film, the method comprising:
coating a support with the photosensitive composition according to claim 1 to form a coated film;
exposing the coated film in a position-selective manner; and
developing the exposed coated film.

8. The method for producing a patterned silicon-containing resin film according to claim 7, wherein the coated film is exposed to extreme ultraviolet irradiation in a position-selective manner.

9. A silicon-containing resin having an aromatic group substituted with one or more iodine atoms.

10. The silicon-containing resin according to claim 9, wherein the silicon-containing resin comprises a constituent unit represented by Formula (a1): 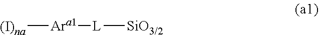
wherein L is a divalent linking group having 1 or more and 40 or less carbon atoms;
provided that when the divalent linking group for L is bonded to an aromatic hydrocarbon ring in Ar^{a1}, there is no aromatic hydrocarbon group at an end of the divalent linking group for L that is bonded to the aromatic hydrocarbon ring in Ar^{a1};
Ar^{a1} is a group having an aromatic hydrocarbon ring that is optionally substituted with one or more groups selected from a hydroxy group, an alkoxy group, or a hydrocarbon group that may have a substituent;
I is bonded to the aromatic hydrocarbon ring that Ar^{a1} has; and
na is an integer of 1 or more and 3 or less.

11. The silicon-containing resin according to claim 9, wherein the silicon-containing resin has a phenolic hydroxy group.
